(19) United States
(12) Patent Application Publication
(10) Pub. No.: US 2026/0223595 A1
(43) Pub. Date: Jul. 30, 2026

(54) NOVEL MULTIFUNCTIONAL COMPOUND AND ORGANIC LIGHT-EMITTING DIODE COMPRISING SAME

(71) Applicant: LORDIN CO., LTD, Hwaseong-si Gyeonggi-do (KR)

(72) Inventors: Bu Bae PARK, Hwaseong-si Gyeonggi-do (KR); Ga Ram HAN, Osan-si Gyeonggi-do (KR); Sang Min KANG, Hwaseong-si Gyeonggi-do (KR)

(21) Appl. No.: 19/141,986

(22) PCT Filed: Dec. 20, 2023
(86) PCT No.: PCT/KR2023/021112

§ 371 Date: Jun. 20, 2025

(30) Foreign Application Priority Data
Dec. 20, 2022 (KR) 10-2022-0179160

(51) Int. Cl. H10K 85/60; C07F 5/02; C09K 11/06; H10K 50/11; H10K 85/30; H10K 101/25

(52) U.S. Cl. CPC H10K 85/658; C07F 5/027; C09K 11/06; H10K 85/342; H10K 85/346; H10K 85/615; H10K 85/654; C09K 2211/1007; C09K 2211/1011; C09K 2211/1018; C09K 2211/185; H10K 50/11; H10K 2101/25

(57) ABSTRACT

Provided is a novel multifunctional compound, and an organic light-emitting diode including a light-emitting layer including the same. The multifunctional compound includes a light-emitting moiety linked to an excited complex-forming moiety. The light-emitting moiety emits light by receiving excited energy from an excited complex formed by the excited complex-forming moiety.

### TECHNICAL FIELD

The present disclosure relates to a novel multifunctional compound and an organic light-emitting diode including the same.

### BACKGROUND ART

An organic light-emitting diode (OLED) is a device in which holes injected from an anode and electrons injected from a cathode combine in a light-emitting layer to form excitons and emit light, and was first reported in Appl. Phys. Lett 51, 913 by C. W. Tang in 1987. Two electrons having different spins are present in the HOMO wave function of a light-emitting layer host. A phenomenon of electrons directly leaving from and entering into an organic material occurs in an OLED in which the electrons leave at a HOMO (Highest Occupied Molecular Orbital) level and are injected at a LUMO (Lowest Unoccupied Molecular Orbital) level. Herein, since the spin directions of the leaving or entering electrons are not determined, the formed excitons are a triplet in the same direction and a singlet in a different spin direction. In an organic material, a triplet normally has smaller energy by 0.5 eV to 1 eV due to exchange energy and repulsive energy between electrons. The ratio between a singlet and a triplet is theoretically 25% and 75%, and the singlet is emitted as light, but the triplet is lost as heat. In order to increase internal quantum efficiency of an OLED device, the triplet needs to be induced to be emitted as light. Mark E. Thompson reported a technique of emitting a triplet as light by increasing spin-orbit coupling using a heavy metal such as Pt in the patent (U.S. Pat. No. 6,303,238B1) filed in 1997. Chihaya Adachi designed a molecule to have a minimum wave function overlap between HOMO and LUMO in one molecule, which was reported in Nature, 2012, 492, 234-238. In this way, the designed molecule increases efficiency due to thermally activated delayed fluorescence (TADF) in which energy of the triplet is transferred to the singlet to emit light. However, the method of using a heavy metal requires very expensive metals such as Pt and Ir, and may have a problem in material stability due to high HOMO-LUMO gap energy of the singlet since a blue color needs to be expressed in the triplet. The method of using thermally activated delayed fluorescence has a problem in that it is difficult to implement a deep blue color since full width at half maximum (FWHM) of the emission spectrum is widened due to a small degree of overlap between the wave functions of HOMO and LUMO, and there is also a problem in material stability.

Another method that has been studied to reduce the energy difference between a singlet and a triplet is to form an excited complex between a relatively electron-rich electron donor molecule and an electron-deficient electron acceptor molecule, and when an electron donor (or electron acceptor) molecule absorbs light and becomes excited, the excited molecule and an electron acceptor (or electron donor) molecule in a ground state form an excited complex (exciplex) by Coulombic interaction (Valeur, B, Berberan-santos, M.N, Wiley-VCH Verlag GmbH & co. KGaA, 2nd edition, 2012). In this state, light emission efficiency may be increased since a difference between the triplet energy and the singlet energy is small. However, even when forming such an excited complex, there is a problem in that it is difficult to obtain a deep blue color by having a very wide emission spectrum FWHM, and when doping a dopant to obtain a deep blue color, energy transfer from the excited complex to the dopant is not efficient, causing a problem of not obtaining high quantum efficiency.

### DISCLOSURE

### Technical Problem

An object of the present disclosure is to provide a novel multifunctional compound capable of efficiently transferring energy.

Another object of the present disclosure is to provide an organic light-emitting diode having improved quantum efficiency through efficiently transferring energy by the multifunctional compound.

Objects of the present disclosure are not limited to the object mentioned above, and other objects and advantages of the present disclosure not mentioned herein may be understood by the following description, and will be more clearly understood by embodiments of the present disclosure. In addition, it may be readily seen that objects and advantages of the present disclosure may be embodied by means described in the claims and combinations thereof.

### Technical Solution

One embodiment of the present disclosure provides a multifunctional compound represented by the following Chemical Formula 1.

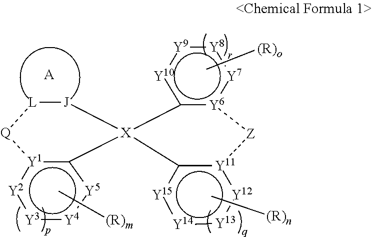

In Chemical Formula 1,
ring A is a fused ring represented by the following Chemical Formula 2, the following Chemical Formula 3 or the following Chemical Formula 4,
L represents a linking site in ring A, and L is linked to Q; or Y¹ when Q is not present,
J represents another linking site in ring A, and J is linked to X,
X is C, Si, Ge, Sn or Pb,
Q is not present, represents a single bond, or is one atom selected from the group consisting of Group IIIA, Group IVA, Group VA and Group VIA elements,
when Q is not present, L in ring A is not linked to Y¹,
when Q is a single bond, a single bond directly linking L in ring A and Y¹ is formed to form a 5-membered ring including X,
when Q is any one atom of the elements defined above, a 6-membered ring including X is formed, and the atom may have a substituent selected from the group consisting of alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a first additional substituent, heteroaryl having 2 to 30 carbon atoms unsubstituted or substituted with a first additional substituent, and combinations thereof according to a stoichiometric ratio, and the substituent may be linked to Y² or R that is linked to Y² to form a fused ring or linked to ring A to form a fused ring,
Y¹ to Y¹⁵ are each independently boron, carbon, nitrogen, oxygen, sulfur, Se or Te,
Z is not present, or a single bond, boron, oxygen, sulfur, —S(O₂)—, Se, C—(Ar¹)₂, POAr¹ or N—Ar¹, and herein, Ar¹ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar¹ may be linked to any one of Y⁷, Y¹², R linked to Y⁷ and R linked to Y¹² to form a fused ring, when Z is not present, Y⁶ and Y¹¹ are not linked,
when Z is a single bond, Y⁶ and Y¹¹ are linked through the single bond,
however, when X is Si, Z is present as defined above,
m, n and o are each independently an integer of 0 to 5,
Rs are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms unsubstituted or substituted with a second additional substituent, aryloxy having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms unsubstituted or substituted with a second additional substituent, or aryl phosphine oxide having 6 to 30 carbon atoms unsubstituted or substituted with a second additional substituent, and at least two Rs present when m, n or o is 2 or greater may be linked to each other to form a ring, and
p, q and r each independently represent 0 or 1, and when p, q or r is 0, it means that a 5-membered ring is formed, and when p, q or r is 1, it means that a 6-membered ring is formed,

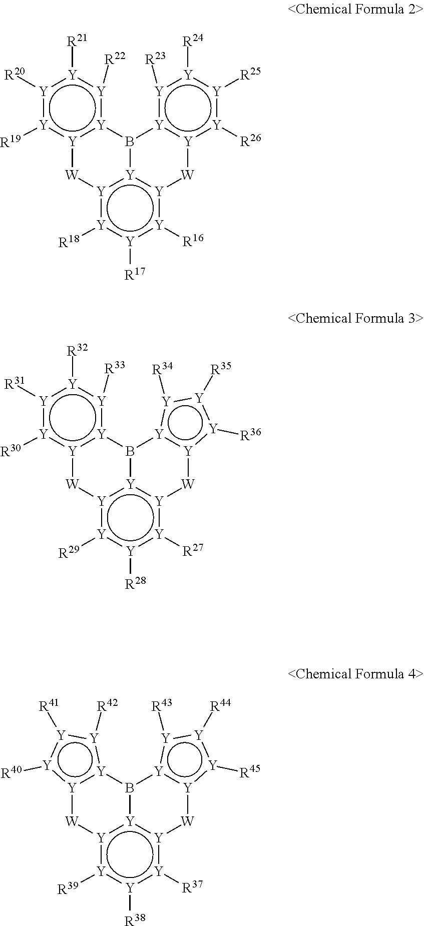

in Chemical Formula 2, Chemical Formula 3 and Chemical Formula 4,
Ys are each independently carbon, nitrogen, oxygen, sulfur, Se or Te, however, Y at the position corresponding to J in Chemical Formula 1 is carbon,
Ws are each independently oxygen, sulfur, Se, POAr² or N—Ar², Ar² is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar² may be linked to a ring fused to the fused ring including W to form a fused ring,
R¹⁶ to R⁴⁵ each independently represent a bond with X such that Y linked thereto corresponds to J in Chemical Formula 1; or a bond with Q such that Y linked thereto corresponds to L in Chemical Formula 1; or are hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹⁶ to R⁴⁵ may be linked to each other to form a ring,
the first additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, halogen, cyano, aryl having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms, heteroaryl having 2 to 30 carbon atoms, alkoxy having 1 to 30 carbon atoms, aryloxy having 6 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine oxide having 6 to 30 carbon atoms, and combinations thereof,
the second additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, alkoxy having 1 to 30 carbon atoms, halogen, cyano, carboxyl, carbonyl, amine, alkyl amine having 1 to 30 carbon atoms cycloalkyl amine having 3 to 30 carbon atoms, heterocycloalkyl amine having 2 to 30 carbon atoms, nitro, alkyl silyl having 1 to 30 carbon atoms, cycloalkyl silyl having 3 to 30 carbon atoms, heterocycloalkyl silyl having 2 to 30 carbon atoms, alkoxy silyl having 1 to 30 carbon atoms, aryl silyl having 6 to 30 carbon atoms, aryl having 6 to 30 carbon atoms, aryl amine having 6 to 30 carbon atoms, heteroaryl having 2 to 30 carbon atoms, aryl phosphine oxide having 6 to 30 carbon atoms, aryl phosphinyl having 6 to 30 carbon atoms, alkyl phosphine oxide having 1 to 30 carbon atoms, cycloalkyl phosphine oxide having 3 to 30 carbon atoms, heterocycloalkyl phosphine oxide having 2 to 30 carbon atoms, alkyl sulfonyl having 1 to 30 carbon atoms, cycloalkyl sulfonyl having 3 to 30 carbon atoms, heterocycloalkyl sulfonyl having 2 to 30 carbon atoms, and combinations thereof,
positions of L and J in Chemical Formula 1 are according to the following (i) or (ii),
(i) Y linked to any one of R¹⁶ to R⁴⁵ corresponds to J in Chemical Formula 1, and another Y adjacent to Y corresponding to J corresponds to L in Chemical Formula 1; or,
(ii) any one of Ws is N—Ar², Ar² is aryl having 6 to 30 carbon atoms unsubstituted or substituted with a second additional substituent or heteroaryl having 2 to 30 carbon atoms unsubstituted or substituted with a second additional substituent, any one ring of aryl or heteroaryl of Ar² is carbon and corresponds to J in Chemical Formula 1, and another ring adjacent thereto corresponds to L in Chemical Formula 1,
however, in Chemical Formula 1, when Z and Q are both a single bond, the following case (a) or (b) is excluded:
(a) ring A in Chemical Formula 1 is Chemical Formula 3 or Chemical Formula 4, any one of R³⁴ to R³⁶ and R⁴⁰ to R⁴⁵ in Chemical Formula 3 or Chemical Formula 4 corresponds to L in Chemical Formula 1, and two Ws in ring A are both N—Ar²,
(b) a 5-membered ring is formed in which at least one of p and q in Chemical Formula 1 is 0, and two Rs linked to the 5-membered ring are linked to each other to form an unsubstituted 6-membered fused ring.

Another embodiment of the present disclosure provides an organic light-emitting diode including: a first electrode; a second electrode; and a light-emitting layer disposed between the first electrode and the second electrode; and further including or not including an organic layer adjacent to any one or both surfaces of the light-emitting layer, wherein the light-emitting layer includes the multifunctional compound, and the light-emitting layer or the adjacent organic layer includes an excited complex-forming compound.

### Advantageous Effects

A multifunctional compound according to the present disclosure enables an effective energy transfer between moieties in the multifunctional compound while reducing an energy difference between a singlet and a triplet, readily implements a deep blue color and achieves an efficient energy transfer, and therefore, an organic light-emitting diode using the multifunctional compound is able to have high quantum efficiency.

Specific effects of the present disclosure in addition to the above-described effect will be described together while describing specific details to carry out the present disclosure hereinafter.

### BRIEF DESCRIPTION OF DRAWINGS

FIG. 1 is a diagram illustrating a working mechanism of a multifunctional compound according to one embodiment of the present disclosure hereinafter.

FIG. 2 schematically illustrates a mechanism in which excited energy of an excited complex is transferred between moieties in the multifunctional compound and light is emitted in an organic light-emitting diode according to one embodiment of the present disclosure.

FIG. 3 is a graph showing a PL (photoluminescence) phenomenon observed by depositing HOST-1:HOST-3 in a 1:1 ratio, and exciting each deposited glass with an absorption wavelength (350 nm).

FIG. 4 is a graph showing a PL (photoluminescence) phenomenon observed by depositing HOST-2:HOST-4 in a 1:1 ratio, and exciting each deposited glass with an absorption wavelength (350 nm).

FIG. 5 is a graph showing a PL (photoluminescence) phenomenon observed by dissolving each of Comparative Compound 1 and Compound 2 in toluene to have a concentration of 2 micromoles, and exciting them with an absorption wavelength (maximum).

### BEST MODE

Hereinafter, embodiments of the present disclosure will be described in detail with reference to drawings so that those skilled in the art may readily carry out the present disclosure. The present disclosure may be embodied in various different forms, and is not limited to the embodiments described herein.

In the present specification, the term “substitution” means that a hydrogen atom bonding to a carbon atom in a compound is substituted with another substituent. The position where substitution occurs means a position at which the hydrogen atom is substituted. The position is not limited as long as it is a position where hydrogen at the position may be substituted with a substituent. When two or more substitutions occur, the two or more substituents may be the same as or different from each other.

In the present specification, the substituent when “substituted” may be, unless otherwise stated, one selected from the group consisting of, for example, deuterium, an alkyl group having 1 to 20 carbon atoms, a cycloalkyl group having 3 to 30 carbon atoms, a heterocycloalkyl group having 2 to 30 carbon atoms, an allyl group having 3 to 30 carbon atoms, an alkoxy group having 1 to 30 carbon atoms, a halogen group, a cyano group, a carboxyl group, a carbonyl group, an amine group, an alkyl amine group having 1 to 30 carbon atoms, a cycloalkyl amine group having 3 to 30 carbon atoms, a heterocycloalkyl amine group having 2 to 30 carbon atoms, a nitro group, an alkyl silyl group having 1 to 30 carbon atoms, a cycloalkyl silyl group having 3 to 30 carbon atoms, a heterocycloalkyl silyl group having 2 to 30 carbon atoms, an alkoxysilyl group having 1 to 30 carbon atoms, an aryl silyl group having 6 to 30 carbon atoms, an aryl group having 6 to 30 carbon atoms, an aryl amine group having 6 to 30 carbon atoms, a heteroaryl group having 2 to 30 carbon atoms, an aryl phosphine oxide group having 6 to 30 carbon atoms, an aryl phosphinyl group having 6 to 30 carbon atoms, an alkyl phosphine oxide group having 1 to 30 carbon atoms, a cycloalkyl phosphine oxide group having 3 to 30 carbon atoms, a heterocycloalkyl phosphine oxide group having 2 to 30 carbon atoms, an alkyl sulfonyl group having 1 to 30 carbon atoms, a cycloalkyl sulfonyl group having 3 to 30 carbon atoms, a heterocycloalkyl sulfonyl group having 2 to 30 carbon atoms, and combinations thereof, but is not limited thereto.

“Combinations thereof” in the definition of substituents of the present specification means that, unless otherwise defined, two or more substituents are present, or two or more divalent substituents are linked or fused for bonding.

In the present specification, a case of two substituents being linked to form a ring includes a case in which one of the two substituents is hydrogen, and the two substituents are linked as the hydrogen is removed.

In the present specification, alkyl includes cycloalkyl and heterocycloalkyl unless otherwise stated. In addition, for example, alkyl amine includes cycloalkyl amine and heterocycloalkyl amine unless otherwise stated.

In the present specification, “hetero” means, unless otherwise defined, including a heteroatom in one compound or substituent. The heteroatom means an atom that is not carbon and hydrogen among the atoms forming a heterocyclic compound. Examples thereof may include N, O, Si, Ge, S, P, B, Se, Te and the like, but are not limited thereto. When two or more heteroatoms are included in one compound or substituent, the included heteroatoms may be the same as or different from each other, and, for example, be one, or two or more types of heteroatoms. For example, heteroaryl or heterocycloalkyl includes at least one heteroatom as an atom forming the ring.

In the present specification, a ring includes a fused ring unless otherwise stated.

One embodiment of the present disclosure provides,
a multifunctional compound represented by the following Chemical Formula 1.

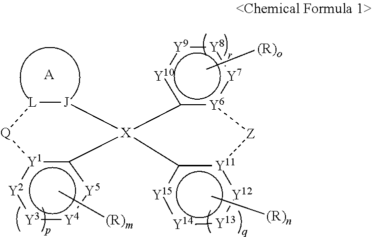

In Chemical Formula 1,
ring A is a fused ring represented by the following Chemical Formula 2, the following Chemical Formula 3 or the following Chemical Formula 4,
L represents a linking site in ring A, and L is linked to Q; or Y¹ when Q is not present,
J represents another linking site in ring A, and J is linked to X,
X is C, Si, Ge, Sn or Pb,
Q is not present, represents a single bond, or is one atom selected from the group consisting of Group IIIA, Group IVA, Group VA and Group VIA elements,
when Q is not present, L in ring A is not linked to Y¹,
when Q is a single bond, a single bond directly linking L in ring A and Y¹ is formed to form a 5-membered ring including X,
when Q is any one atom of the elements defined above, a 6-membered ring including X is formed, and the atom may have a substituent selected from the group consisting of alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a first additional substituent, heteroaryl having 2 to 30 carbon atoms unsubstituted or substituted with a first additional substituent, and combinations thereof according to a stoichiometric ratio, and the substituent may be linked to Y² or R that is linked to Y² to form a fused ring or linked to ring A to form a fused ring,
Y¹ to Y¹⁵ are each independently boron, carbon, nitrogen, oxygen, sulfur, Se or Te,
Z is not present, or a single bond, boron, oxygen, sulfur, —S(O₂)—, Se, C—(Ar¹)₂, POAr¹ or N—Ar¹, and herein, Ar¹ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar¹ may be linked to any one of Y⁷, Y¹², R linked to Y⁷ and R linked to Y¹² to form a fused ring, when Z is not present, Y⁶ and Y¹¹ are not linked,
when Z is a single bond, Y⁶ and Y¹¹ are linked through the single bond,
however, when X is Si, Z is present as defined above,
m, n and o are each independently an integer of 0 to 5,
Rs are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms unsubstituted or substituted with a second additional substituent, aryloxy having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms unsubstituted or substituted with a second additional substituent, or aryl phosphine oxide having 6 to 30 carbon atoms unsubstituted or substituted with a second additional substituent, and at least two Rs present when m, n or o is 2 or greater may be linked to each other to form a ring, and
p, q and r each independently represent 0 or 1, and when p, q or r is 0, it means that a 5-membered ring is formed, and when p, q or r is 1, it means that a 6-membered ring is formed,

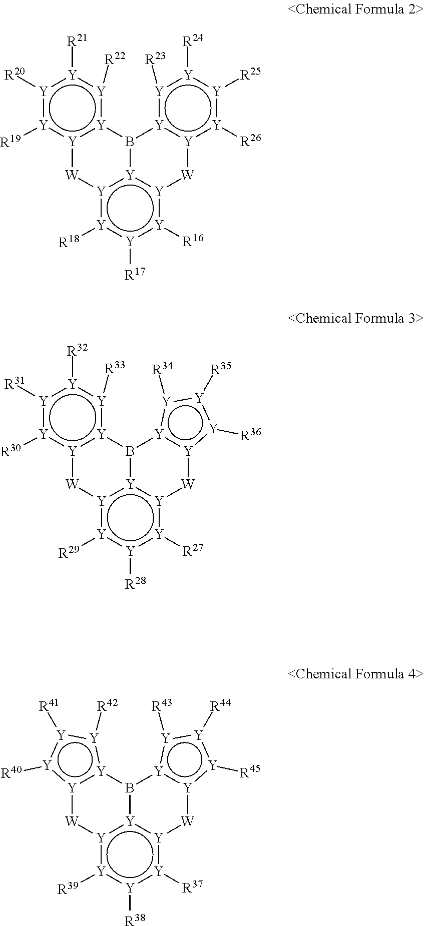

in Chemical Formula 2, Chemical Formula 3 and Chemical Formula 4,
Ys are each independently carbon, nitrogen, oxygen, sulfur, Se or Te, however, Y at the position corresponding to J in Chemical Formula 1 is carbon,
Ws are each independently oxygen, sulfur, Se, POAr² or N—Ar², Ar² is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar² may be linked to a ring fused to the fused ring including W to form a fused ring,
R¹⁶ to R⁴⁵ each independently represent a bond with X such that Y linked thereto corresponds to J in Chemical Formula 1; or a bond with Q such that Y linked thereto corresponds to L in Chemical Formula 1; or are hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹⁶ to R⁴⁵ may be linked to each other to form a ring,
the first additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, halogen, cyano, aryl having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms, heteroaryl having 2 to 30 carbon atoms, alkoxy having 1 to 30 carbon atoms, aryloxy having 6 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine oxide having 6 to 30 carbon atoms, and combinations thereof,
the second additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, alkoxy having 1 to 30 carbon atoms, halogen, cyano, carboxyl, carbonyl, amine, alkyl amine having 1 to 30 carbon atoms, cycloalkyl amine having 3 to 30 carbon atoms, heterocycloalkyl amine having 2 to 30 carbon atoms, nitro, alkyl silyl having 1 to 30 carbon atoms, cycloalkyl silyl having 3 to 30 carbon atoms, heterocycloalkyl silyl having 2 to 30 carbon atoms, alkoxy silyl having 1 to 30 carbon atoms, aryl silyl having 6 to 30 carbon atoms, aryl having 6 to 30 carbon atoms, aryl amine having 6 to 30 carbon atoms, heteroaryl having 2 to 30 carbon atoms, aryl phosphine oxide having 6 to 30 carbon atoms, aryl phosphinyl having 6 to 30 carbon atoms, alkyl phosphine oxide having 1 to 30 carbon atoms, cycloalkyl phosphine oxide having 3 to 30 carbon atoms, heterocycloalkyl phosphine oxide having 2 to 30 carbon atoms, alkyl sulfonyl having 1 to 30 carbon atoms, cycloalkyl sulfonyl having 3 to 30 carbon atoms, heterocycloalkyl sulfonyl having 2 to 30 carbon atoms, and combinations thereof,
positions of L and J in Chemical Formula 1 are according to the following (i) or (ii),
(i) Y linked to any one of R¹⁶ to R⁴⁵ corresponds to J in Chemical Formula 1, and another Y adjacent to Y corresponding to J corresponds to L in Chemical Formula 1; or,
(ii) any one of Ws is N—Ar², Ar² is aryl having 6 to 30 carbon atoms unsubstituted or substituted with a second additional substituent or heteroaryl having 2 to 30 carbon atoms unsubstituted or substituted with a second additional substituent, any one reduction of aryl or heteroaryl of Ar² is carbon and corresponds to J in Chemical Formula 1, and another reduction adjacent thereto corresponds to L in Chemical Formula 1,
however, in Chemical Formula 1, when Z and Q are both a single bond, the following case (a) or (b) is excluded:
(a) ring A in Chemical Formula 1 is Chemical Formula 3 or Chemical Formula 4, any one of R³⁴ to R³⁶ and R⁴⁰ to R⁴⁵ in Chemical Formula 3 or Chemical Formula 4 corresponds to L in Chemical Formula 1, and two Ws in ring A are both N—Ar²,
(b) a 5-membered ring is formed in which at least one of p and q in Chemical Formula 1 is 0, and two Rs linked to the 5-membered ring are linked to each other to form an unsubstituted 6-membered fused ring.

In the definition of Chemical Formula 1, a case in which a substituent linked to Q is linked to Y² or R that is linked to Y² to form a fused ring includes a case in which R linked to Y² is hydrogen, and as R, the hydrogen, is eliminated, the substituent linked to Q is linked to Y².

In the definition of Chemical Formula 1, a case in which Ar¹ is linked to any one of Y⁷, Y¹², R linked to Y⁷ and R linked to Y¹² to form a fused ring includes a case in which R linked to Y⁷ or R linked to Y¹² is hydrogen, and as R, the hydrogen, is eliminated, Ar¹ is linked to Y⁷ or Y¹².

When at least two Rs are linked to form a ring in Chemical Formula 1, such a ring includes a fused ring. In addition, when two Rs are linked, it includes a case in which any one R of the linked two is hydrogen, and as R, the hydrogen, is eliminated, the other R of the linked two is directly linked to any one of Y¹ to Y¹⁵ to which R, the hydrogen, is linked.

When at least two of R¹⁶ to R⁴⁵ are linked to form a ring in Chemical Formulae 2 to 4, such a ring includes a fused ring. In addition, when two of R¹⁶ to R⁴⁵ are linked, it includes a case in which any one of the linked two is hydrogen, and as the hydrogen is eliminated, the other one of the linked two is directly linked to Y to which the hydrogen is linked.

The multifunctional compound is a compound represented by Chemical Formula 1 chemical-structurally designed to have an increased rate constant value related to an energy transfer rate, and may improve luminous efficiency of an organic light-emitting diode.

The multifunctional compound may implement a deep blue color, and may also improve quantum efficiency of an organic light-emitting diode.

The multifunctional compound represented by Chemical Formula 1 is designed to be divided into an atom represented by X, a light-emitting moiety and an excited complex-forming moiety: the light-emitting moiety and the excited complex-forming moiety are linked through the atom represented by X, and the atom represented by X is X presented in Chemical Formula 1. The light-emitting moiety includes ring A, a conjugated ring formed to include Y¹ to Y⁵, and Q in Chemical Formula 1. The excited complex-forming moiety includes a conjugated ring formed to include Y⁶ to Y¹⁰, a conjugated ring formed to include Y¹¹ to Y¹⁵, and Z in Chemical Formula 1.

The excited complex-forming moiety may form an excited complex together with an excited complex-forming compound described below.

The multifunctional compound is a compound in which the light-emitting moiety bonds to the excited complex-forming moiety that may form an excited complex with an excited complex-forming compound via the atom represented by X.

A mechanism of the excited complex is a phenomenon occurring between two molecules, and one molecule becomes excited (excited state) first by absorbing light corresponding to a HOMO-LUMO gap, and interacts with another molecule in the vicinity to form an excited complex. When the excited complex emits light, the two molecules return to their original states.

When separately defining the excited complex in a narrow sense, it is called an excited dimer or excimer when the two molecules are the same molecules, and called an excited complex or exciplex when the two molecules are heterogeneous molecules. Alternatively, the excited complex is also named separately as an electroplex. The electroplex is an excited complex or excited dimer formed when an electric field is applied inside an organic light-emitting diode (OLED) device. In the present specification, the term ‘excited complex’ is defined in a broad sense, and needs to be understood to include all concepts of excited dimer, excimer, excited complex, exciplex and electroplex.

The excited complex-forming moiety is designed as a moiety induced from any one of two molecules forming the excited complex, and the other one of the two molecules forming the excited complex becomes the above-described excited complex-forming compound. For the convenience of distinction, the two molecules forming the excited complex are each distinguishably referred to as a first excited complex-forming compound and a second excited complex-forming compound, and the excited complex-forming moiety is induced from the first excited complex-forming compound, and may form the excited complex with the second excited complex-forming compound.

When a material having small ionization energy and a material having large electron affinity are used together in a light-emitting layer in an organic light-emitting diode device, an excited complex is formed during a process of electron migration. When a light-emitting compound is mixed with this excited complex as a dopant, the dopant absorbs exciton energy of the excited complex to cause light emission. In order to cause such light emission, efficiency of energy transfer from the excited complex to the dopant needs to be high. The method of energy transfer includes a method by light of the following Mathematical Formula 1 (FRET, Forster Resonance Energy transfer) and a method by electron of the following Mathematical Formula 2 (Dexter Electron Transfer).

### FRET (Forster Resonance Energy Transfer)

$${k}_{ET} = ( \frac{1}{{r}^{6} {τ}_{D}} ) ( \frac{2.07 {κ}^{2} {Q}_{D} J}{128 {π}^{5} {N}_{A} {n}^{4}} ) \qquad [ Mathematical Formula 1 ]$$

### Dexter Electron Transfer

$${k}_{ET} ∝ J {exp}^{( - \frac{2 r}{L} )} \qquad [ Mathematical Formula 2 ]$$

k_{ET}: rate constant
r: distance between energy donor and energy acceptor
τ_{D}: PL decay time of energy donor
κ: orientation factor
Q_{D}: PL quantum efficiency of energy donor
N_{A}: Avogadro number
n: refractive index
J: defined by Mathematical Formula 3.

$$J = \int {f}_{D} ( λ ) {ε}_{A} ( λ ) {λ}^{4} d λ \qquad [ Mathematical Formula 3 ]$$

f_{D}: emission spectrum of energy donor
ε_{A}: extinction coefficient depending on wavelength of energy acceptor
L: sum of Van der Waals radii
λ: wavelength

The inventors of the present disclosure have derived the multifunctional compound as a novel compound that allows r to approach 0 in Mathematical Formula 1 and Mathematical Formula 2. The inventors of the present disclosure deduce an advantage when r approaches 0 as follows.

Regardless of whether the energy transfer method is the method by light of Mathematical Formula 1 or by the method by electron of Mathematical Formula 2, what is important is a distance (r) between an energy donor (excited complex) and an energy acceptor (dopant). When a distance (r) approaches 0 in Mathematical Formula 1 of energy transfer by light, quantum efficiency and decay time of the energy donor (excited complex) become unimportant, and theoretically, the energy transfer rate approaches infinity. On the other hand, when a distance (r) between two molecules approaches 0 in Mathematical Formula 2, an energy transfer method by electron migration, the energy transfer rate is only affected by the degree of overlap (J) between emission spectrum and absorption spectrum between the two molecules.

The multifunctional compound is designed as a compound obtained by combining any one of the two molecules forming the excited complex (corresponding to the first excited complex-forming compound) and the dopant (corresponding to the light-emitting compound inducing the light-emitting moiety). When applying the concepts of Mathematical Formula 1 and Mathematical Formula 2 to the multifunctional compound, the distance is fixed and minimized when any one of the two molecules forming the excited complex and the dopant are combined in the multifunctional compound, and accordingly, exciton energy formed in the excited complex is transferred to the dopant at a high rate, emitting light.

The excited complex-forming moiety in the multifunctional compound is induced (or derived) from the first excited complex-forming compound, and therefore, may form an excited complex with the second excited complex-forming compound.

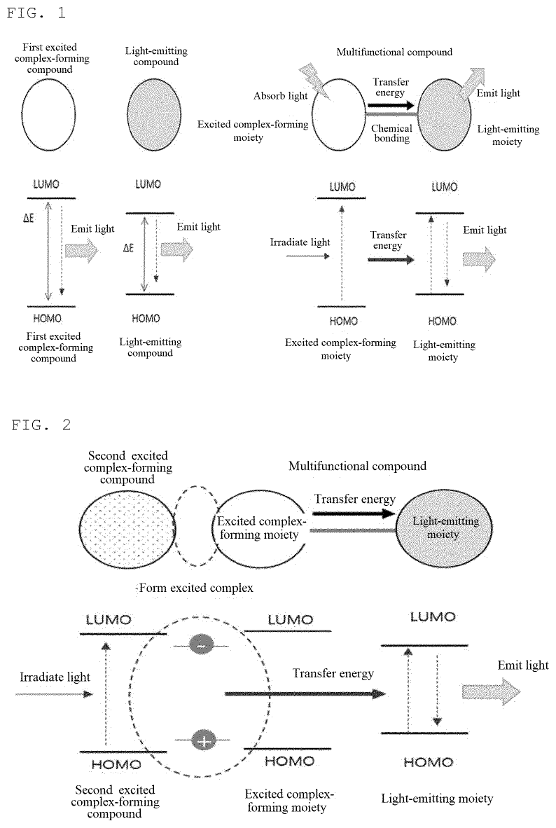

FIG. 1 is a diagram illustrating a working mechanism of the multifunctional compound.

FIG. 1 shows a multifunctional compound formed by linking the first excited complex-forming compound having large HOMO-LUMO gap energy and the light-emitting compound having relatively small HOMO-LUMO gap energy through chemical bonding. When the excited complex-forming moiety, which is induced from the first excited complex-forming compound in the multifunctional compound, is excited, energy is transferred to the light-emitting moiety induced from the light-emitting compound. This may be identified by comparing absorption spectrum and emission spectrum of Compound 1 that is the first excited complex-forming compound, Compound 2 that is the light-emitting compound, and Compound 3 that is the multifunctional compound of FIG. 3.

The phenomenon of the excited complex energy being transferred from the excited complex made by interaction between the excited complex-forming moiety and the (second) excited complex-forming compound to the light-emitting moiety may be identified by manufacturing an organic light-emitting diode. In other words, when charges are injected into a light-emitting layer of an organic light-emitting diode, the excited complex-forming moiety and the (second) excited complex-forming compound inside the multifunctional compound make an excited complex first, and energy of this excited complex is transferred to the light-emitting moiety through the excited complex moiety. When the energy of the excited complex formed in the excited complex is larger than the energy of the light-emitting moiety, the excited complex energy is transferred to the light-emitting moiety.

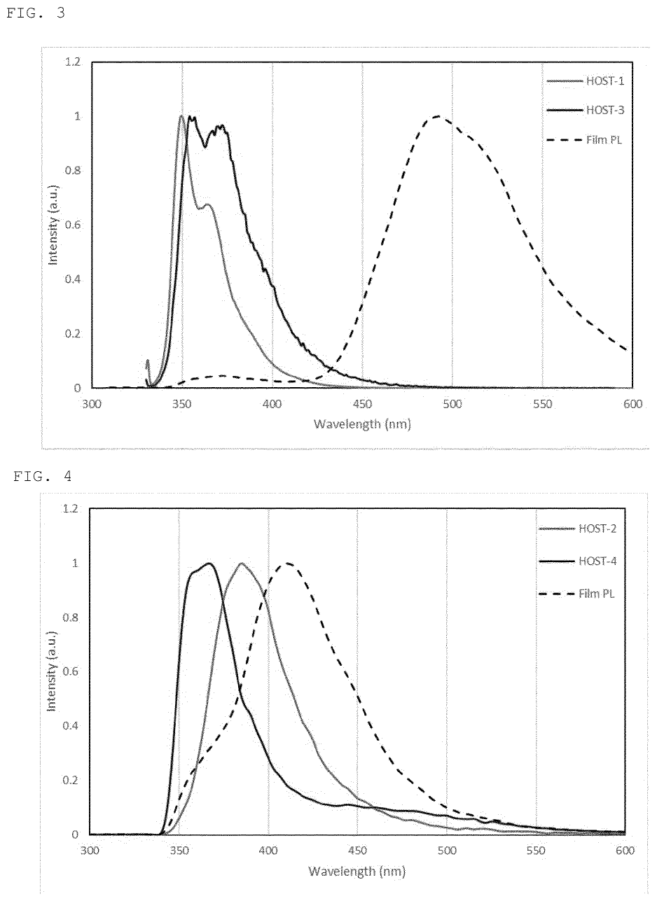

FIG. 2 schematically illustrates a mechanism in which excited energy of the excited complex is transferred between the moieties in the multifunctional compound to emit light in an organic light-emitting diode according to one embodiment of the present disclosure.

The excited complex-forming moiety or the (second) excited complex-forming compound absorbs energy from the outside to form an excited complex, and excited energy of this excited complex is transferred to the light-emitting moiety linked through chemical bonding, and a phenomenon of light emission occurs in the light-emitting moiety.

In more detail, when charges are injected into a light-emitting layer including the excited complex-forming moiety of the multifunctional compound inside an organic light-emitting diode, the excited complex-forming moiety and the (second) excited complex-forming compound included in the organic light-emitting diode so as to be adjacent thereto interact to form an excited complex, and energy of the excited complex formed as above is transferred to the light-emitting moiety that is present very close within one molecule of the multifunctional compound. Such an energy transfer between moieties in the multifunctional compound is performed with high efficiency and at a high rate since the distance r approaches almost 0 in Mathematical Formulae 1 and 2, which significantly increases the rate constant. The excited complex energy is transferred to the light-emitting moiety, and the light-emitting moiety may emit light with minimal energy loss, and as a result, the multifunctional compound may implement a mechanism capable of emitting light with high efficiency using the excited complex energy, and an effect of improving energy efficiency is obtained therefrom.

As the organic light-emitting diode including the multifunctional compound uses an excited complex, energy is effectively transferred between moieties in the multifunctional compound while having an advantage of reducing an energy difference between a singlet and a triplet, and as the organic light-emitting diode including the multifunctional compound includes the light-emitting moiety, high quantum efficiency may be obtained by efficiently transferring energy while readily implementing a deep blue color.

The multifunctional compound is not limited to the application of implementing a blue color, and may be applied to emissions of all green, red and near infrared light.

The light-emitting moiety may be induced from a light-emitting material (referred to as light-emitting compound in the present specification) capable of emitting light by electron migration in an organic light-emitting diode.

The light-emitting compound (light-emitting material) may be a compound that may be commonly used as a dopant in an organic light-emitting diode. A dopant capable of implementing a desired color is selected as the light-emitting compound depending on the purpose, and the light-emitting moiety may be induced therefrom.

In one embodiment, the light-emitting moiety may have a conjugated structure with quantum efficiency of 50% or greater in a visible wavelength region of 400 nm to 700 nm.

In one embodiment, the light-emitting moiety may have a conjugated structure with quantum efficiency of 0.5% or greater in a near-infrared wavelength region of 700 nm to 2500 nm.

In one embodiment, ring A may be represented by any one of the following C-1 to C-24 in the multifunctional compound. However, when Z and Q are a single bond in Chemical Formula 1, ring A is not C-8, C-10, C-11, C-17, C-20, C-22 or C-23.

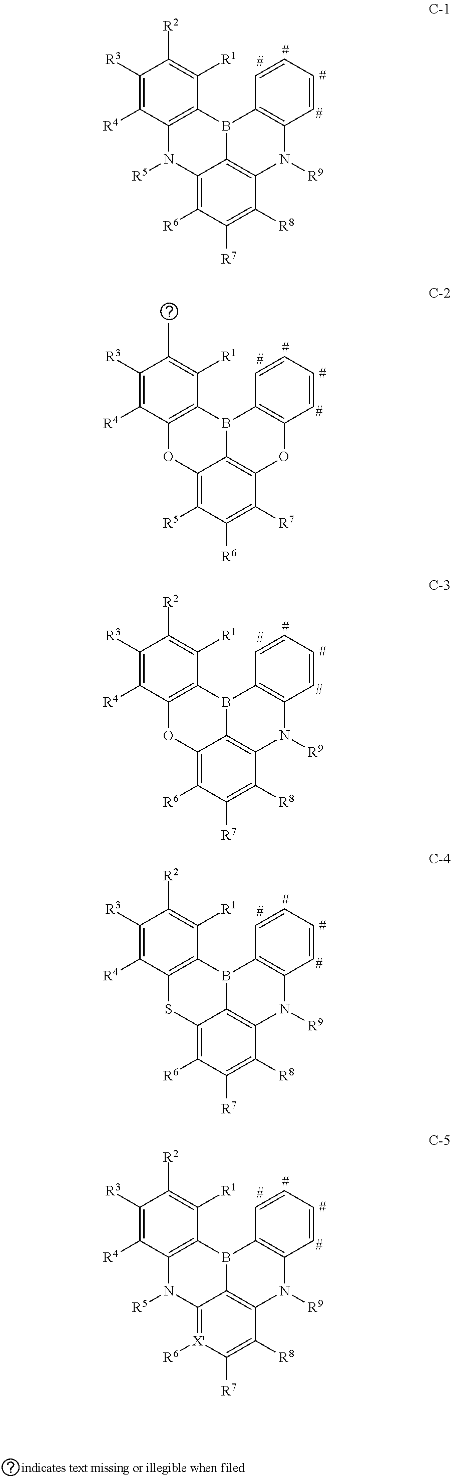

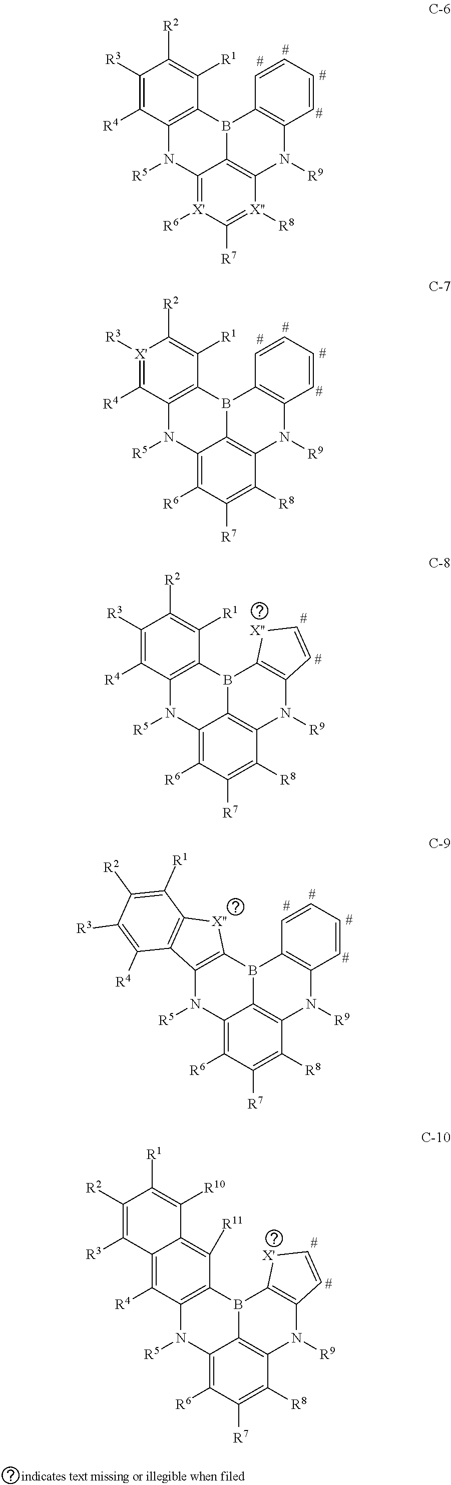

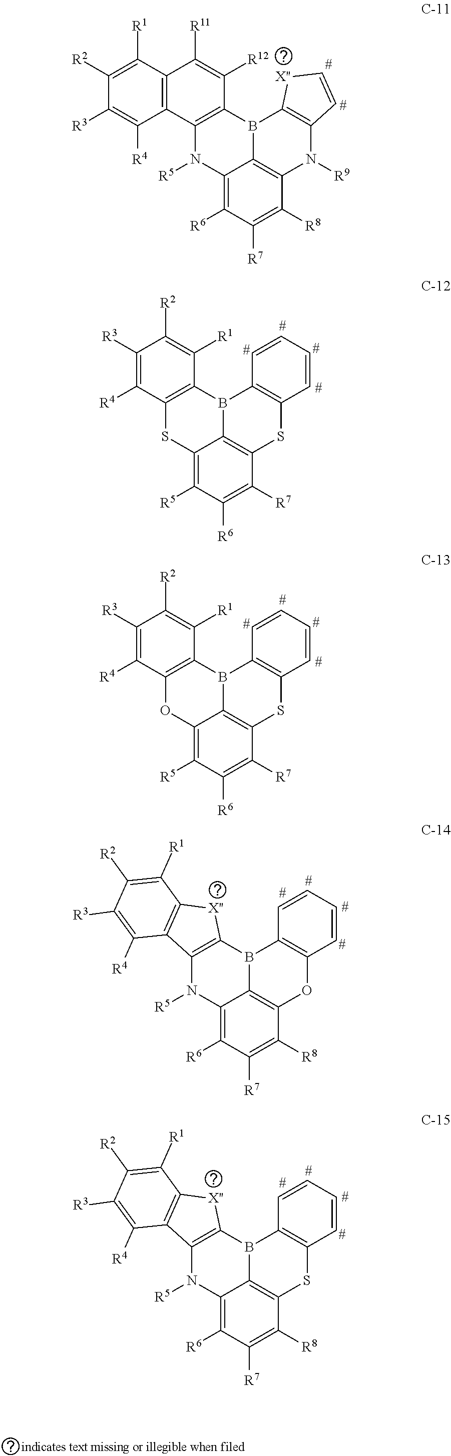

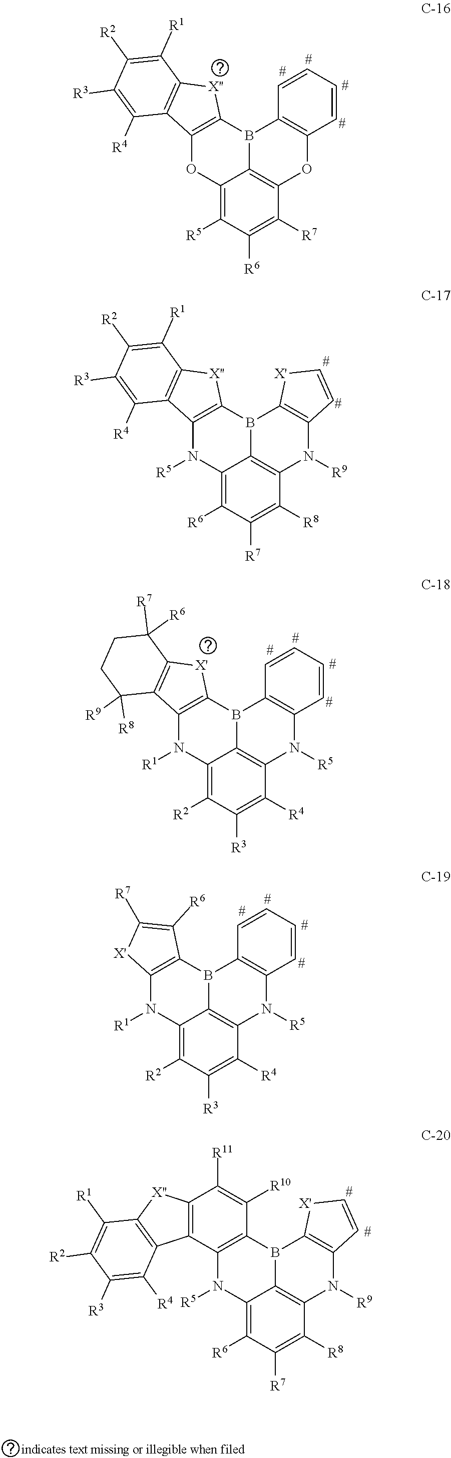

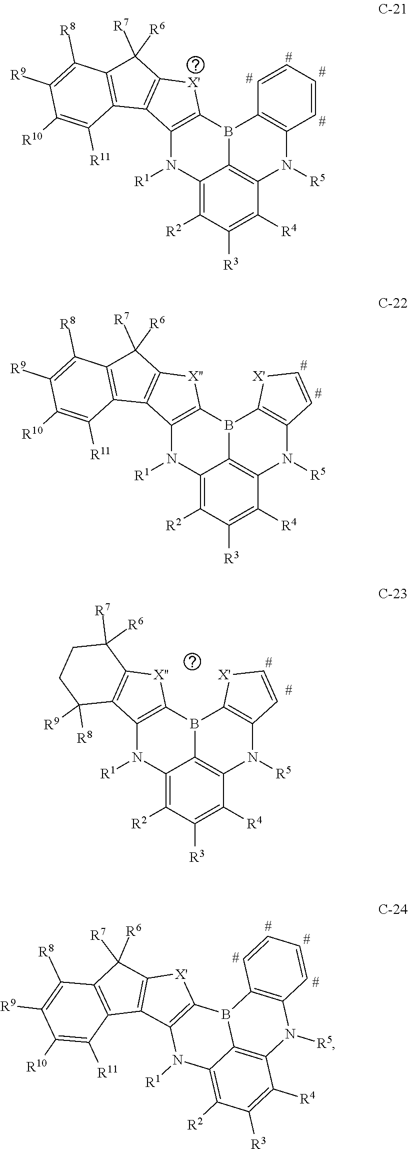

In C-1 to C-24, two adjacent #s among the positions indicated by #correspond to J or L in ring A of Chemical Formula 1,
R¹ to R¹¹ are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹ to R¹¹ may be linked to each other to form a ring,
X′s are each independently O, S, Se, C, Si, C—(Ar³)₂, Si—(Ar³)₂ or N—Ar³, Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar³s, the plurality of Ars may be linked to each other to form a ring,
X″s are each independently N, O, S or Se, and
the second additional substituent has the same definition as the second additional substituent defined in Chemical Formula 1.

In C-1 to C-24, when at least two of R¹ to R¹¹ are linked to each other to form a ring, such a ring includes a fused ring. In addition, when two of R¹ to R¹¹ are linked, it includes a case in which any one of the linked two is hydrogen, and as the hydrogen is eliminated, the other one of the linked two is directly linked due to the reduction of the ring to which the hydrogen is linked.

The light-emitting mechanism of the light-emitting moiety may include fluorescence that light is emitted from a singlet, phosphorescence that light is emitted from a triplet, and thermally activated delayed fluorescence that light is emitted by transferring energy from a triplet to a singlet.

In one embodiment, the second excited complex-forming compound may not form an excited complex with the light-emitting moiety. When the light-emitting moiety is capable of forming an excited complex with the second excited complex-forming compound, it may affect an emission wavelength of the light-emitting moiety. It is due to the fact that, when an emission wavelength of the light-emitting moiety changes, it may be difficult to apply properties of a light-emitting compound known in the art to the light-emitting moiety when designing color implementation, or, when a desired light-emitting compound is to be used to implement a specific color, it may be difficult to implement a desired color as an emission wavelength of the light-emitting moiety changes.

In one embodiment, the excited complex-forming moiety may have band gap energy of 1 eV to 4.7 eV, and the light-emitting moiety may have band gap energy of 0.5 eV to 3.5 eV.

In one embodiment, a difference in the band gap energy between the excited complex-forming moiety and the light-emitting moiety may be within 2 eV.

In one embodiment, a difference between the HOMO energy level of the excited complex-forming moiety and the HOMO energy level of the light-emitting moiety may be within 1.9 eV.

In one embodiment, a difference between the LUMO energy level of the excited complex-forming moiety and the LUMO energy level of the light-emitting moiety may be within 1.9 eV.

The HOMO energy may be measured using methods such as cyclic voltammetry (CV), ultraviolet photoelectron spectroscopy (UPS) and AC2, and the LUMO energy may be measured using UV absorption spectrum or cyclic voltammetry (CV).

In one embodiment, Chemical Formula 1 may be any one of chemical formulae represented by the following B-1 to B-32.

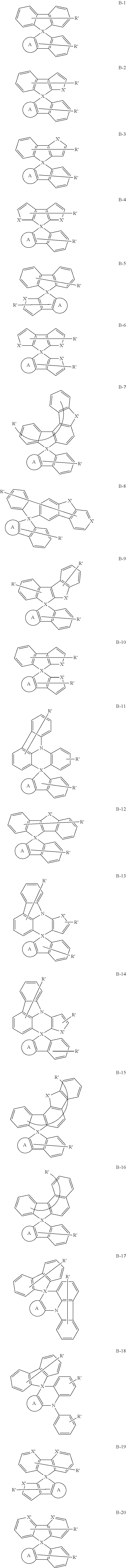

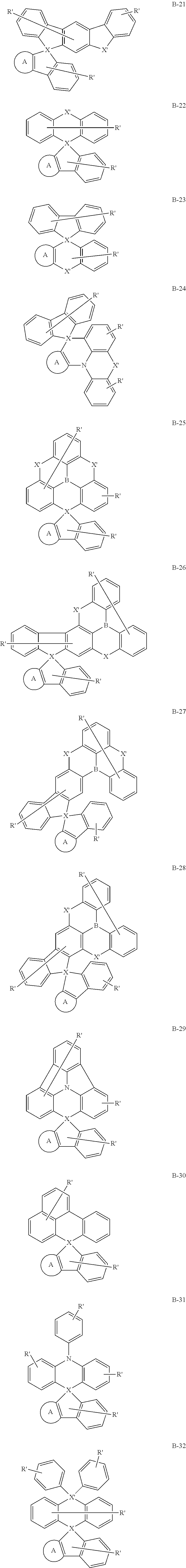

In B-1 to B-32,
ring A has the same definition as in Chemical Formula 1,
X is C, Si, Ge, Sn or Pb,
X′s are each independently O, S, Se, C, Si, C—(Ar³)₂, Si—(Ar³)₂ or N—Ar³, and Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar³s, the plurality of Ars may be linked to each other to form a ring,
R′s exist in the numbers according to a stoichiometric ratio, and are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two R′s may be linked to each other to form a ring, and
the second additional substituent has the same definition as the second additional substituent defined in Chemical Formula 1.

In B-1 to B-32, when at least two R′s are linked to each other to form a ring, such a ring includes a fused ring. In addition, when two of R′s are linked, it includes a case in which any one of the linked two R′s is hydrogen, and as the hydrogen is eliminated, the other R′ of the linked two R′s is directly linked due to the reduction of the ring to which the hydrogen is linked.

The first excited complex-forming compound (the excited complex-forming moiety in the multifunctional compound is induced therefrom) and the second excited complex-forming compound are, as described above, compounds capable of forming an excited complex, and as a result, the excited complex-forming moiety and the second excited complex-forming compound form an excited complex. The excited complex may be formed between an electron donor molecule having small ionization energy and an electron acceptor molecule having large electron affinity.

Accordingly, the excited complex-forming moiety (or the first excited complex-forming compound) and the second excited complex-forming compound may be in a relationship of a pair of electron donor molecule and electron acceptor molecule. For example, the excited complex-forming moiety (or the first excited complex-forming compound) and the second excited complex-forming compound may be an electron donor molecule and an electron acceptor molecule, respectively, or vice versa.

In one embodiment, the excited complex-forming moiety may be an electron donor or an electron acceptor including an atom having at least one unshared electron pair.

In the multifunctional compound in one embodiment, at least one of Y⁶ to Y¹⁵ and Z is an atom having an unshared electron pair included in a wave function of HOMO or LUMO of the excited complex-forming moiety; or
at least one of Y⁶ to Y¹⁵ has R represented by the following Chemical Formula 5 or the following Chemical Formula 6.

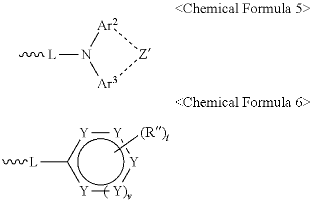

In Chemical Formula 5 and Chemical Formula 6,
L′ is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof,
Z′ is not present, represents a single bond, or is one atom selected from the group consisting of Group IIIA, Group IVA, Group VA and Group VIA elements, and when Z′ is an atom, it may have a substituent selected from hydrogen, alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a third additional substituent, heteroaryl having 2 to 30 carbon atoms unsubstituted or substituted with a third additional substituent, and combinations thereof according to a stoichiometric ratio,
Ar² and Ar³ are each independently alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, or heteroaryl having 2 to 30 carbon atoms unsubstituted or substituted with a third additional substituent, and Ar² and Ar³ may be each independently linked to L′ or the second additional substituent to form a fused ring,
t is an integer of 0 to 5,
v is 0 or 1,
R″s are each independently selected from hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 6 to 30 carbon atoms, aryl phosphine oxide having 6 to 30 carbon atoms, and combinations thereof, and herein, at least two of R′s may be linked to each other to form a ring, the third additional substituent is selected from alkyl having 1 to 30 carbon atoms,
cycloalkyl having 3 to 30 carbon atoms, heterocycloalkyl having 2 to 30 carbon atoms, ally having 3 to 30 carbon atoms, aryl having 6 to 30 carbon atoms, heteroaryl having 2 to 30 carbon atoms, alkyl amine having 1 to 30 carbon atoms, cycloalkyl amine having 3 to 30 carbon atoms, heterocycloalkyl amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof,
Ys are each independently nitrogen, oxygen, sulfur or carbon,
[symbol] represents a linking site,
however, in Chemical Formula 6, L′ or R″ includes at least one atom having an unshared electron pair included in a wave function of HOMO or LUMO of the excited complex-forming moiety, or at least one of Ys is nitrogen, oxygen or sulfur.

In one embodiment, the multifunctional compound may include at least one deuterium.

One embodiment of the present disclosure provides an organic light-emitting diode including:
a first electrode; a second electrode; and a light-emitting layer disposed between the first electrode and the second electrode; and
further including or not including an organic layer adjacent to any one or both surfaces of the light-emitting layer,
in which the light-emitting layer includes the multifunctional compound, and
the light-emitting layer or the adjacent organic layer includes an excited complex-forming compound.

The organic light-emitting diode improves luminous efficiency by using the multifunctional compound capable of increasing a rate constant value related to an energy transfer rate.

The organic light-emitting diode exhibits high quantum efficiency while implementing a deep blue color.

Detailed description on the multifunctional compound is the same as the description stated above.

The multifunctional compound is represented by the following Chemical Formula 1.

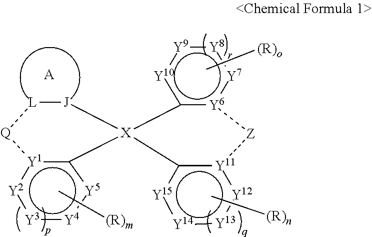

In Chemical Formula 1,
ring A is a fused ring represented by the following Chemical Formula 2, the following Chemical Formula 3 or the following Chemical Formula 4,
L represents a linking site in ring A, and L is linked to Q; or Y¹ when Q is not present,
J represents another linking site in ring A, and J is linked to X,
X is C, Si, Ge, Sn or Pb,
Q is not present, represents a single bond, or is one atom selected from the group consisting of Group IIIA, Group IVA, Group VA and Group VIA elements,
when Q is not present, L in ring A is not linked to Y¹,
when Q is a single bond, a single bond directly linking L in ring A and Y¹ is formed to form a 5-membered ring including X,
when Q is any one atom of the elements defined above, a 6-membered ring including X is formed, and the atom may have a substituent selected from the group consisting of alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a first additional substituent, heteroaryl having 2 to 30 carbon atoms unsubstituted or substituted with a first additional substituent, and combinations thereof according to a stoichiometric ratio, and the substituent may be linked to Y² or R that is linked to Y² to form a fused ring or linked to ring A to form a fused ring,
Y¹ to Y¹⁵ are each independently boron, carbon, nitrogen, oxygen, sulfur, Se or Te,
Z is not present, or a single bond, boron, oxygen, sulfur, —S(O₂)—, Se, C—(Ar¹)₂, POAr¹ or N—Ar¹, and herein, Ar¹ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar¹ may be linked to any one of Y⁷, Y¹², R linked to Y⁷ and R linked to Y¹² to form a fused ring,
when Z is not present, Y⁶ and Y¹¹ are not linked,
when Z is a single bond, Y⁶ and Y¹¹ are linked through the single bond,
however, when X is Si, Z is present as defined above,
m, n and o are each independently an integer of 0 to 5,
Rs are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms unsubstituted or substituted with a second additional substituent, aryloxy having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms unsubstituted or substituted with a second additional substituent, or aryl phosphine oxide having 6 to 30 carbon atoms unsubstituted or substituted with a second additional substituent, and at least two Rs present when m, n or o is 2 or greater may be linked to each other to form a ring, and
p, q and r each independently represent 0 or 1, and when p, q or r is 0, it means that a 5-membered ring is formed, and when p, q or r is 1, it means that a 6-membered ring is formed,

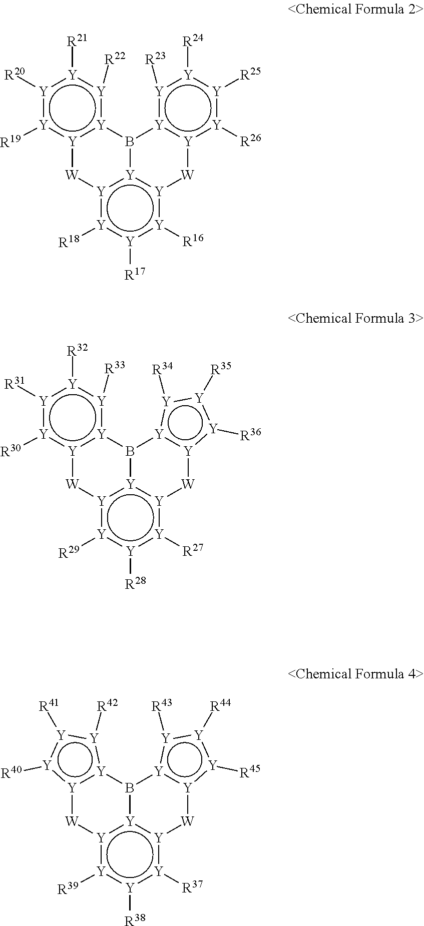

in Chemical Formula 2, Chemical Formula 3 and Chemical Formula 4,
Ys are each independently carbon, nitrogen, oxygen, sulfur, Se or Te, however, Y at the position corresponding to J in Chemical Formula 1 is carbon,
Ws are each independently oxygen, sulfur, Se, POAr² or N—Ar², Ar² is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar² may be linked to a ring fused to the fused ring including W to form a fused ring,
R¹⁶ to R⁴⁵ each independently represent a bond with X such that Y linked thereto corresponds to J in Chemical Formula 1; or a bond with Q such that Y linked thereto corresponds to L in Chemical Formula 1; or are hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹⁶ to R⁴⁵ may be linked to each other to form a ring,
the first additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, halogen, cyano, aryl having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms, heteroaryl having 2 to 30 carbon atoms, alkoxy having 1 to 30 carbon atoms, aryloxy having 6 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine oxide having 6 to 30 carbon atoms, and combinations thereof,
the second additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, alkoxy having 1 to 30 carbon atoms, halogen, cyano, carboxyl, carbonyl, amine, alkyl amine having 1 to 30 carbon atoms, cycloalkyl amine having 3 to 30 carbon atoms, heterocycloalkyl amine having 2 to 30 carbon atoms, nitro, alkyl silyl having 1 to 30 carbon atoms, cycloalkyl silyl having 3 to 30 carbon atoms, heterocycloalkyl silyl having 2 to 30 carbon atoms, alkoxy silyl having 1 to 30 carbon atoms, aryl silyl having 6 to 30 carbon atoms, aryl having 6 to 30 carbon atoms, aryl amine having 6 to 30 carbon atoms, heteroaryl having 2 to 30 carbon atoms, aryl phosphine oxide having 6 to 30 carbon atoms, aryl phosphinyl having 6 to 30 carbon atoms, alkyl phosphine oxide having 1 to 30 carbon atoms, cycloalkyl phosphine oxide having 3 to 30 carbon atoms, heterocycloalkyl phosphine oxide having 2 to 30 carbon atoms, alkyl sulfonyl having 1 to 30 carbon atoms, cycloalkyl sulfonyl having 3 to 30 carbon atoms, heterocycloalkyl sulfonyl having 2 to 30 carbon atoms, and combinations thereof,
positions of L and J in Chemical Formula 1 are according to the following (i) or (ii),
(i) Y linked to any one of R¹⁶ to R⁴⁵ corresponds to J in Chemical Formula 1, and another Y adjacent to Y corresponding to J corresponds to L in Chemical Formula 1; or,
(ii) any one of Ws is N—Ar², Ar² is aryl having 6 to 30 carbon atoms unsubstituted or substituted with a second additional substituent or heteroaryl having 2 to 30 carbon atoms unsubstituted or substituted with a second additional substituent, any one reduction of aryl or heteroaryl of Ar² is carbon and corresponds to J in Chemical Formula 1, and another reduction adjacent thereto corresponds to L in Chemical Formula 1,
however, in Chemical Formula 1, when Z and Q are both a single bond, the following case (a) or (b) is excluded:
(a) ring A in Chemical Formula 1 is Chemical Formula 3 or Chemical Formula 4, any one of R³⁴ to R³⁶ and R⁴⁰ to R⁴⁵ in Chemical Formula 3 or Chemical Formula 4 corresponds to L in Chemical Formula 1, and two Ws in ring A are both N—Ar²,
(b) a 5-membered ring is formed in which at least one of p and q in Chemical Formula 1 is 0, and two Rs linked to the 5-membered ring are linked to each other to form an unsubstituted 6-membered fused ring.

In the definition of Chemical Formula 1, when a substituent linked to Q is linked to Y² or R that is linked to Y² to form a fused ring, it includes a case in which R linked to Y² is hydrogen, and as R, the hydrogen, is eliminated, the substituent linked to Q is linked to Y².

In the definition of Chemical Formula 1, when Ar¹ is linked to any one of Y⁷, Y¹², R linked to Y⁷ and R linked to Y¹² to form a fused ring, it includes a case in which R linked to Y⁷ or R linked to Y¹² is hydrogen, and as R, the hydrogen, is eliminated, Ar¹ is linked to Y⁷ or Y¹².

When at least two Rs are linked to form a ring in Chemical Formula 1, such a ring includes a fused ring. In addition, when two Rs are linked, it includes a case in which any one R of the linked two is hydrogen, and as R, the hydrogen, is eliminated, the other R of the linked two is directly linked to any one of Y¹ to Y¹⁵ to which R, the hydrogen, is linked.

When at least two of R¹⁶ to R⁴⁵ are linked to form a ring in Chemical Formulae 2 to 4, such a ring includes a fused ring. In addition, when two of R¹⁶ to R⁴⁵ are linked, it includes a case in which any one of the linked two is hydrogen, and as the hydrogen is eliminated, the other one of the linked two is directly linked to Y to which the hydrogen is linked.

The multifunctional compound represented by Chemical Formula 1 is divided into an atom represented by X, a light-emitting moiety and an excited complex-forming moiety, the light-emitting moiety and the excited complex-forming moiety are linked through the atom represented by X, and the atom represented by X is X presented in Chemical Formula 1,
the light-emitting moiety includes ring A, a conjugated ring formed to include Y¹ to Y⁵, and Q in Chemical Formula 1,
the excited complex-forming moiety includes a conjugated ring formed to include Y⁶ to Y¹⁰, a conjugated ring formed to include Y¹¹ to Y¹⁵, and Z in Chemical Formula 1,
the excited complex-forming moiety forms an excited complex with the excited complex-forming compound, and
the light-emitting moiety emits light by receiving excited energy of the excited complex.

In the organic light-emitting diode in one embodiment, Chemical Formula 1 may be any one of chemical formulae represented by the following B-1 to B-32.

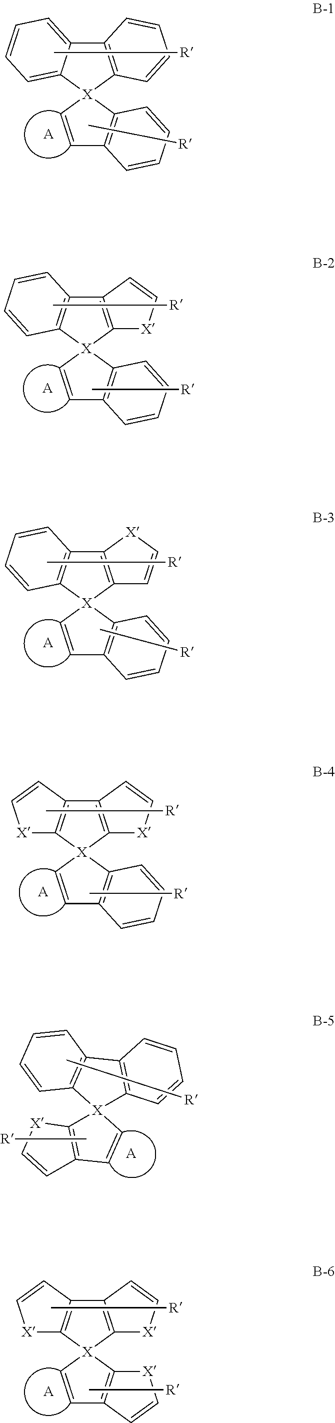

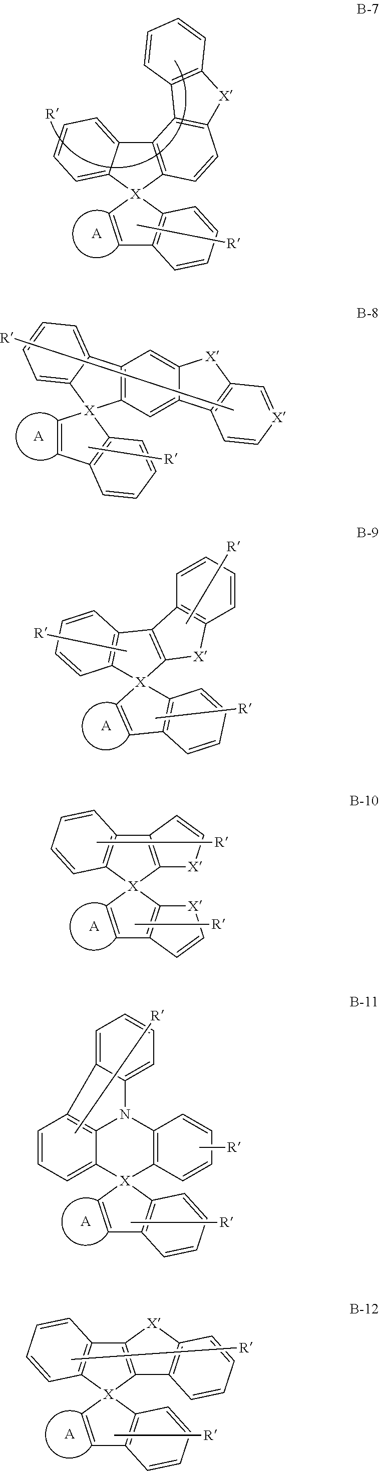

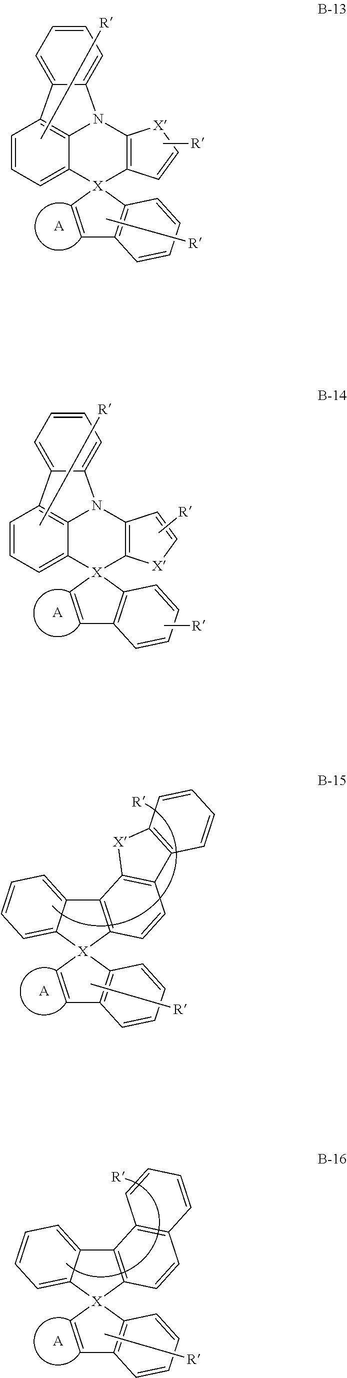

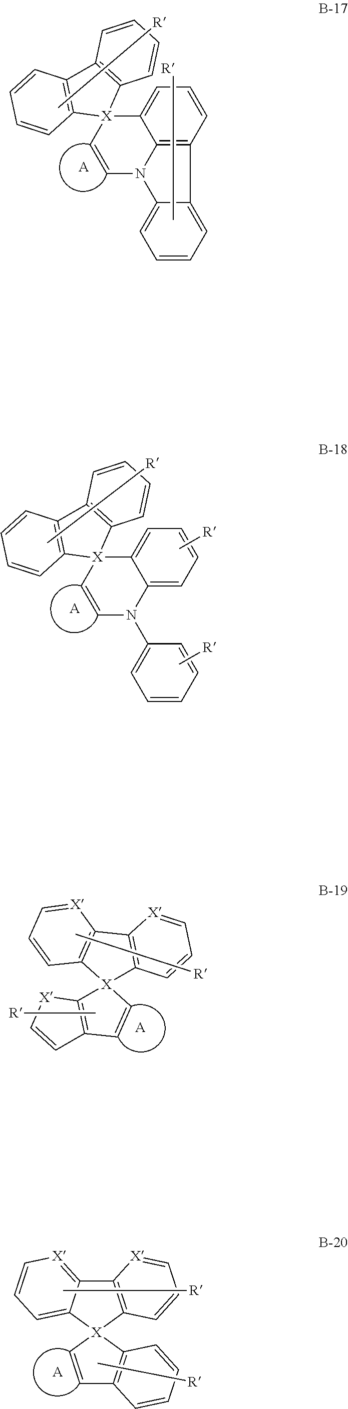

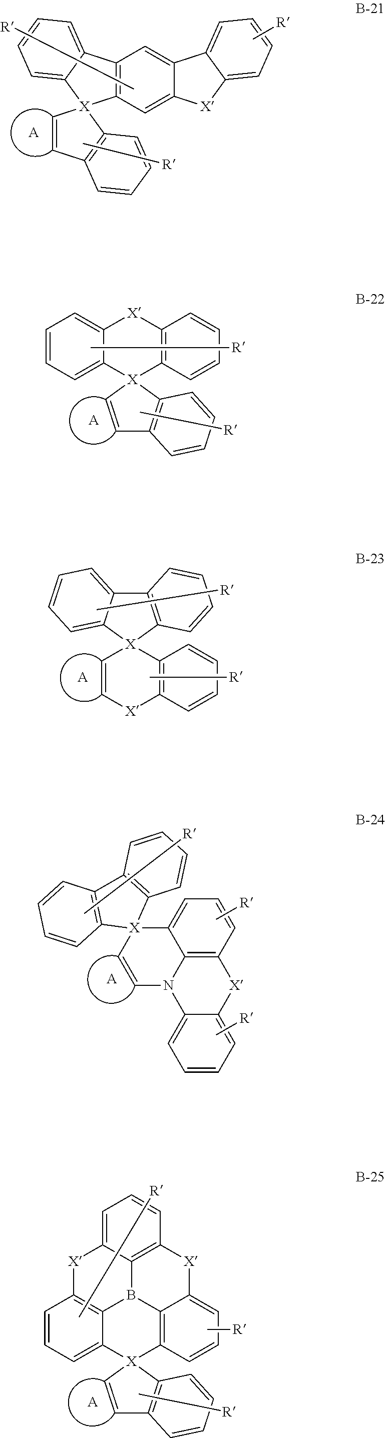

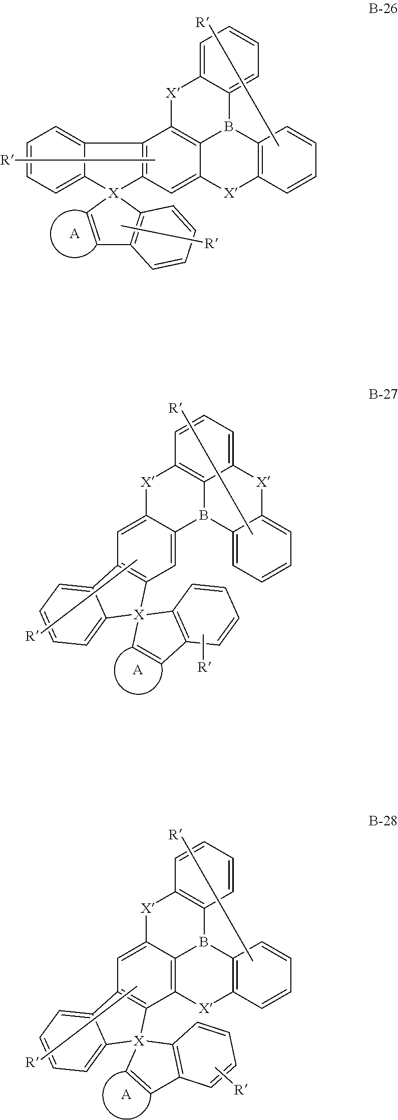

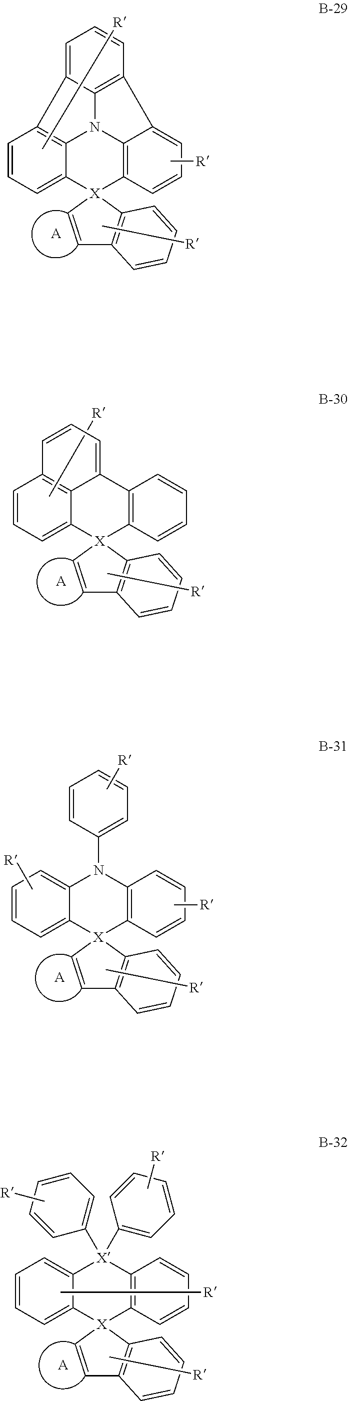

In B-1 to B-32,
ring A has the same definition as in Chemical Formula 1,
X is C, Si, Ge, Sn or Pb,
X′s are each independently O, S, Se, C, Si, C—(Ar³)₂, Si—(Ar³)₂ or N—Ar³, and Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar³s, the plurality of Ars may be linked to each other to form a ring,
R′s exist in the numbers according to a stoichiometric ratio, and are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two R′s may be linked to each other to form a ring, and
the second additional substituent has the same definition as the second additional substituent defined in Chemical Formula 1.

In B-1 to B-32, when at least two of R′s are linked to each other to form a ring, such a ring includes a fused ring. In addition, when two of R′s are linked, it includes a case in which any one of the linked two is hydrogen, and as the hydrogen is eliminated, the other R′ of the linked two is directly linked due to the reduction of the ring to which the hydrogen is linked.

In one embodiment, in the multifunctional compound represented by Chemical Formula 1 included in the light-emitting layer of the organic light-emitting diode, ring A is represented by any one of the following C-1 to C-24, however, when Z and Q are a single bond in Chemical Formula 1, ring A is not C-8, C-10, C-11, C-17, C-20, C-22 and C-23.

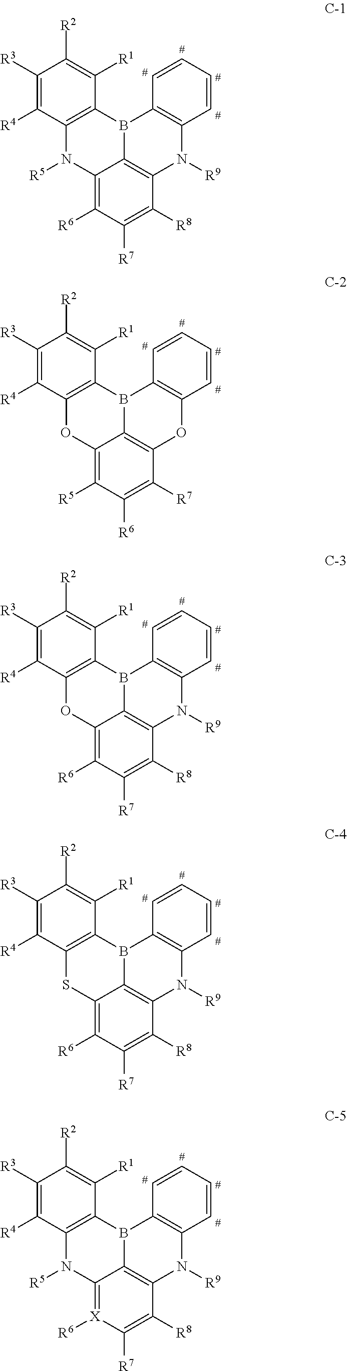

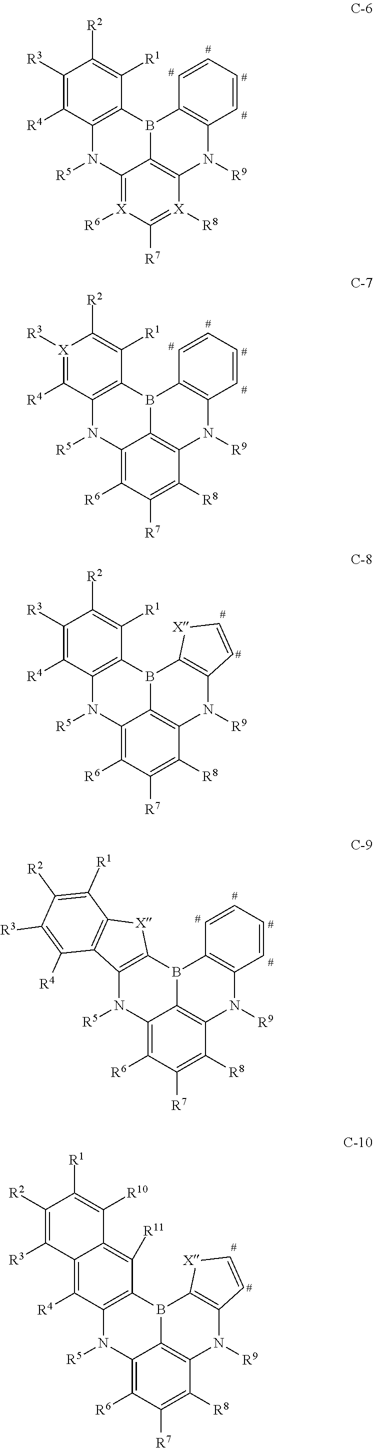

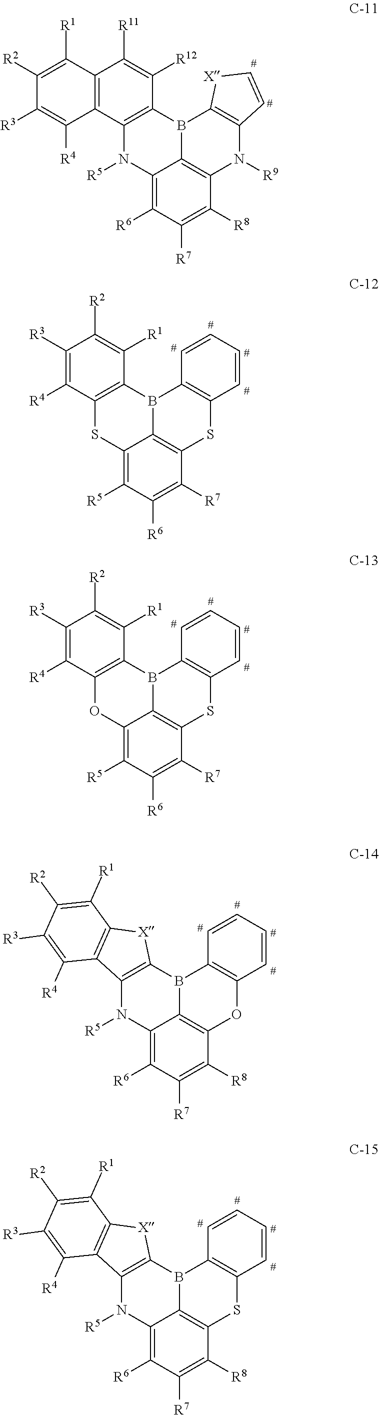

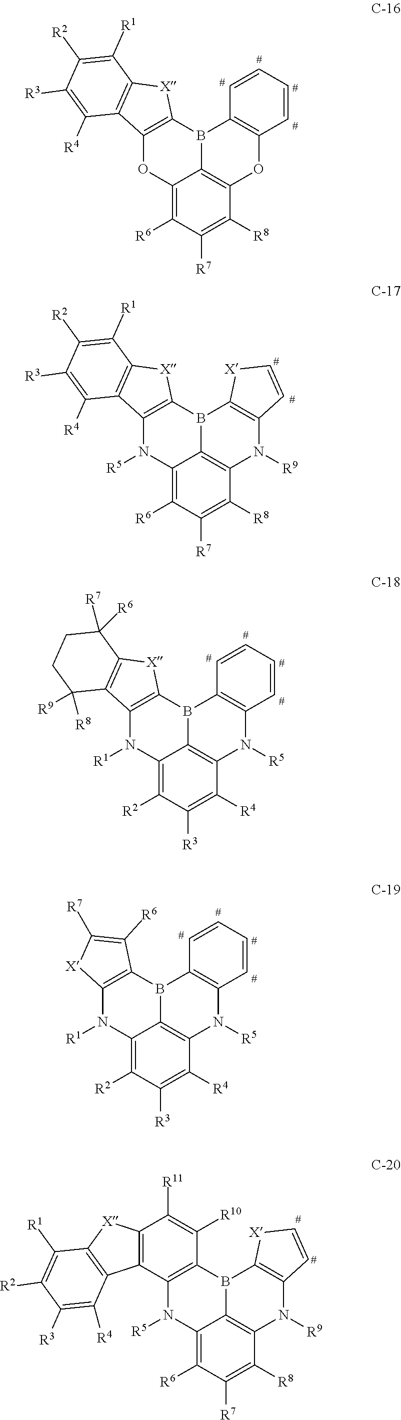

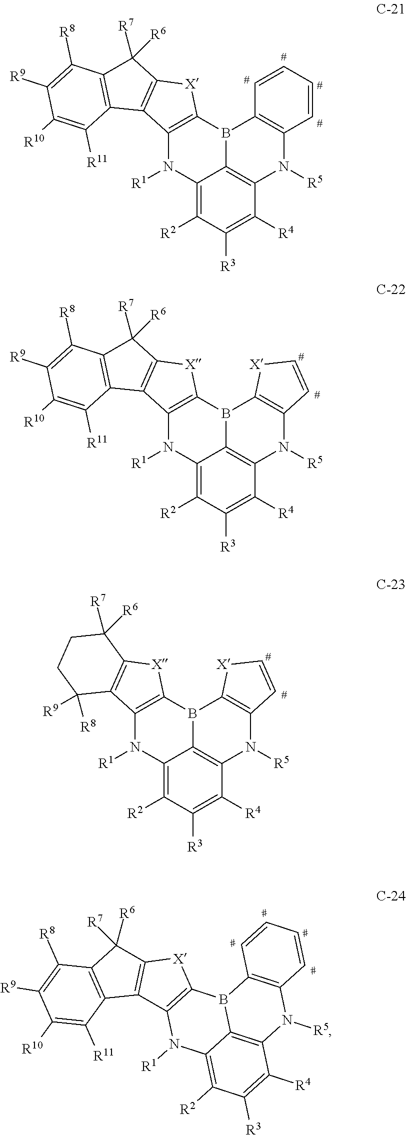

In C-1 to C-24,
two adjacent #s among the positions indicated by #correspond to J or L in ring A of Chemical Formula 1,
R¹ to R¹¹ are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹ to R¹¹ may be linked to each other to form a ring,
X′s are each independently O, S, Se, C, Si, C—(Ar³)₂, Si—(Ar³)₂ or N—Ar³, Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar³s, the plurality of Ars may be linked to each other to form a ring,
X″s are each independently N, O, S or Se, and
the second additional substituent has the same definition as the second additional substituent defined in Chemical Formula 1.

In C-1 to C-24, when at least two of R¹ to R¹¹ are linked to each other to form a ring, such a ring includes a fused ring. In addition, when two of R¹ to R¹¹ are linked, it includes a case in which any one of the linked two is hydrogen, and as the hydrogen is eliminated, the other one of the linked two is directly linked due to the reduction of the ring to which the hydrogen is linked.

In one embodiment, in the multifunctional compound included in the light-emitting layer of the organic light-emitting diode, the excited complex-forming moiety includes an atom having at least one unshared electron pair.

In one embodiment, in the multifunctional compound represented by Chemical Formula 1 included in the light-emitting layer of the organic light-emitting diode,
at least one of Y⁶ to Y¹⁵ and Z is an atom having an unshared electron pair included in a wave function of HOMO or LUMO of the excited complex-forming moiety; or
at least one of Y⁶ to Y¹⁵ has R represented by the following Chemical Formula 5 or the following Chemical Formula 6.

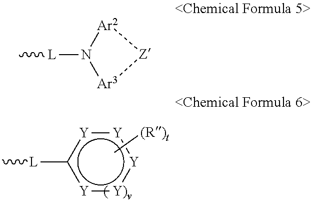

In Chemical Formula 5 and Chemical Formula 6,
L′ is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof,
Z′ is not present, represents a single bond, or is one atom selected from the group consisting of Group IIIA, Group IVA, Group VA and Group VIA elements, and when Z′ is an atom, it may have a substituent selected from hydrogen, alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a third additional substituent, heteroaryl having 2 to 30 carbon atoms unsubstituted or substituted with a third additional substituent, and combinations thereof according to a stoichiometric ratio,
Ar² and Ar³ are each independently alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, or heteroaryl having 2 to 30 carbon atoms unsubstituted or substituted with a third additional substituent, and Ar² and Ar³ may be each independently linked to L′ or the second additional substituent to form a fused ring,
t is an integer of 0 to 5,
v is 0 or 1,
R″s are each independently selected from hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 6 to 30 carbon atoms, aryl phosphine oxide having 6 to 30 carbon atoms, and combinations thereof, and herein, at least two R″s may be linked to each other to form a ring,
the third additional substituent is selected from alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms, heteroaryl having 2 to 30 carbon atoms, alkyl amine having 1 to 30 carbon atoms, cycloalkyl amine having 3 to 30 carbon atoms, heterocycloalkyl amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof,
Ys are each independently nitrogen, oxygen, sulfur or carbon,
[symbol] represents a linking site,
however, in Chemical Formula 6, L′ or R″ includes at least one atom having an unshared electron pair included in a wave function of HOMO or LUMO of the excited complex-forming moiety, or at least one of Ys is nitrogen, oxygen or sulfur.

In the organic light-emitting diode in one embodiment, the multifunctional compound may include at least one deuterium.

In one embodiment, the multifunctional compound may be any one of compounds represented by the following structural formulae.

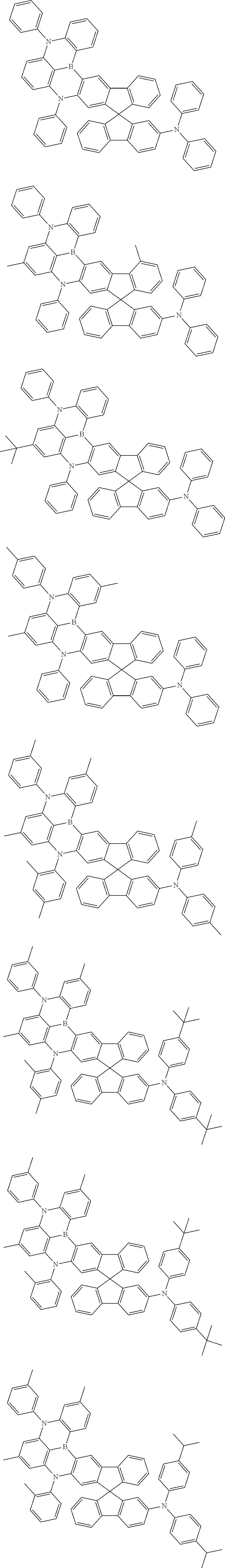

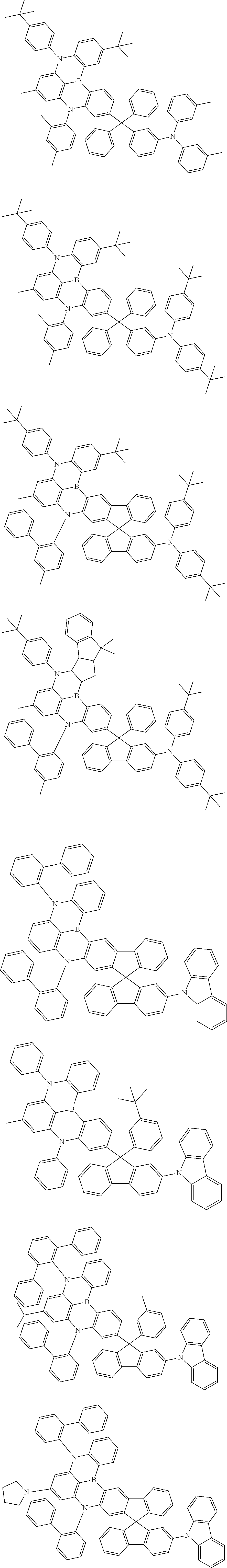

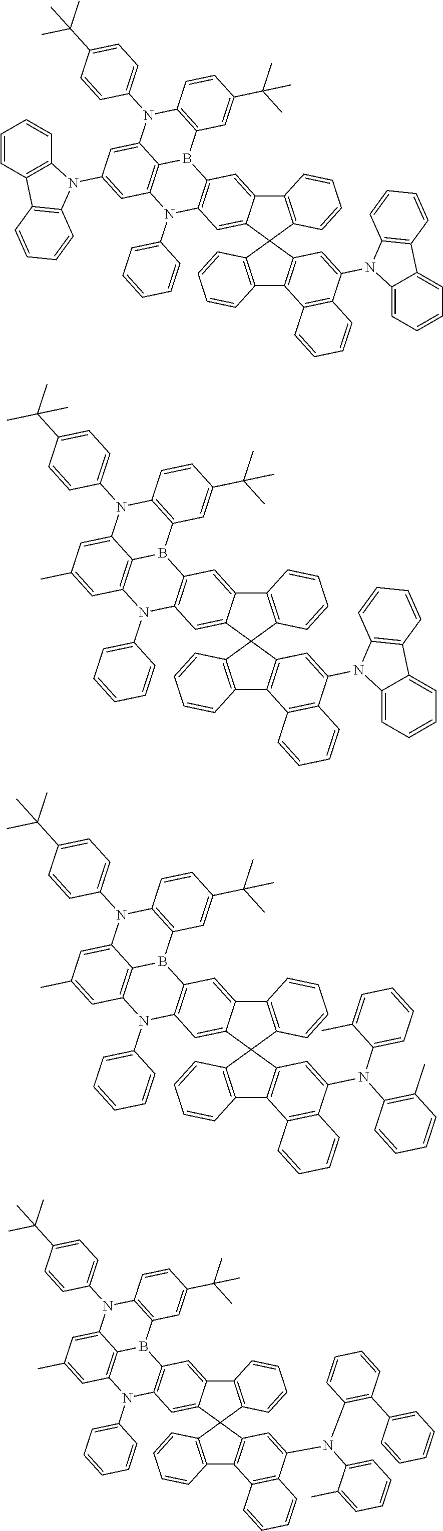

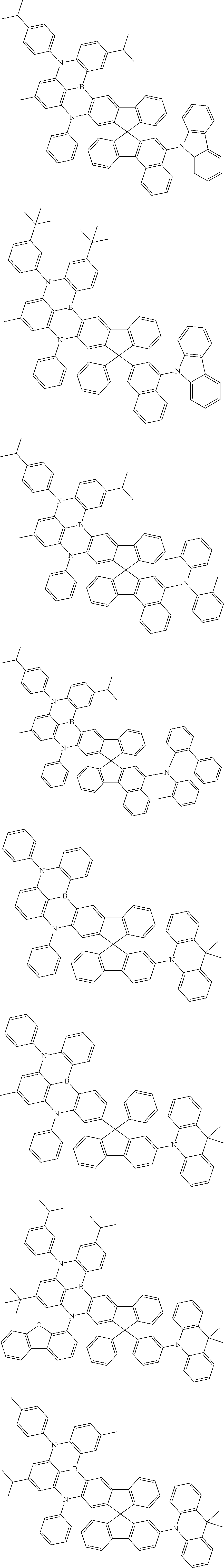

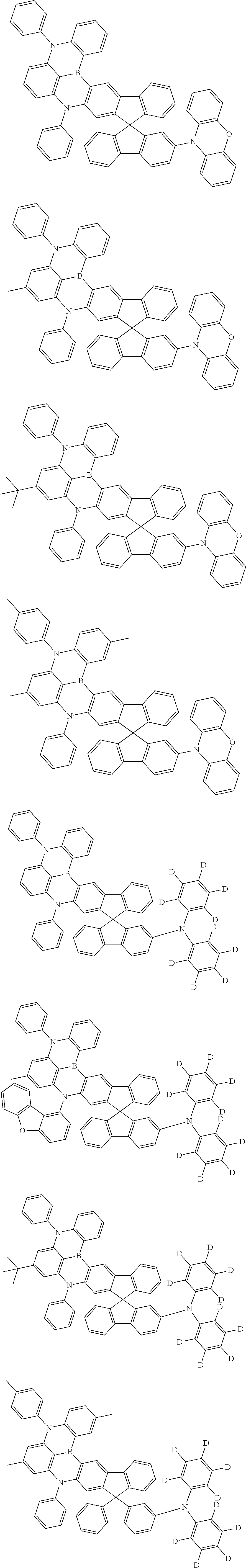

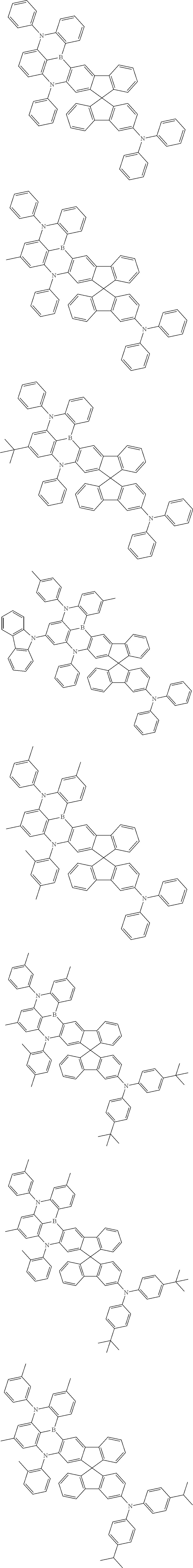

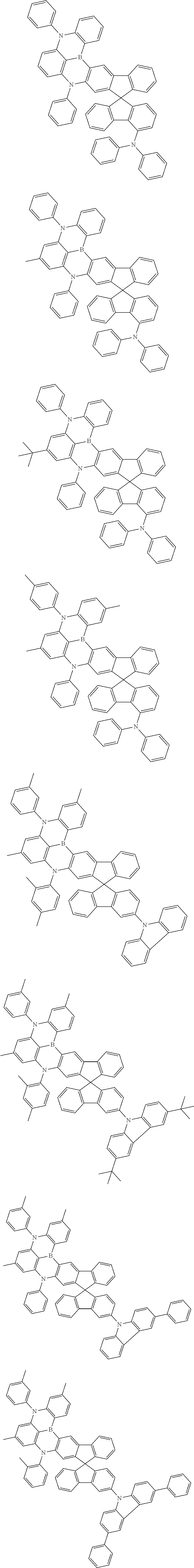

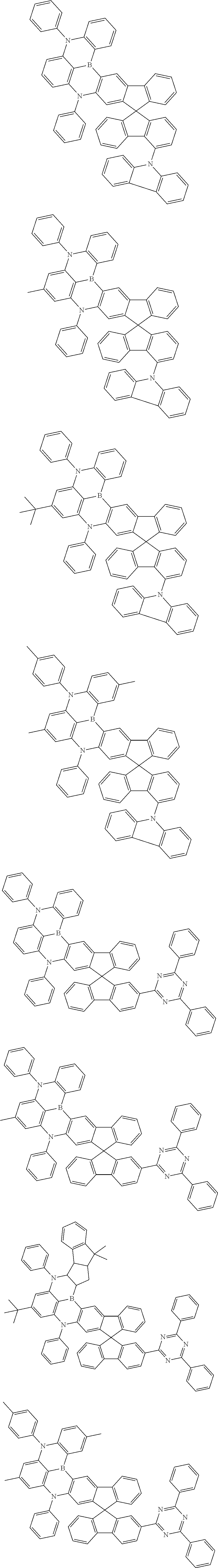

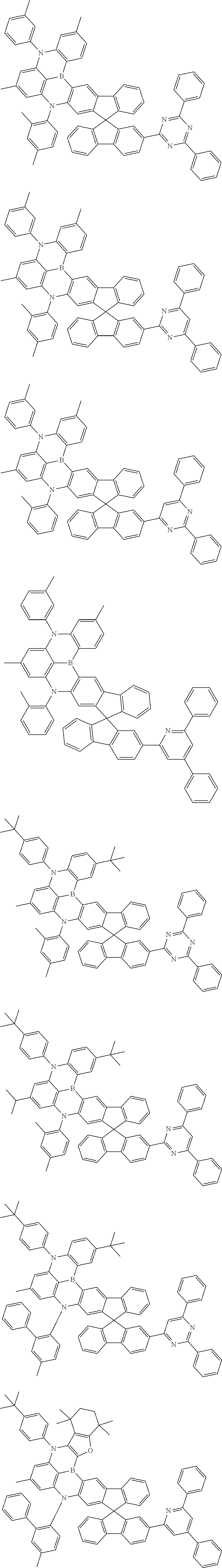

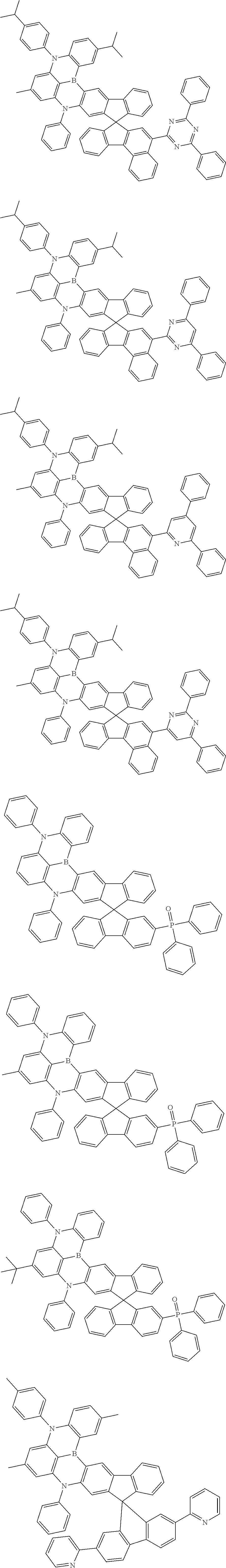

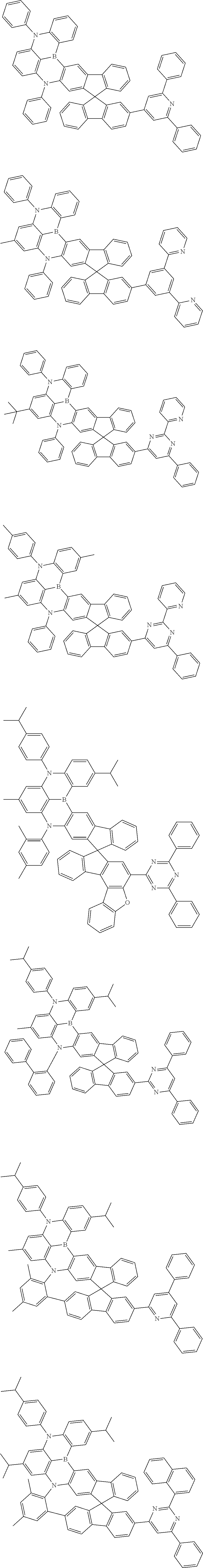

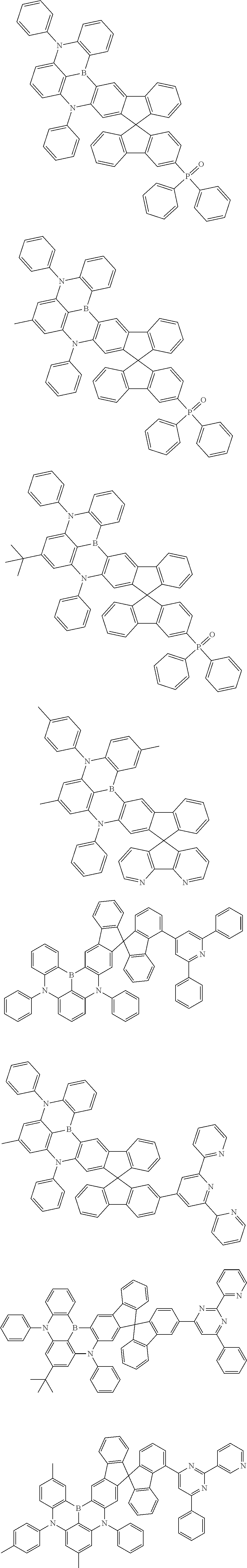

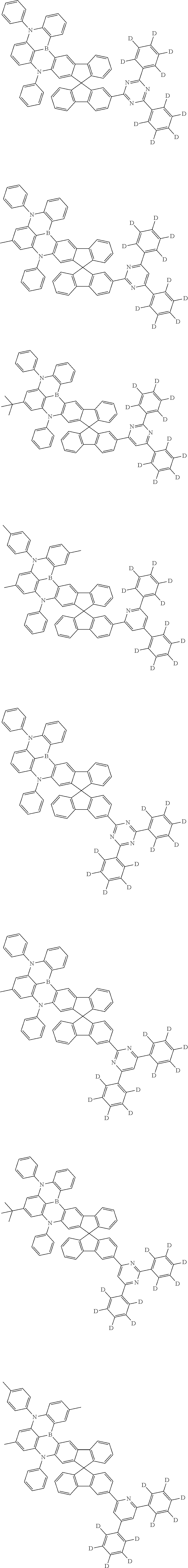

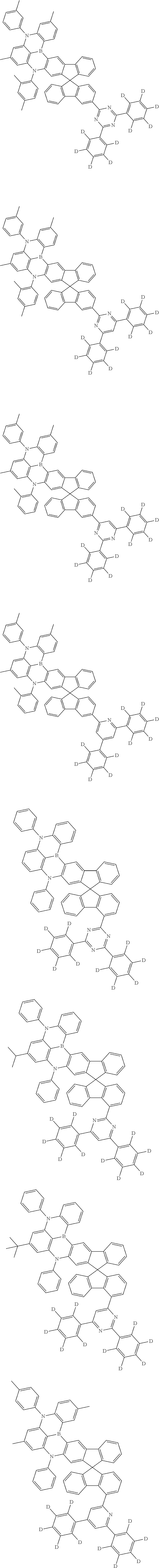

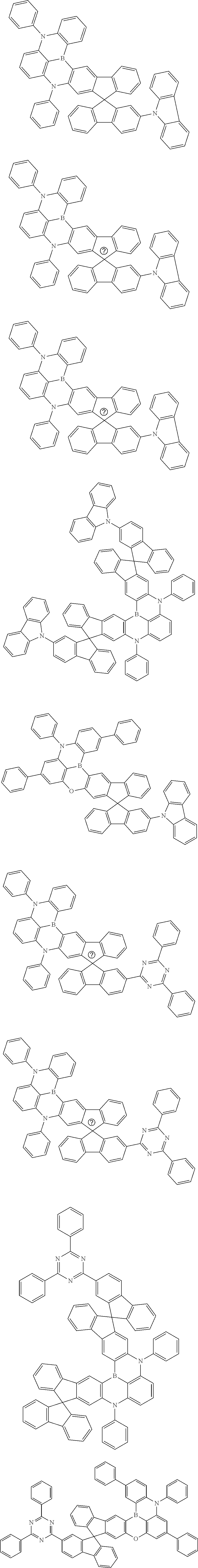

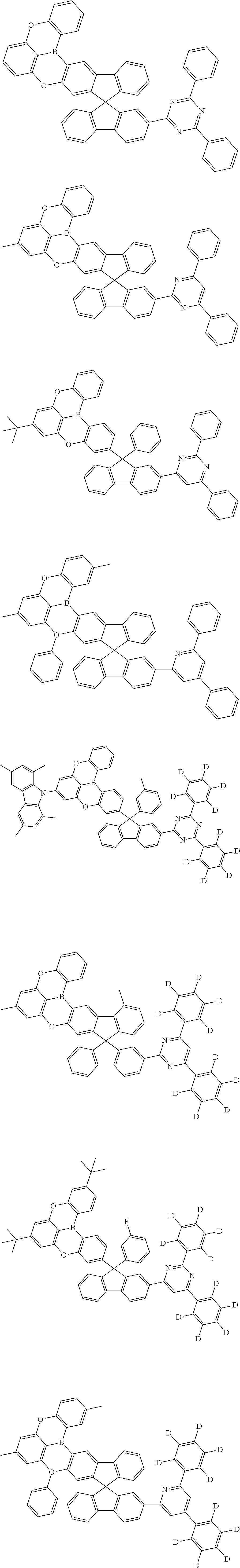

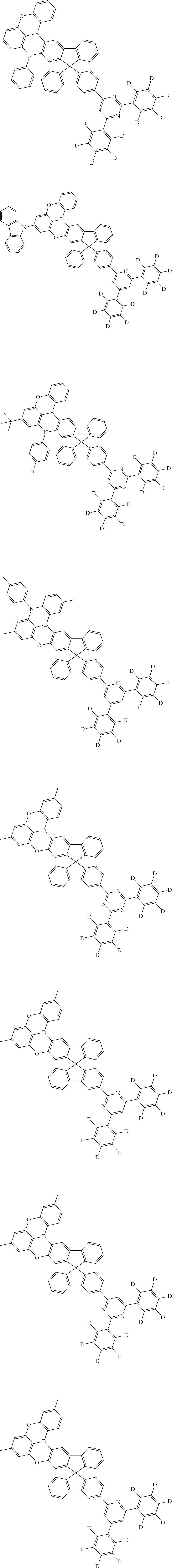

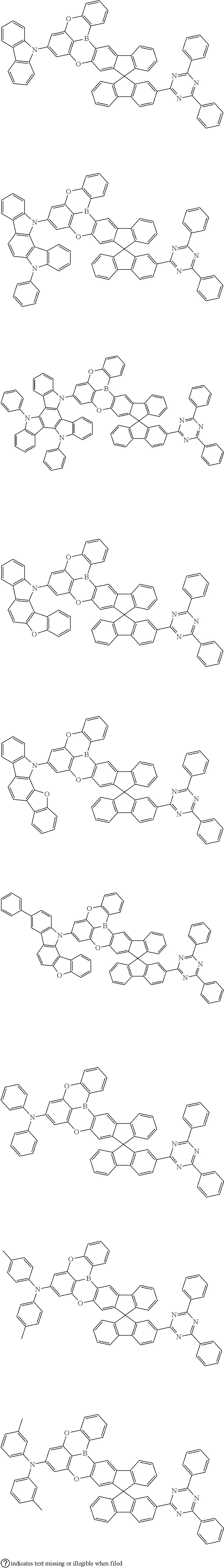

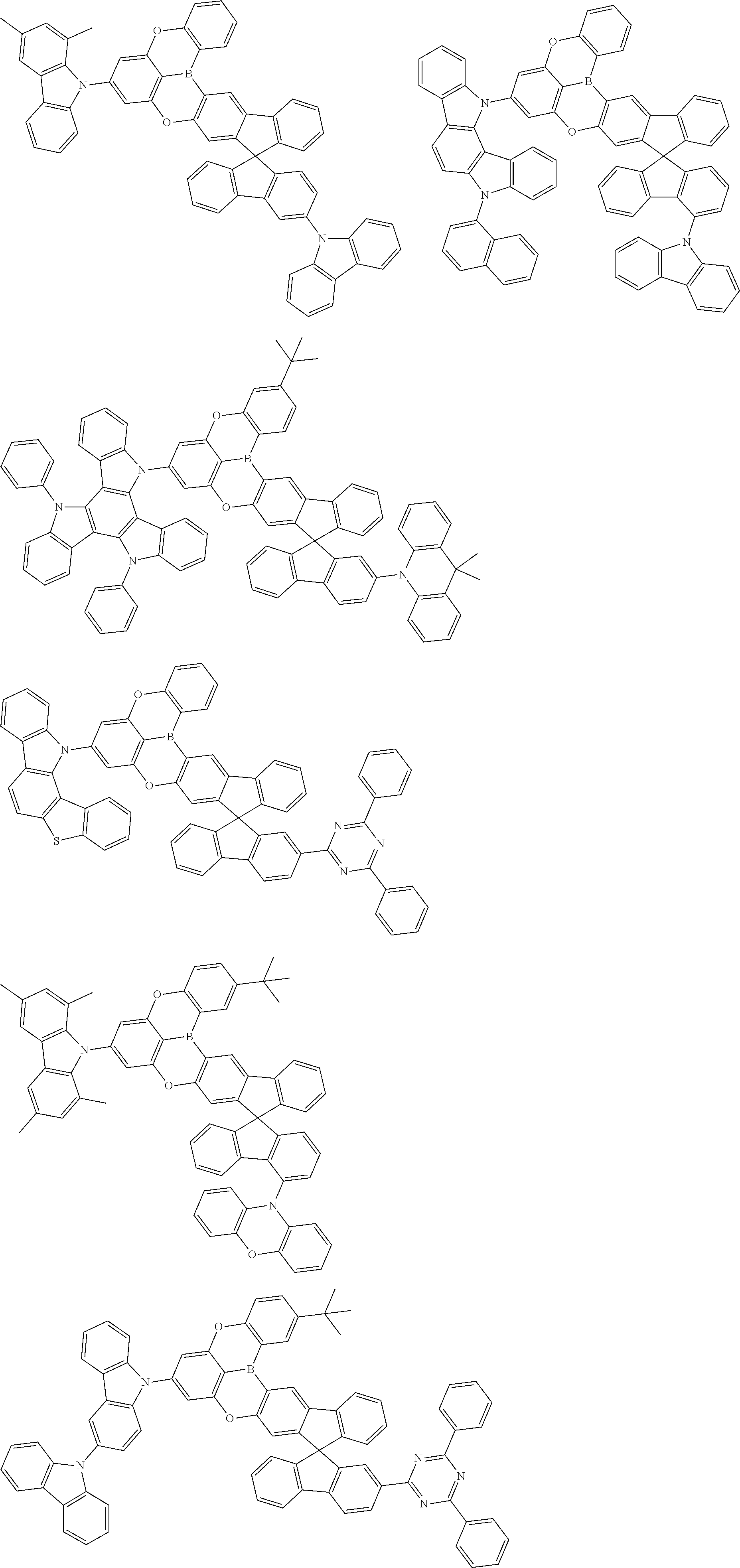

The organic light-emitting diode may include the multifunctional compound at a level equal to or higher than a common dopant content level. This means that the content of the light-emitting moiety may be the same as or higher than the dopant content level. For example, the content of the multifunctional compound may be the same as or higher than a common dopant content level in order to increase the excited complex-forming ratio between the excited complex-forming moiety of the multifunctional compound and the second excited complex-forming compound. The excited complex-forming moiety of the multifunctional compound is capable of efficiently preventing a concentration quenching phenomenon occurring due to the interaction between the light-emitting moieties, and therefore, it is highly likely that efficiency and color are not significantly affected even when the doping amount of the multifunctional compound increases. The ratio of the multifunctional compound in the light-emitting layer may be, for example, in a range of 1 mol % to 50 mol % based on all the materials forming the light-emitting layer, and the ratio may be higher depending on the application.

In one embodiment, the light-emitting layer may include at least two types of the multifunctional compound.

In one embodiment, the multifunctional compound may be used as the excited complex-forming compound.

Specifically, when employing an electron donor moiety as the excited complex-forming moiety and the multifunctional compound obtained by bonding the excited complex-forming moiety to the light-emitting moiety as a first multifunctional compound, and employing an electron acceptor moiety as the excited complex-forming moiety and the multifunctional compound obtained by bonding the excited complex-forming moiety to the light-emitting moiety as a second multifunctional compound, the first multifunctional compound and the second multifunctional compound included in the light-emitting layer have an excited complex formed between each of the electron acceptor moieties and the electron donor moieties, and may have the energy being transferred to the light-emitting moiety. In this case, one that emits light among the first multifunctional compound and the second multifunctional compound corresponds to the multifunctional compound, and the other one corresponds to the excited complex-forming compound.

The ratio of the excited complex-forming compound in the light-emitting layer may be, for example, in a range of 5 mol % to 95 mol % based on all the materials forming the light-emitting layer, and the ratio may be higher depending on the application.

In one embodiment, the light-emitting layer may further include at least one selected from the group consisting of a host, an additional dopant and combinations thereof.

The host may be a material generally known as a host material capable of forming a light-emitting layer.

The additional dopant may be a material known as a light-emitting material or a material generally known as a dopant doped as a light-emitting material in a light-emitting layer. The additional dopant performs a role of re-emitting by absorbing emission energy of the light-emitting moiety. Accordingly, the maximum emission wavelength energy of the additional dopant may be smaller than the highest emission wavelength energy of the light-emitting moiety. Emission of low energy may be obtained by using the additional dopant.

The highest emission wavelength energy means a wavelength having the largest photon energy in the emission spectrum. The highest emission wavelength is obtained from an onset value at the position where emission starts, and the maximum emission wavelength is obtained from the wavelength having the highest luminescence intensity.

The light-emitting layer may further include a phosphorescent material in order to further increase luminous efficiency of the light-emitting layer.

In one embodiment, the light-emitting layer may further include a phosphorescent material including Pt or Ir.

Compounds represented by the following structural formulae are examples of organometallic complexes commonly used as the phosphorescent material.

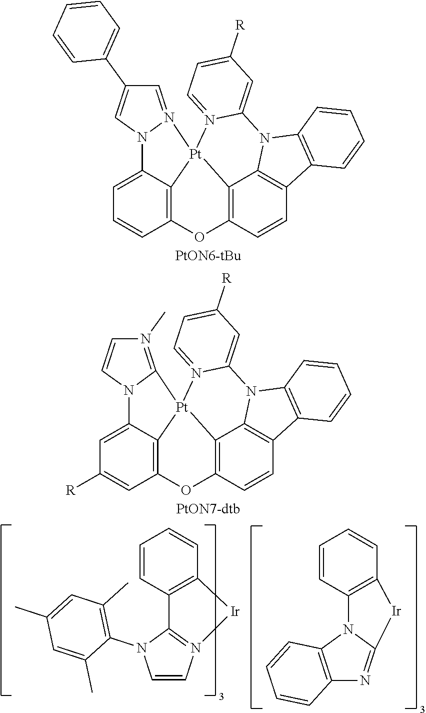

In the formulae, R may be alkyl having 1 to 20 carbon atoms, cycloalkyl having 3 to 20 carbon atoms, heterocycloalkyl having 2 to 20 carbon atoms, aryl having 6 to 30 carbon atoms, and the like.

The light-emitting layer may further include a delayed fluorescent material in order to further increase luminous efficiency of the light-emitting layer.

In one embodiment, the light-emitting layer may further include a delayed fluorescent material in which an energy difference between a singlet and a triplet is 0.3 eV or greater.

Compounds represented by the following structural formulae are examples of the delayed fluorescent material commonly used.

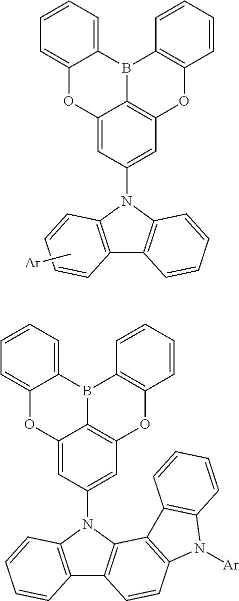

In the formulae, Ar may be alkyl having 1 to 20 carbon atoms, cycloalkyl having 3 to 20 carbon atoms, heterocycloalkyl having 2 to 20 carbon atoms, aryl having 6 to 30 carbon atoms, and the like.

The organic light-emitting diode may include one selected from the group consisting of a hole injection layer, a hole transport layer, an electron blocking layer, a hole blocking layer, an electron transport layer, an electron injection layer and combinations thereof as the organic layer.

In one embodiment, the organic light-emitting diode may sequentially include an anode, a hole injection layer (HIL), a hole transport layer (HTL), a light-emitting layer (EML), an electron transport layer (ETL) and a cathode.

The organic light-emitting diode may form the light-emitting layer including the multifunctional compound by a deposition process or a solution process.

The organic light-emitting diode may be a tandem-type organic light-emitting diode including a plurality of organic light-emitting units. One organic light-emitting unit includes a light-emitting layer, and may further include at least one organic layer. The organic layer may include one selected from the group consisting of a hole injection layer, a hole transport layer, an electron blocking layer, a hole blocking layer, an electron transport layer, an electron injection layer and combinations thereof.

The plurality of organic light-emitting units may be sequentially laminated, and a charge generation layer (CGL) may be included between each of the organic light-emitting units. The charge generation layer is located between the organic light-emitting units so as to smoothly distribute charges to the light-emitting layer of each organic light-emitting unit.

In the tandem-type organic light-emitting diode, at least one organic light-emitting unit includes the light-emitting layer including the multifunctional compound,
an organic layer adjacent to any one or both surfaces of the light-emitting layer including the multifunctional compound may or may not be further included,
the light-emitting layer including the multifunctional compound or the adjacent organic layer includes an excited complex-forming compound,
the multifunctional compound includes an excited complex-forming moiety and a light-emitting moiety,
the excited complex-forming moiety forms an excited complex with the excited complex-forming compound, and
the light-emitting moiety emits light by receiving excited energy of the excited complex.

In the tandem-type organic light-emitting diode, detailed description on the multifunctional compound, the excited complex-forming compound and the like is the same as the description stated above.

### EXAMPLE

### Synthesis Example

### Synthesis of Comparative Compound 1

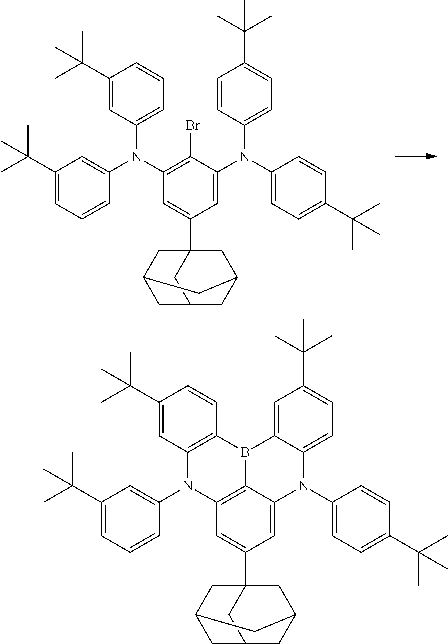

### Comparative Compound 1-1 Comparative Compound 1

Comparative Compound 1-1 (8.48 g, 10.0 mmol) was dissolved in tertiary butylbenzene (32 ml), and then the solution was cooled to 0° C. A 2.5 M n-butyllithium solution (in hexane) (8.0 mL, 20.0 mmol) was added thereto under a nitrogen atmosphere, and the mixture was stirred for 3 hours at room temperature.

After that, the reaction solution was cooled to 0° C. again, boron tribromide (1.90 mL, 20.0 mmol) was added thereto, and the reaction solution was stirred for 0.5 hours at room temperature. The reaction solution was cooled to 0° C. again, and after adding N,N-diisopropylethyl amine (3.51 mL, 20.0 mmol) thereto, the reaction solution was stirred for 2 hours at 60° C. to 70° C.

The reaction solution was cooled to room temperature, and the organic layer was extracted with ethyl acetate. The solvent of the extracted organic layer was dried with MgSO₄, and then the dried organic layer was filtered. The filtrate was concentrated under reduced pressure, and then purified using a silica gel column chromatography (DCM/hexane) method.

After that, the purified material was recrystallized with a mixed solvent of DCM/acetone to obtain Comparative Compound 1 (1.05 g) in a yield of 12%.

MS (ACPI) m/z: 779 [M+H]

NMR: 8H (500 MHz; CDCl3; Me4Si) 8.94 (s, 1H), 8.84 (d, J=10 Hz, 1H), 7.69 (d, 2H), 7.66-7.56 (m, 2H), 7.51-7.45 (d, 1H), 7.42 (s, 1H), 7.34-7.28 (m, 3H), 7.19 (d, 1H), 6.67 (s, J=8 Hz, 2H), 6.15 (d, 1H), 6.06 (s, 1H), 1.89 (s, 3H), 1.64 (d, 4H), 1.46 (s, 20H), 1.37 (s, 11H), 1.25 (s, 3H), 1.22 (s, 10H).

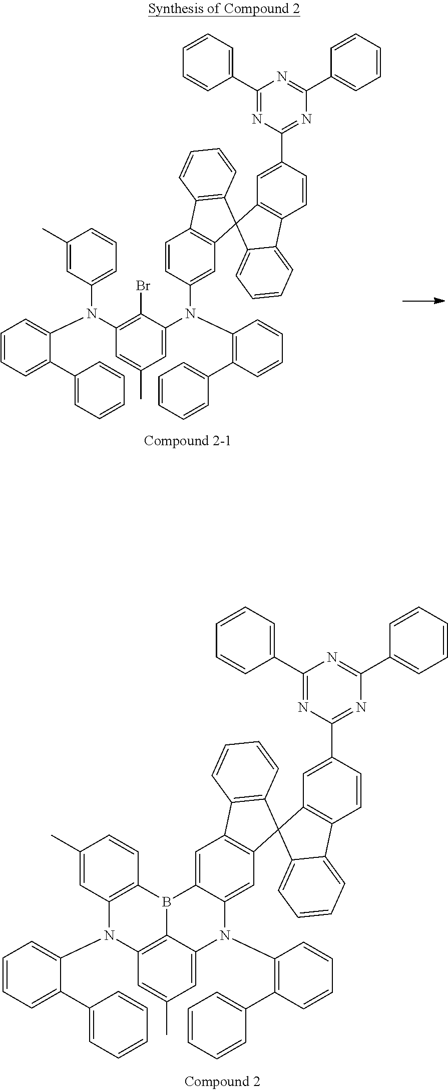 [SMILES: Cc1cccc(N(c2ccccc2-c2ccccc2)c2cc(C)cc(N(c3ccc4c(c3)C3(c5ccccc5-c5ccc(-c6nc(-c7ccccc7)nc(-c7ccccc7)n6)cc53)c3ccccc3-4)c3ccccc3-c3ccccc3)c2Br)c1 ; Cc1ccc2c(c1)N(c1ccccc1-c1ccccc1)c1cc(C)cc3c1B2c1cc2c(cc1N3c1ccccc1-c1ccccc1)C1(c3ccccc3-c3ccc(-c4nc(-c5ccccc5)nc(-c5ccccc5)n4)cc31)c1ccccc1-2]

Compound 2-1 (11.41 g, 10.0 mmol) was dissolved in mesitylene (45 ml), and then the solution was cooled to −30° C. A 2.5 M n-butyllithium solution (in hexane) (8.0 mL, 20.0 mmol) was added thereto under a nitrogen atmosphere, and the mixture was stirred for 30 minutes at −30° C.

After that, the reaction solution was cooled to −30° C. again, boron tribromide (1.90 mL, 20.0 mmol) was added thereto, and the reaction solution was stirred for 2 hours at room temperature. 2,6-di-tert-butylpyridine (2.18 mL, 10.0 mmol) was added thereto at room temperature, and then the reaction solution was stirred for 8 hours at 170° C.

The reaction solution was cooled to room temperature, and the organic layer was extracted with ethyl acetate. The solvent of the extracted organic layer was dried with MgSO₄, and then the dried organic layer was filtered. The filtrate was concentrated under reduced pressure, and then purified using a silica gel column chromatography (DCM/hexane) method.

After that, the purified material was recrystallized with a mixed solvent of DCM/acetone to obtain Compound 2 (0.75 g) in a yield of 7%.

MS (ACPI) m/z: 1071 [M+H]

NMR: 8H (400 MHz; CDCl3; Me4Si) 9.20 (dd, J=7.7, 2.7 Hz, 1H), 9.00-8.81 (m, 2H), 8.74-8.63 (m, 3H), 7.97 (dddd, J=41.1, 34.8, 16.0, 4.6 Hz, 4H), 7.77-7.63 (m, 3H), 7.62-7.28 (m, 12H), 7.17-6.85 (m, 10H), 6.83-6.34 (m, 8H), 6.04-5.83 (m, 3H), 2.36 (s, 3H), 2.13 (s, 3H).

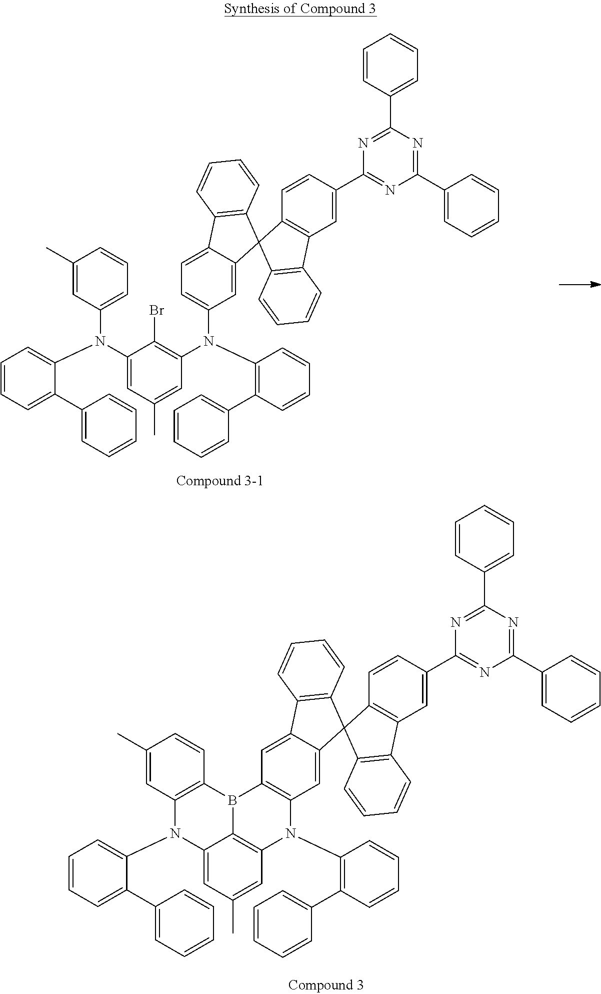 [SMILES: Cc1cccc(N(c2ccccc2-c2ccccc2)c2cc(C)cc(N(c3ccc4c(c3)C3(c5ccccc5-c5cc(-c6nc(-c7ccccc7)nc(-c7ccccc7)n6)ccc53)c3ccccc3-4)c3ccccc3-c3ccccc3)c2Br)c1 ; Cc1ccc2c(c1)N(c1ccccc1-c1ccccc1)c1cc(C)cc3c1B2c1cc2c(cc1N3c1ccccc1-c1ccccc1)C1(c3ccccc3-c3cc(-c4nc(-c5ccccc5)nc(-c5ccccc5)n4)ccc31)c1ccccc1-2]

Compound 3 was synthesized in the same manner as in Synthesis of Compound 2 described above, except that Compound 3-1 was used instead of Comparative Compound 2-1 in the same molar ratio as in Synthesis of Compound 2 described above.

After that, Compound 3 (0.54 g) was obtained in a yield of 5%.

MS (ACPI) m/z: 1071 [M+H]

NMR: δH (400 MHz; CDCl3; Me4Si) 9.25-9.07 (m, 2H), 8.93-8.77 (m, 5H), 8.62-8.43 (m, 1H), 8.10-7.87 (m, 2H), 7.81-7.56 (m, 10H), 7.54-7.27 (m, 6H), 7.17-6.59 (m, 15H), 6.46 (ddd, J=7.1, 5.6, 4.2 Hz, 2H), 6.07-5.95 (m, 2H), 5.96-5.87 (m, 1H), 2.36 (s, 3H), 2.15 (d, J=2.1 Hz, 3H).

### Experimental Example 1. PL Measurement of Exciplex HOST Flim

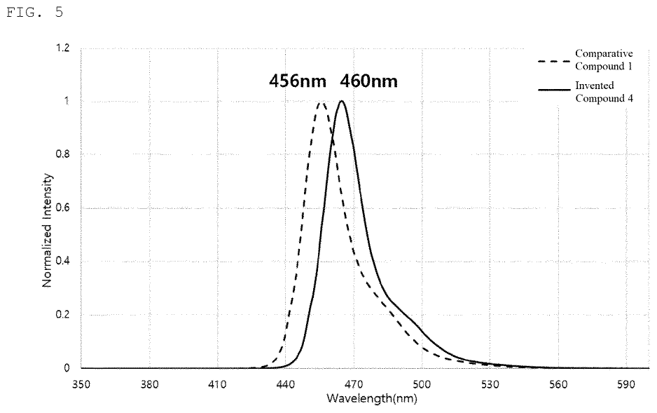

HOST-1, HOST-2, HOST-3 and HOST-4 were each prepared in a film form on bare glass using a vacuum deposition device. In order to observe an exciplex spectrum, HOST-1:HOST-3 and HOSt-2:HOST-4 were deposited in a ratio of 1:1. A PL (photoluminescence) phenomenon was observed by exciting each deposited glass with an absorption wavelength (350 nm), and the results are shown in FIGS. 3 and 4.

Looking into FIGS. 3 and 4, the unique spectrum of each HOST used disappeared, and a new dotted spectrum was observed. This means that a new exciplex HOST is produced by mixing two HOSTs with different properties.

As the measurement device, SHIMADZU RF5301PC and SHIMADZU UV 2550 were used.

### Experimental Example 2. PL Measurement of Dopant Solution

Each of Comparative Compound 1 and Compound 2 was dissolved in toluene to have a concentration of 2 micromoles, and excited with an absorption wavelength (max) to observe a PL (photoluminescence) phenomenon, and the results are shown in FIG. 5.

The graph of FIG. 5 represents emission spectra of the two compounds used as a dopant, and means that unique emission wavelengths of the two dopants are different.

As the measurement device, SHIMADZU RF5301PC and SHIMADZU UV 2550 were used.

### Manufacture of Organic Light-Emitting Diode

An ITO surface was treated with UV ozone for 3 minutes at atmospheric pressure.

In a 10⁻⁷ torr vacuum chamber, processes were performed in the following order to manufacture a device.

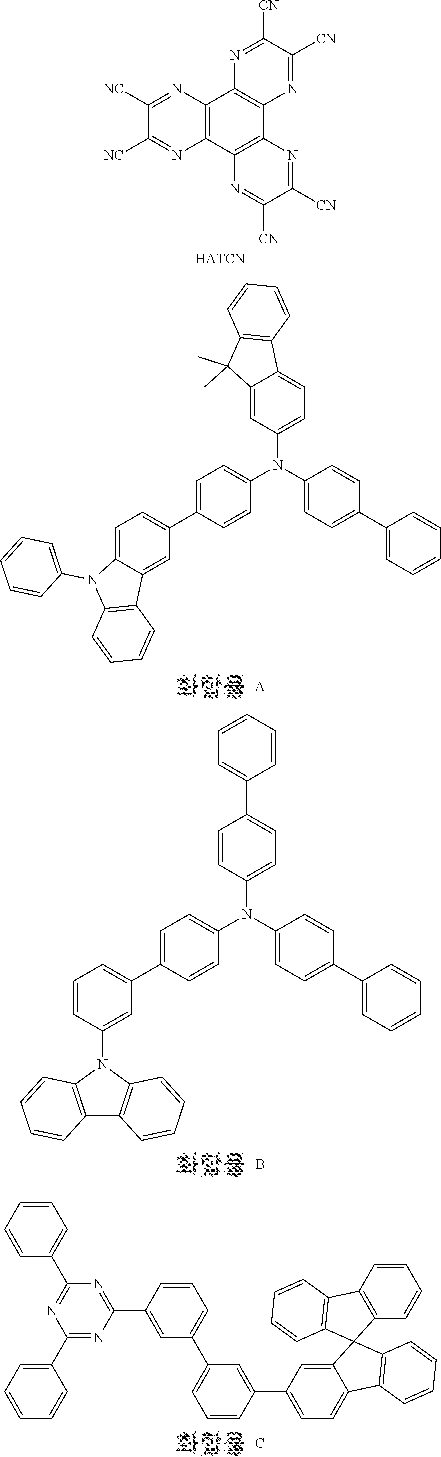

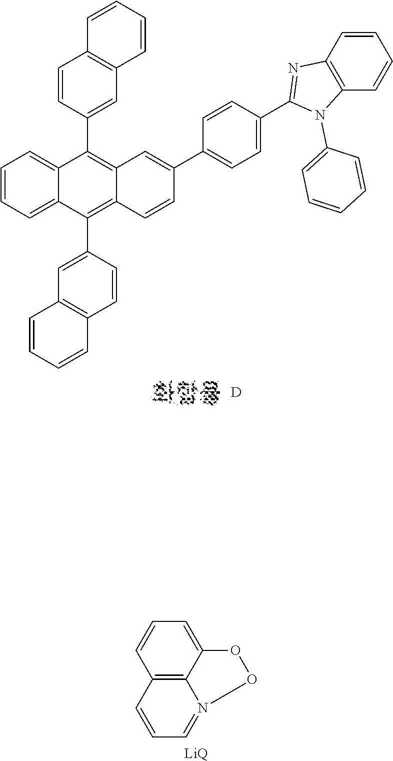

[symbol]

: Compound

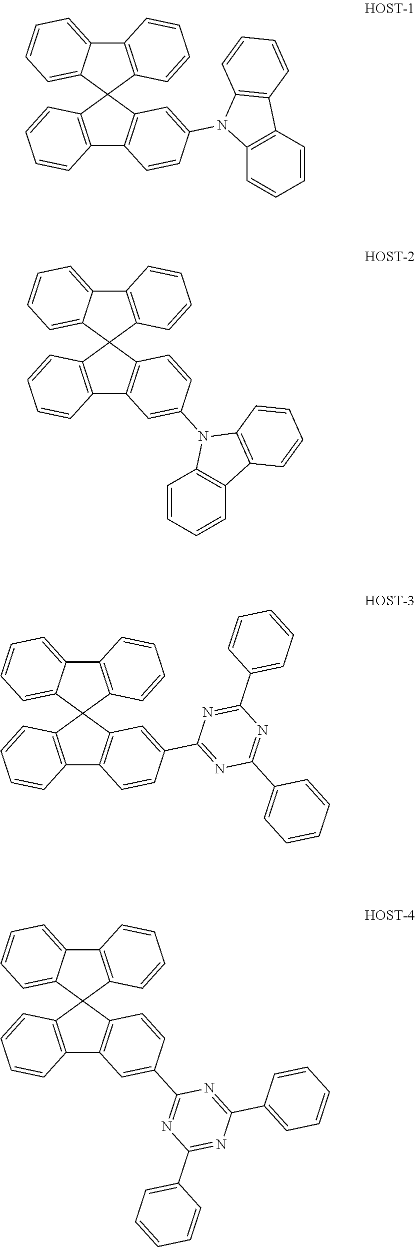 [SMILES: c1ccc2c(c1)-c1ccccc1C21c2ccccc2-c2ccc(-n3c4ccccc4c4ccccc43)cc21 ; c1ccc2c(c1)-c1ccccc1C21c2ccccc2-c2cc(-n3c4ccccc4c4ccccc43)ccc21 ; c1ccc(-c2nc(-c3ccccc3)nc(-c3ccc4c(c3)C3(c5ccccc5-c5ccccc53)c3ccccc3-4)n2)cc1 ; c1ccc(-c2nc(-c3ccccc3)nc(-c3ccc4c(c3)-c3ccccc3C43c4ccccc4-c4ccccc43)n2)cc1]

### Comparative Example 1 (Device 1)

HATCN was deposited to a thickness of 50 Å as a hole injection material.

Compound A was deposited to a thickness of 600 Å as a hole transport material.

Compound B was deposited to a thickness of 50 Å as an electron blocking layer.

A light-emitting layer was deposited to a thickness of 200 Å using HOST-1 and by doping Comparative Compound 1 (5 mol %) thereto.

Compound C was deposited to a thickness of 50 Å as a hole blocking layer.

Compound D and LiQ in a ratio of 1:1 were deposited to a thickness of 300 Å as an electron transport layer.

LiQ was deposited to a thickness of 15 Å as an electron injection layer.

Al was deposited to a thickness of 500 Å as an electrode.

### Comparative Example 2 (Device 2)

Device 2 was manufactured in the same manner as in Comparative Example 1, except that the light-emitting layer of Device 1 was doped with Comparative Compound 1 (10 mol %).

### Comparative Example 3 (Device 3)

Device 3 was manufactured in the same manner as in Comparative Example 1, except that HOST-2 was used instead of HOST-1 in the light-emitting layer of Device 1.

### Comparative Example 4 (Device 4)

Device 4 was manufactured in the same manner as in Comparative Example 2, except that HOST-2 was used instead of HOST-1 in the light-emitting layer of Device 2.

### Example 1 (Device 5)

Device 5 was manufactured in the same manner as in Comparative Example 1, except that the light-emitting layer of Device 1 was doped with Compound 2 (10 mol %).

### Example 2 (Device 6)

Device 6 was manufactured in the same manner as in Comparative Example 4, except that the light-emitting layer of Device 4 was doped with Compound 3 (10 mol %).

Table 1 was prepared based on maximum luminous efficiency in doping % of each device.

TABLE 1

| | | | | Doping | Voltage | Max_EQE | | | Λ |
|---|---|---|---|---|---|---|---|---|---|
| Device | | Host | Dopant | % | (V) | (%) | CIE x | CIE y | (max) |
| Comparative | Device 1 | HOST-1 | Comparative | 5% | 3.80 | 2.56 | 0.134 | 0.101 | 460 |
| Example | Device 2 | HOST-1 | Compound 1 | 10% | 3.2 | 3.82 | 0.140 | 0.154 | 460 |
| | Device 3 | HOST-2 | | 5% | 3.76 | 4.25 | 0.136 | 0.101 | 460 |
| | Device 4 | HOST-2 | | 10% | 3.72 | 6.61 | 0.138 | 0.120 | 460 |
| Example | Device 5 | HOST-1 | Compound 2 | 10% | 2.8 | 11.26 | 0.137 | 0.171 | 466 |
| | Device 6 | HOST-2 | Compound 3 | 10% | 3.2 | 9.16 | 0.127 | 0.111 | 466 |

As shown in Table 1, it may be identified that efficiency of energy transfer from the host to the dopant is low based on the results of measuring performance of the devices of Comparative Examples, resulting in low external quantum efficiency of the light-emitting devices. When Device 2 and Device 4 were each doped with Comparative Compound 1 (10 mol %), external quantum efficiency was 3.82% and 6.61%, respectively. However, Compounds 2 and 3 including an excited complex-forming moiety in the dopant as in the present disclosure were able to have maximum quantum efficiency of 11.26% and 9.16%, respectively, by forming an excited complex with the host material, and efficiently transferring the energy.

Hereinbefore, the present disclosure has been described with reference to accompanying drawings, however, the present disclosure is not limited by the embodiments and the drawings disclosed in the present specification, and it is obvious that various modifications may be made by those skilled in the art within the scope of technical ideas of the present disclosure. In addition, even when working effects obtained from the constitutions of the present disclosure are not explicitly described while describing the embodiments of the present disclosure, it is logical that effects predictable by the corresponding constitutions need to be acknowledged as well.

1. A multifunctional compound represented by the following Chemical Formula 1: 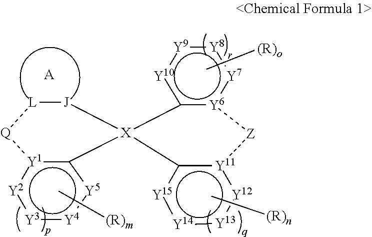
wherein, in Chemical Formula 1,
ring A is a fused ring represented by the following Chemical Formula 2, the following Chemical Formula 3 or the following Chemical Formula 4;
L represents a linking site in ring A, and L is linked to Q; or Y¹ when Q is not present;
J represents another linking site in ring A, and J is linked to X;
X is C, Si, Ge, Sn or Pb;
Q is not present, represents a single bond, or is one atom selected from the group consisting of Group IIIA, Group IVA, Group VA and Group VIA elements;
when Q is not present, L in ring A is not linked to Y¹;
when Q is a single bond, a single bond directly linking L in ring A and Y¹ is formed to form a 5-membered ring including X;
when Q is any one atom of the elements defined above, a 6-membered ring including X is formed, and the atom optionally has a substituent selected from the group consisting of alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a first additional substituent, heteroaryl having 2 to 30 carbon atoms unsubstituted or substituted with a first additional substituent, and combinations thereof according to a stoichiometric ratio, and the substituent are optionally linked to Y² or R that is linked to Y² to form a fused ring or linked to ring A to form a fused ring;
Y¹ to Y¹⁵ are each independently boron, carbon, nitrogen, oxygen, sulfur, Se or Te;
Z is not present, or a single bond, boron, oxygen, sulfur, —S(O₂)—, Se, C—(Ar¹)₂, POAr¹ or N—Ar¹, and herein, Ar¹ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar¹ is optionally linked to any one of Y⁷, Y¹², R linked to Y⁷ and R linked to Y¹² to form a fused ring;
when Z is not present, Y⁶ and Y¹¹ are not linked;
when Z is a single bond, Y⁶ and Y¹¹ are linked through the single bond;
however, when X is Si, Z is present as defined above;
m, n and o are each independently an integer of 0 to 5;
Rs are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms unsubstituted or substituted with a second additional substituent, aryloxy having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms unsubstituted or substituted with a second additional substituent, or aryl phosphine oxide having 6 to 30 carbon atoms unsubstituted or substituted with a second additional substituent, and at least two Rs present when m, n or o is 2 or greater are optionally linked to each other to form a ring; and
p, q and r each independently represent 0 or 1, and when p, q or r is 0, it means that a 5-membered ring is formed, and when p, q or r is 1, it means that a 6-membered ring is formed, 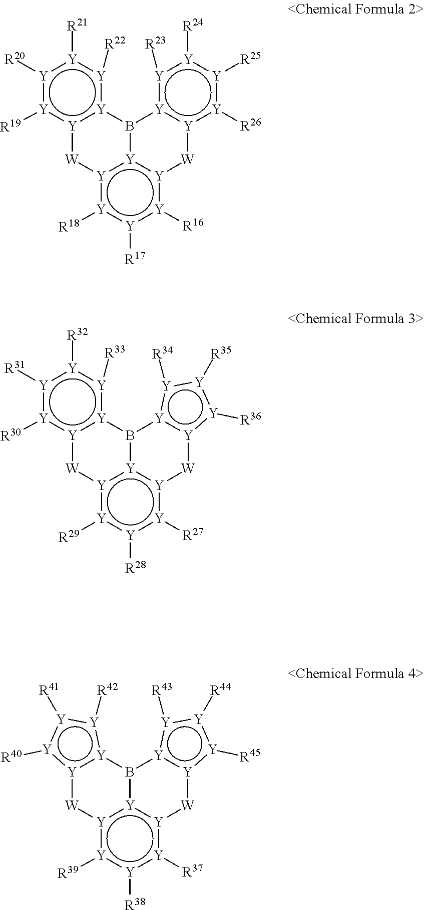
in Chemical Formula 2, Chemical Formula 3 and Chemical Formula 4,
Ys are each independently carbon, nitrogen, oxygen, sulfur, Se or Te, however, Y at the position corresponding to J in Chemical Formula 1 is carbon;
Ws are each independently oxygen, sulfur, Se, POAr² or N—Ar², Ar² is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and Ar² is optionally linked to a ring fused to the fused ring including W to form a fused ring;
R¹⁶ to R⁴⁵ each independently represent a bond with X such that Y linked thereto corresponds to J in Chemical Formula 1; or a bond with Q such that Y linked thereto corresponds to L in Chemical Formula 1; or are hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹⁶ to R⁴⁵ are optionally linked to each other to form a ring;
the first additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, halogen, cyano, aryl having 6 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms, heteroaryl having 2 to 30 carbon atoms, alkoxy having 1 to 30 carbon atoms, aryloxy having 6 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine oxide having 6 to 30 carbon atoms, and combinations thereof;
the second additional substituent is selected from the group consisting of deuterium, alkyl having 1 to 30 carbon atoms, cycloalkyl having 3 to 30 carbon atoms, heterocycloalkyl having 2 to 30 carbon atoms, ally having 3 to 30 carbon atoms, alkoxy having 1 to 30 carbon atoms, halogen, cyano, carboxyl, carbonyl, amine, alkyl amine having 1 to 30 carbon atoms, cycloalkyl amine having 3 to 30 carbon atoms, heterocycloalkyl amine having 2 to 30 carbon atoms, nitro, alkyl silyl having 1 to 30 carbon atoms, cycloalkyl silyl having 3 to 30 carbon atoms, heterocycloalkyl silyl having 2 to 30 carbon atoms, alkoxy silyl having 1 to 30 carbon atoms, aryl silyl having 6 to 30 carbon atoms, aryl having 6 to 30 carbon atoms, aryl amine having 6 to 30 carbon atoms, heteroaryl having 2 to 30 carbon atoms, aryl phosphine oxide having 6 to 30 carbon atoms, aryl phosphinyl having 6 to 30 carbon atoms, alkyl phosphine oxide having 1 to 30 carbon atoms, cycloalkyl phosphine oxide having 3 to 30 carbon atoms, heterocycloalkyl phosphine oxide having 2 to 30 carbon atoms, alkyl sulfonyl having 1 to 30 carbon atoms, cycloalkyl sulfonyl having 3 to 30 carbon atoms, heterocycloalkyl sulfonyl having 2 to 30 carbon atoms, and combinations thereof;
positions of L and J in Chemical Formula 1 are according to the following (i) or (ii):
(i) Y linked to any one of R¹⁶ to R⁴⁵ corresponds to J in Chemical Formula 1, and another Y adjacent to Y corresponding to J corresponds to L in Chemical Formula 1; or,
(ii) any one of Ws is N—Ar², Ar² is aryl having 6 to 30 carbon atoms unsubstituted or substituted with a second additional substituent or heteroaryl having 2 to 30 carbon atoms unsubstituted or substituted with a second additional substituent, any one reduction of aryl or heteroaryl of Ar² is carbon and corresponds to J in Chemical Formula 1, and another reduction adjacent thereto corresponds to L in Chemical Formula 1;
however, in Chemical Formula 1, when Z and Q are both a single bond, the following case (a) or (b) is excluded:
(a) ring A in Chemical Formula 1 is Chemical Formula 3 or Chemical Formula 4, any one of R³⁴ to R³⁶ and R⁴⁰ to R⁴⁵ in Chemical Formula 3 or Chemical Formula 4 corresponds to L in Chemical Formula 1, and two Ws in ring A are both N—Ar²;
(b) a 5-membered ring is formed in which at least one of p and q in Chemical Formula 1 is 0, and two Rs linked to the 5-membered ring are linked to each other to form an unsubstituted 6-membered fused ring.

2. The multifunctional compound of claim 1, wherein Chemical Formula 1 is any one of chemical formulae represented by the following B-1 to B-32: 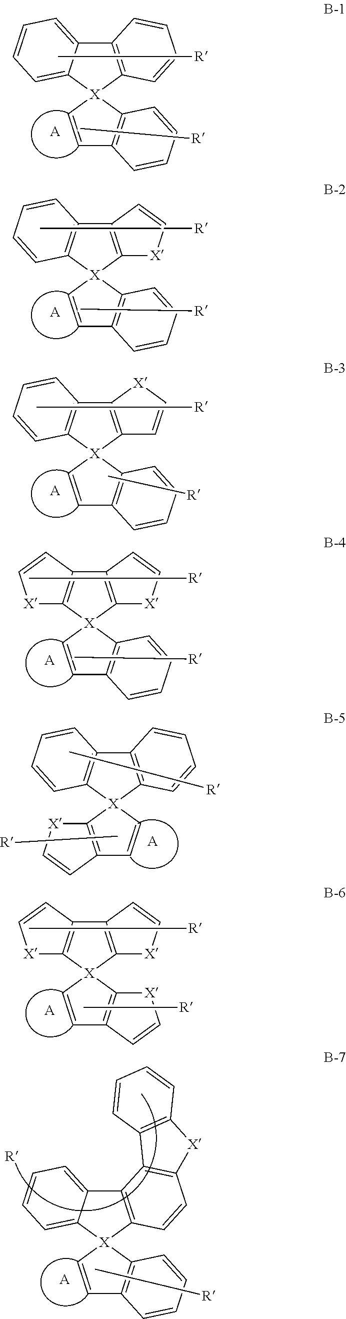 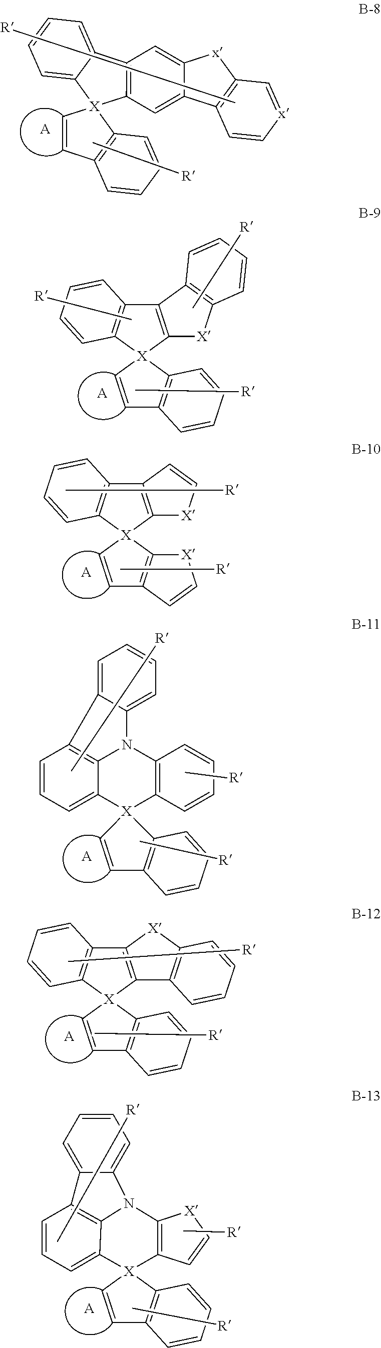 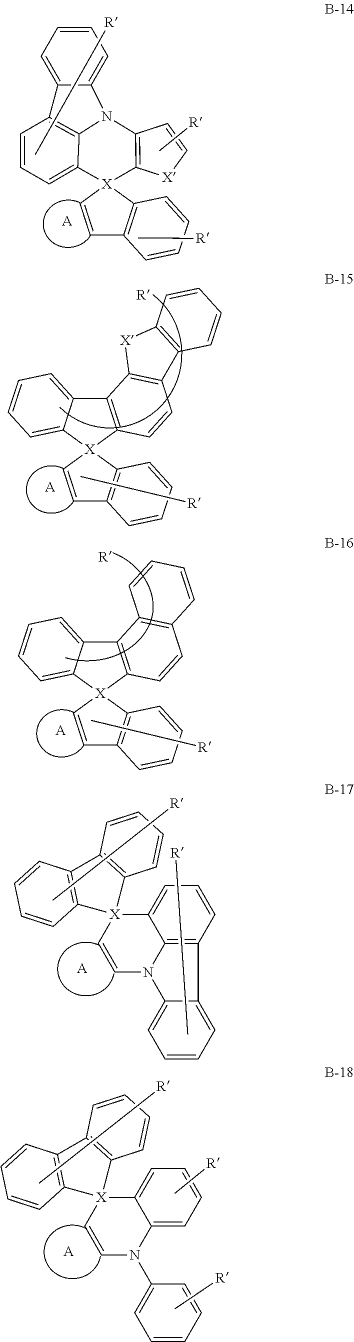 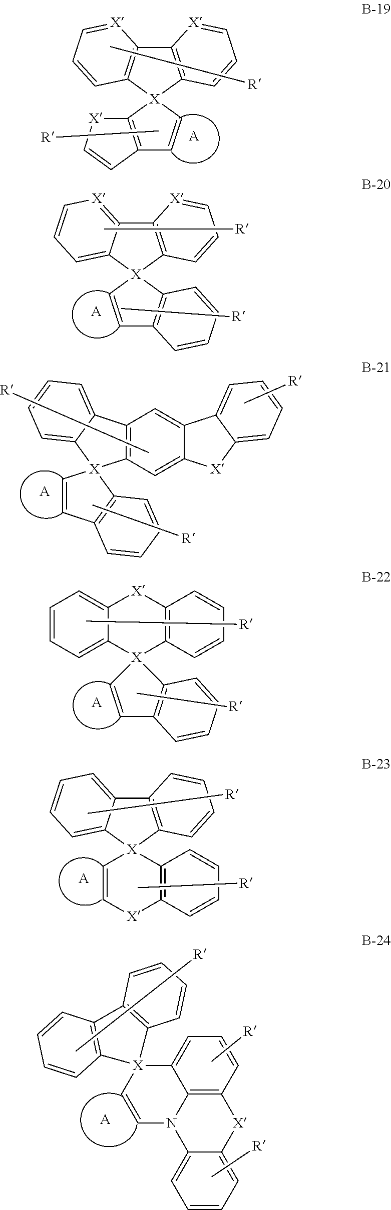 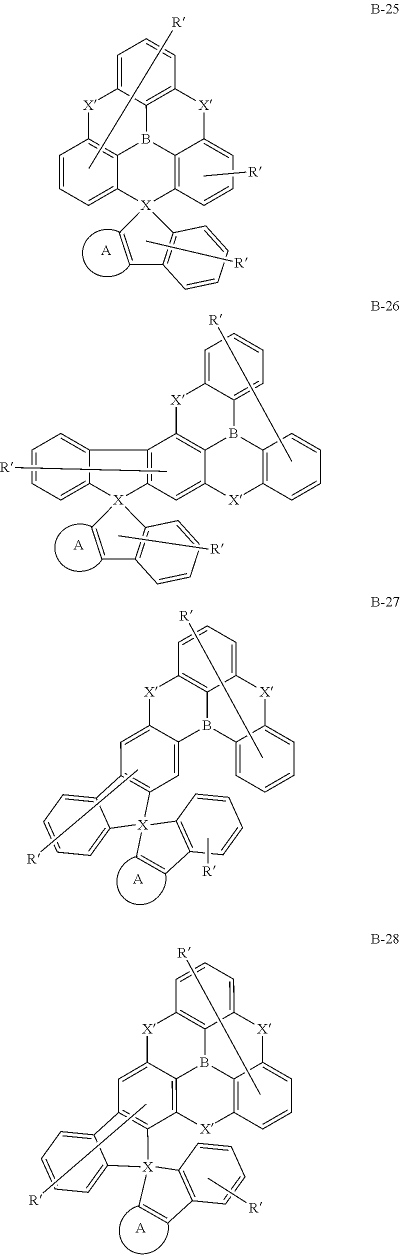 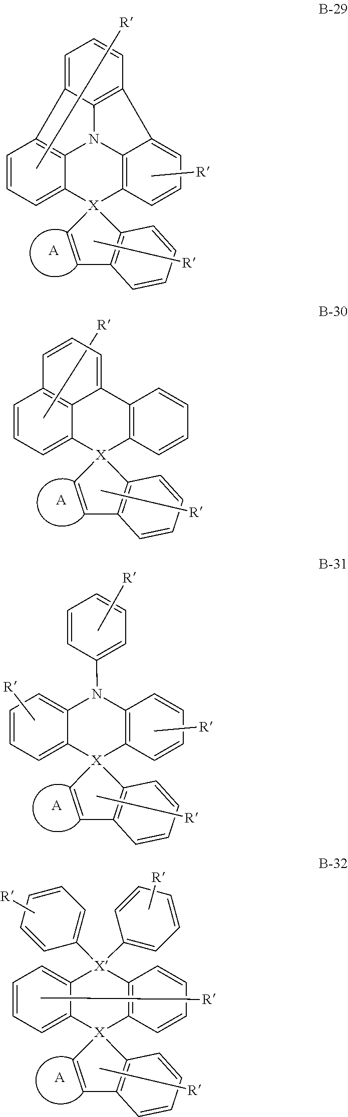
in B-1 to B-32,
ring A has the same definition as in Chemical Formula 1;
X is C, Si, Ge, Sn or Pb;
X′s are each independently O, S, Se, C, Si, C—(Ar³)₂, Si—(Ar³)₂ or N—Ar³, and Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar³s, the plurality of Ars are optionally linked to each other to form a ring;
R′s exist in the numbers according to a stoichiometric ratio, and are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two R′s are optionally linked to each other to form a ring; and
the second additional substituent has the same definition as the second additional substituent defined in Chemical Formula 1.

3. The multifunctional compound of claim 1, wherein ring A is represented by any one of the following C-1 to C-24,
however, in Chemical Formula 1, when Z and Q are a single bond, ring A is not C-8, C-10, C-11, C-17, C-20, C-22 and C-23: 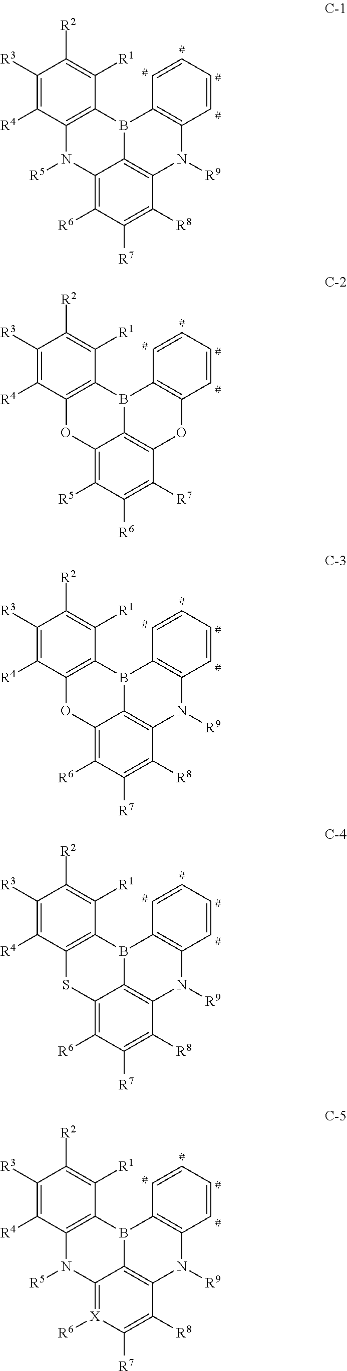 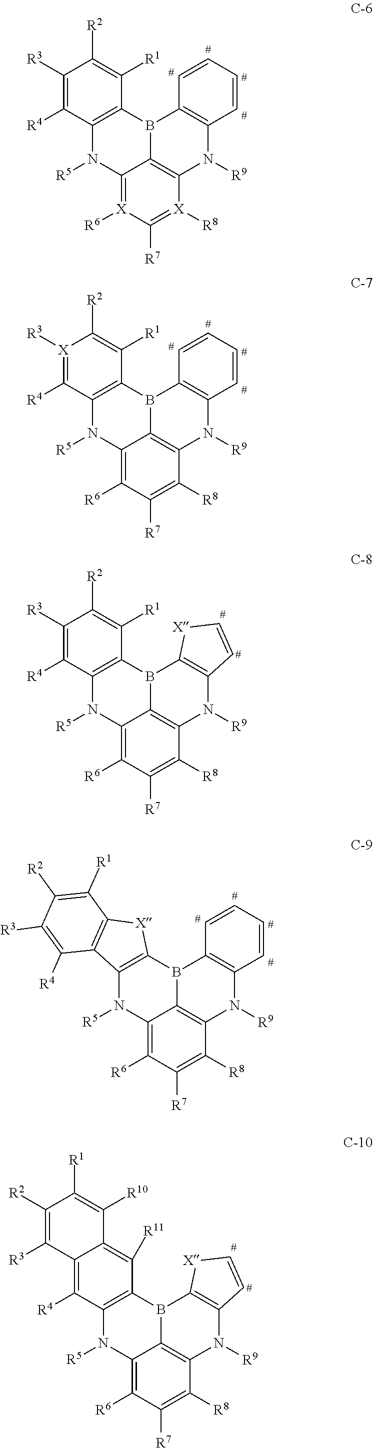 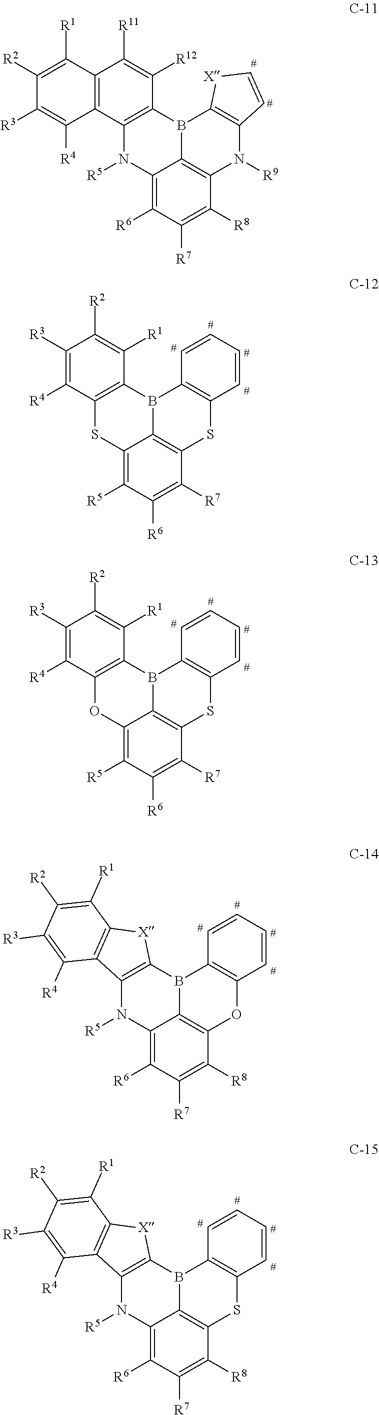 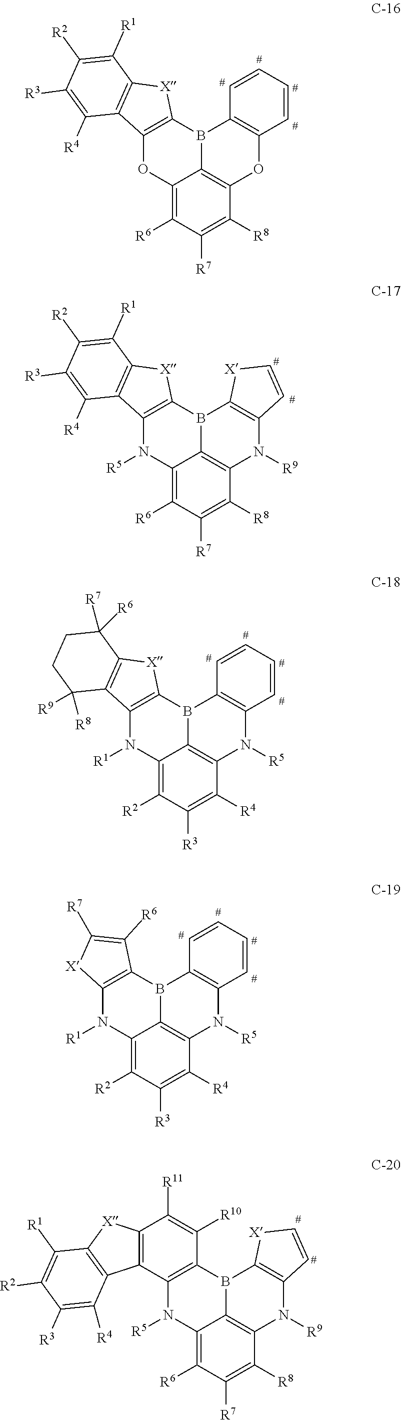 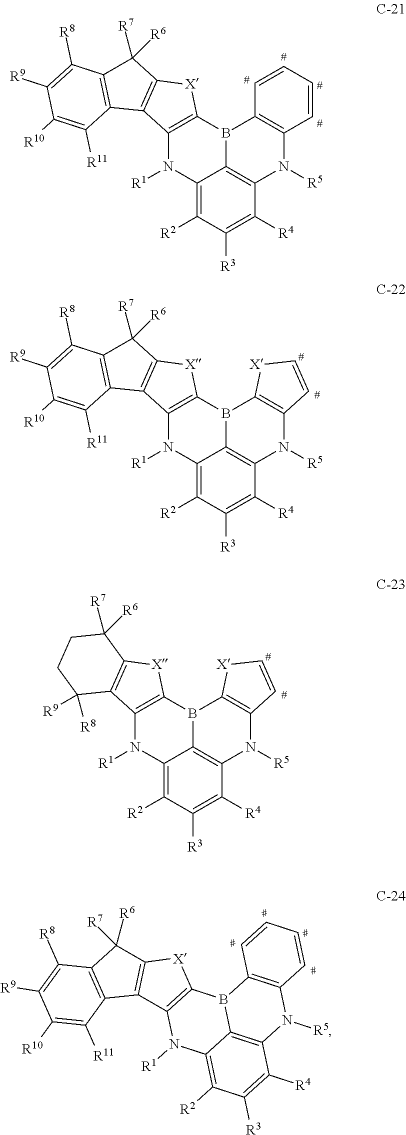
in C-1 to C-24,
two adjacent #s among the positions indicated by #correspond to J or L in ring A of Chemical Formula 1;
R¹ to R¹¹ are each independently hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a second additional substituent, heteroaryl having 2 to 30 carbon atoms unsubstituted or substituted with a second additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a second additional substituent, alkyl aryl amine having 7 to 30 carbon atoms unsubstituted or substituted with a second additional substituent, cycloalkyl aryl amine having 9 to 30 carbon atoms unsubstituted or substituted with a second additional substituent, heterocycloalkyl aryl amine having 8 to 30 carbon atoms unsubstituted or substituted with a second additional substituent, halogen, CN, alkoxy having 1 to 30 carbon atoms, aryloxy having 6 to 30 carbon atoms unsubstituted or substituted with a second additional substituent, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms unsubstituted or substituted with a second additional substituent, alkyl aryl silyl having 7 to 30 carbon atoms unsubstituted or substituted with a second additional substituent, cycloalkyl aryl silyl having 9 to 30 carbon atoms unsubstituted or substituted with a second additional substituent, heterocycloalkyl aryl silyl having 8 to 30 carbon atoms unsubstituted or substituted with a second additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms or aryl phosphine oxide having 6 to 30 carbon atoms, and at least two of R¹ to R¹¹ are optionally linked to each other to form a ring;
X′s are each independently O, S, Se, C, Si, C—(Ar³)₂, Si—(Ar³)₂ or N—Ar³, Ar³ is alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a second additional substituent, or heteroaryl having 2 to 30 carbon atoms unsubstituted or substituted with a second additional substituent, and when there are a plurality of Ar's, the plurality of Ars are optionally linked to each other to form a ring;
X″s are each independently N, O, S or Se; and
the second additional substituent has the same definition as the second additional substituent defined in Chemical Formula 1.

4. The multifunctional compound of claim 1, wherein the multifunctional compound represented by Chemical Formula 1 is divided into an atom represented by X, a light-emitting moiety and an excited complex-forming moiety, the light-emitting moiety and the excited complex-forming moiety are linked through the atom represented by X, and the atom represented by X is X presented in Chemical Formula 1;
the light-emitting moiety includes ring A, a conjugated ring formed to include Y¹ to Y⁵, and Q in Chemical Formula 1;
the excited complex-forming moiety includes a conjugated ring formed to include Y⁶ to Y¹⁰, a conjugated ring formed to include Y¹¹ to Y¹⁵, and Z in Chemical Formula 1; and
the excited complex-forming moiety includes an atom having at least one unshared electron pair.

5. The multifunctional compound of claim 4, wherein at least one of Y⁶ to Y¹⁵ and Z is an atom having an unshared electron pair included in a wave function of HOMO or LUMO of the excited complex-forming moiety; or
at least one of Y⁶ to Y¹⁵ has R represented by the following Chemical Formula 5 or the following Chemical Formula 6: 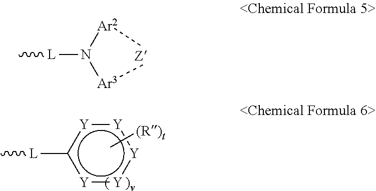
in Chemical Formula 5 and Chemical Formula 6,
L′ is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof;
Z′ is not present, represents a single bond, or is one atom selected from the group consisting of Group IIIA, Group IVA, Group VA and Group VIA elements, and when Z′ is an atom, it optionally has a substituent selected from hydrogen, alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a third additional substituent, heteroaryl having 2 to 30 carbon atoms unsubstituted or substituted with a third additional substituent, and combinations thereof according to a stoichiometric ratio;
Ar² and Ar³ are each independently alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, or heteroaryl having 2 to 30 carbon atoms unsubstituted or substituted with a third additional substituent, and Ar² and Ar³ are optionally each independently linked to L′ or the second additional substituent to form a fused ring;
t is an integer of 0 to 5;
v is 0 or 1;
R″s are each independently selected from hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 6 to 30 carbon atoms, aryl phosphine oxide having 6 to 30 carbon atoms, and combinations thereof, and herein, at least two R″s are optionally linked to each other to form a ring;
the third additional substituent is selected from alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms, heteroaryl having 2 to 30 carbon atoms, alkyl amine having 1 to 30 carbon atoms, cycloalkyl amine having 3 to 30 carbon atoms, heterocycloalkyl amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof;
Ys are each independently nitrogen, oxygen, sulfur or carbon; [symbol]
represents a linking site;
however, in Chemical Formula 6, L′ or R″ includes at least one atom having an unshared electron pair included in a wave function of HOMO or LUMO of the excited complex-forming moiety, or at least one of Ys is nitrogen, oxygen or sulfur.

6. The multifunctional compound of claim 1, comprising at least one deuterium.

7. The multifunctional compound of claim 1, wherein the multifunctional compound represented by Chemical Formula 1 is any one of the following compounds:

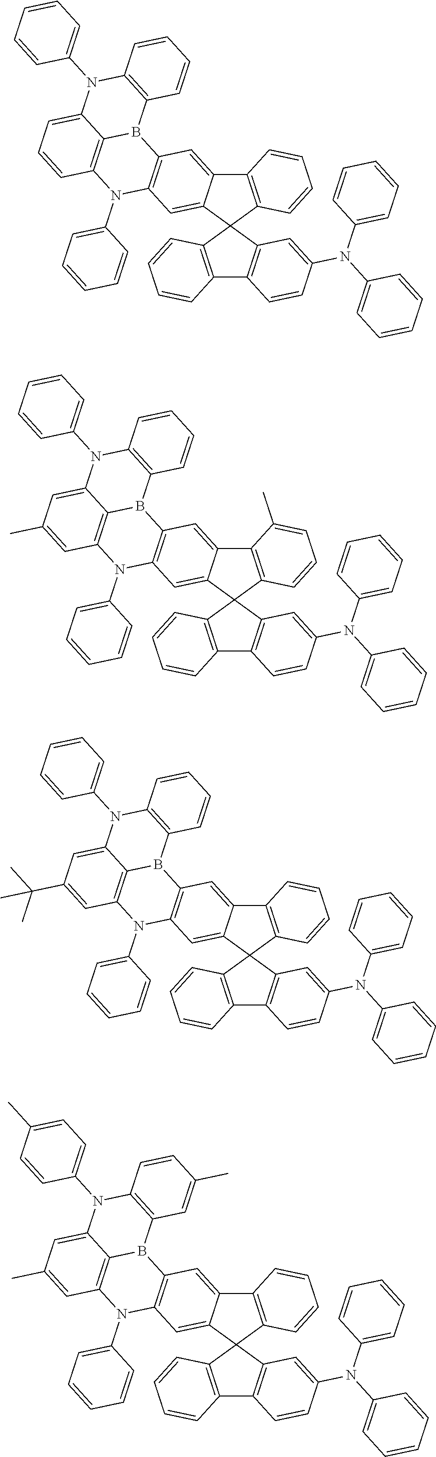 [SMILES: c1ccc(N(c2ccccc2)c2ccc3c(c2)C2(c4ccccc4-3)c3ccccc3-c3cc4c(cc32)N(c2ccccc2)c2cccc3c2B4c2ccccc2N3c2ccccc2)cc1 ; Cc1cc2c3c(c1)N(c1ccccc1)c1cc4c(cc1B3c1ccccc1N2c1ccccc1)-c1c(C)cccc1C41c2ccccc2-c2ccc(N(c3ccccc3)c3ccccc3)cc21 ; CC(C)(C)c1cc2c3c(c1)N(c1ccccc1)c1cc4c(cc1B3c1ccccc1N2c1ccccc1)-c1ccccc1C41c2ccccc2-c2ccc(N(c3ccccc3)c3ccccc3)cc21 ; Cc1ccc(N2c3ccc(C)cc3B3c4cc5c(cc4N(c4ccccc4)c4cc(C)cc2c43)C2(c3ccccc3-c3ccc(N(c4ccccc4)c4ccccc4)cc32)c2ccccc2-5)cc1]

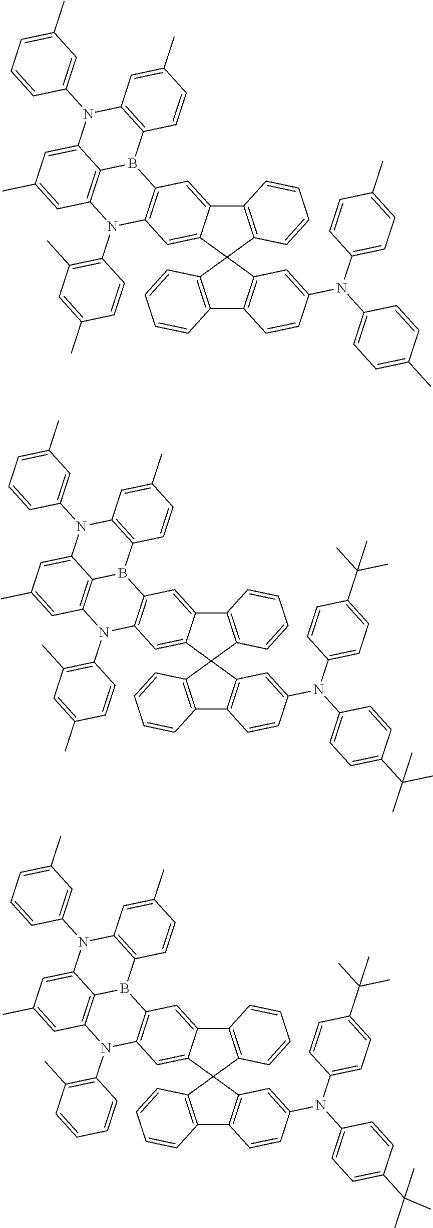

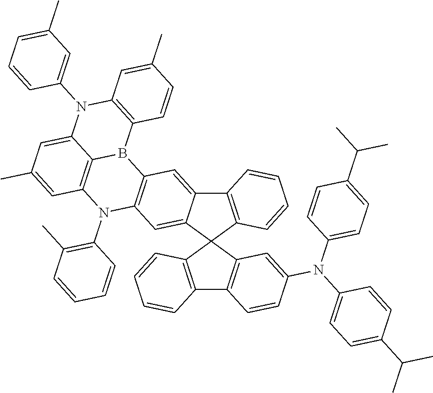 [SMILES: Cc1cccc(N2c3cc(C)ccc3B3c4cc5c(cc4N(c4ccccc4C)c4cc(C)cc2c43)C2(c3ccccc3-c3ccc(N(c4ccc(C(C)C)cc4)c4ccc(C(C)C)cc4)cc32)c2ccccc2-5)c1]

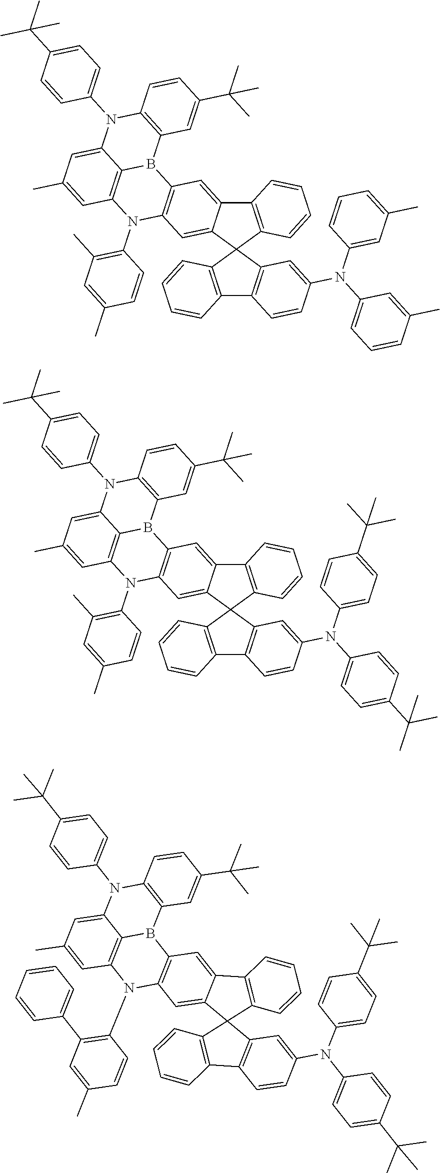

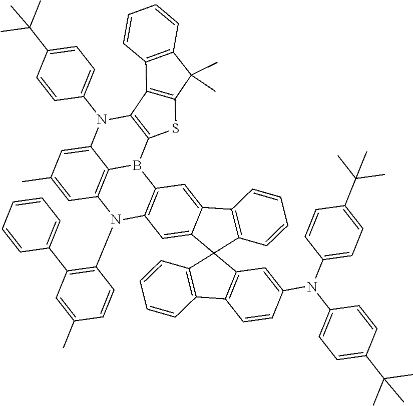 [SMILES: Cc1ccc(N2c3cc4c(cc3B3c5sc6c(c5N(c5ccc(C(C)(C)C)cc5)c5cc(C)cc2c53)-c2ccccc2C6(C)C)-c2ccccc2C42c3ccccc3-c3ccc(N(c4ccc(C(C)(C)C)cc4)c4ccc(C(C)(C)C)cc4)cc32)c(-c2ccccc2)c1]

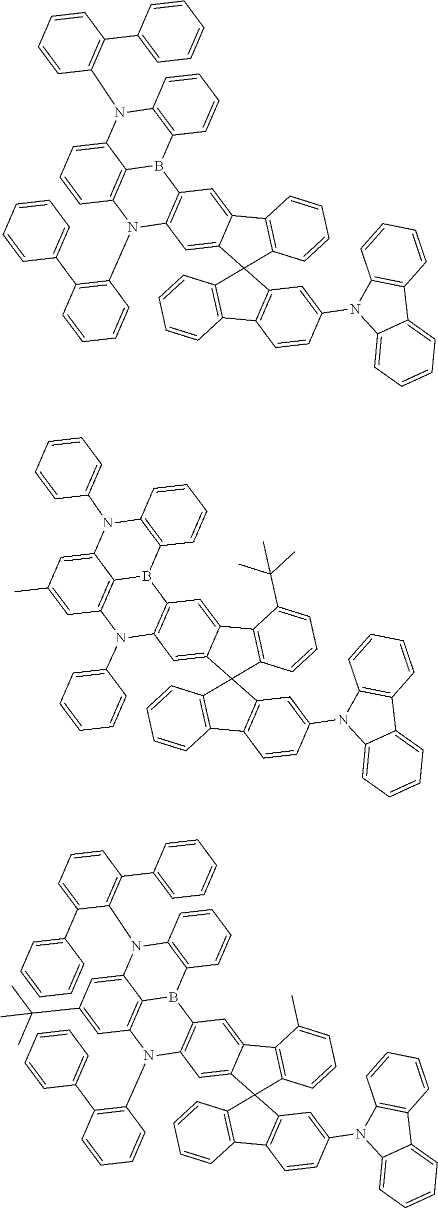 [SMILES: c1ccc(-c2ccccc2N2c3ccccc3B3c4cc5c(cc4N(c4ccccc4-c4ccccc4)c4cccc2c43)C2(c3ccccc3-c3ccc(-n4c6ccccc6c6ccccc64)cc32)c2ccccc2-5)cc1 ; Cc1cc2c3c(c1)N(c1ccccc1)c1cc4c(cc1B3c1ccccc1N2c1ccccc1)-c1c(C(C)(C)C)cccc1C41c2ccccc2-c2ccc(-n3c4ccccc4c4ccccc43)cc21 ; Cc1cccc2c1-c1cc3c(cc1C21c2ccccc2-c2ccc(-n4c5ccccc5c5ccccc54)cc21)N(c1ccccc1-c1ccccc1)c1cc(C(C)(C)C)cc2c1B3c1ccccc1N2c1c(-c2ccccc2)cccc1-c1ccccc1]

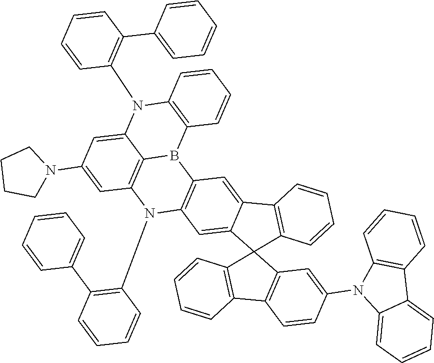 [SMILES: c1ccc(-c2ccccc2N2c3ccccc3B3c4cc5c(cc4N(c4ccccc4-c4ccccc4)c4cc(N6CCCC6)cc2c43)C2(c3ccccc3-c3ccc(-n4c6ccccc6c6ccccc64)cc32)c2ccccc2-5)cc1]

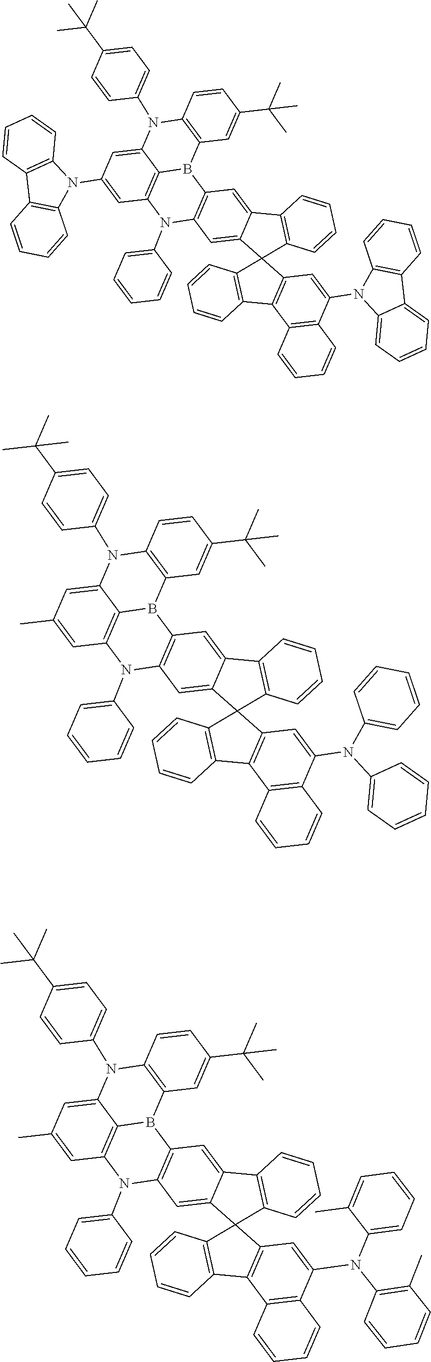 [SMILES: CC(C)(C)c1ccc(N2c3ccc(C(C)(C)C)cc3B3c4cc5c(cc4N(c4ccccc4)c4cc(-n6c7ccccc7c7ccccc76)cc2c43)C2(c3ccccc3-5)c3ccccc3-c3c2cc(-n2c4ccccc4c4ccccc42)c2ccccc32)cc1 ; Cc1cc2c3c(c1)N(c1ccccc1)c1cc4c(cc1B3c1cc(C(C)(C)C)ccc1N2c1ccc(C(C)(C)C)cc1)-c1ccccc1C41c2ccccc2-c2c1cc(N(c1ccccc1)c1ccccc1)c1ccccc21 ; Cc1cc2c3c(c1)N(c1ccccc1)c1cc4c(cc1B3c1cc(C(C)(C)C)ccc1N2c1ccc(C(C)(C)C)cc1)-c1ccccc1C41c2ccccc2-c2c1cc(N(c1ccccc1C)c1ccccc1C)c1ccccc21]

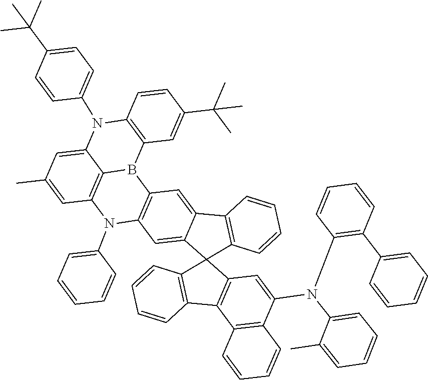 [SMILES: Cc1cc2c3c(c1)N(c1ccccc1)c1cc4c(cc1B3c1cc(C(C)(C)C)ccc1N2c1ccc(C(C)(C)C)cc1)-c1ccccc1C41c2ccccc2-c2c1cc(N(c1ccccc1C)c1ccccc1-c1ccccc1)c1ccccc21]

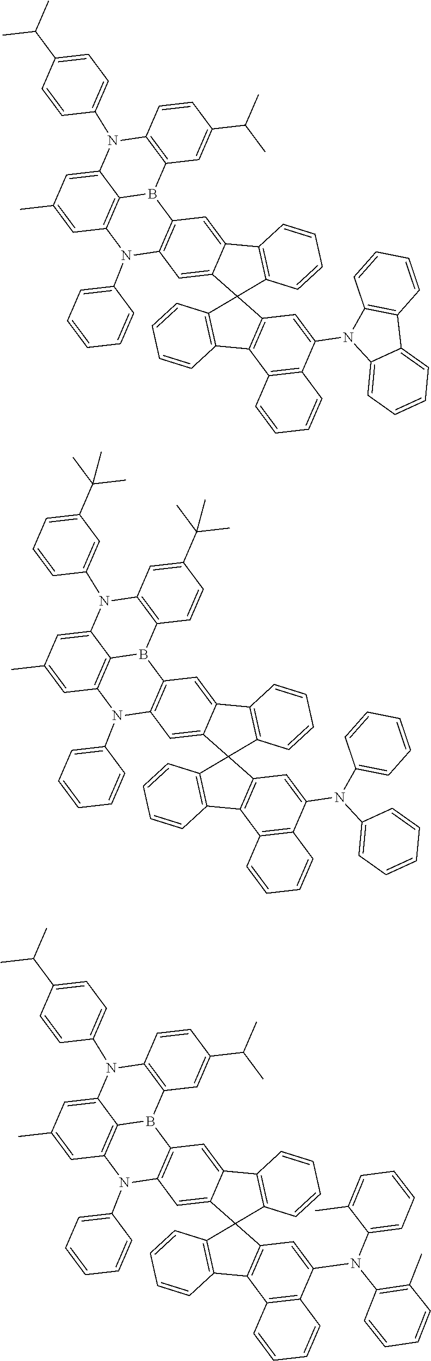 [SMILES: Cc1cc2c3c(c1)N(c1ccccc1)c1cc4c(cc1B3c1cc(C(C)C)ccc1N2c1ccc(C(C)C)cc1)-c1ccccc1C41c2ccccc2-c2c1cc(-n1c3ccccc3c3ccccc31)c1ccccc21 ; Cc1cc2c3c(c1)N(c1ccccc1)c1cc4c(cc1B3c1ccc(C(C)(C)C)cc1N2c1cccc(C(C)(C)C)c1)-c1ccccc1C41c2ccccc2-c2c1cc(N(c1ccccc1)c1ccccc1)c1ccccc21 ; Cc1cc2c3c(c1)N(c1ccccc1)c1cc4c(cc1B3c1cc(C(C)C)ccc1N2c1ccc(C(C)C)cc1)-c1ccccc1C41c2ccccc2-c2c1cc(N(c1ccccc1C)c1ccccc1C)c1ccccc21]

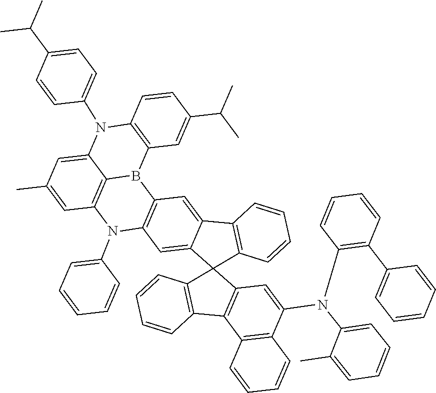 [SMILES: Cc1cc2c3c(c1)N(c1ccccc1)c1cc4c(cc1B3c1cc(C(C)C)ccc1N2c1ccc(C(C)C)cc1)-c1ccccc1C41c2ccccc2-c2c1cc(N(c1ccccc1C)c1ccccc1-c1ccccc1)c1ccccc21]

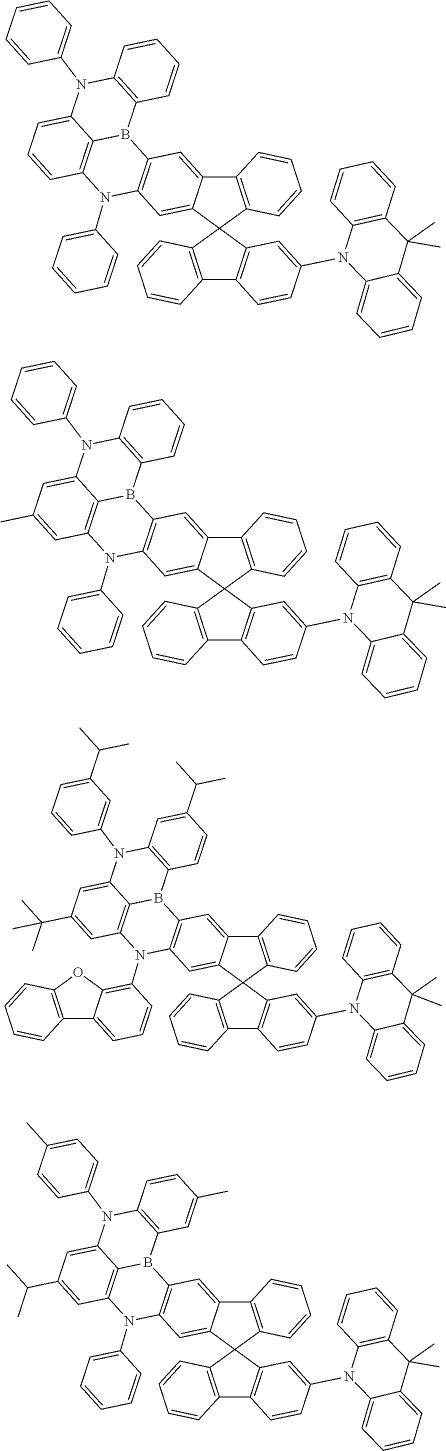

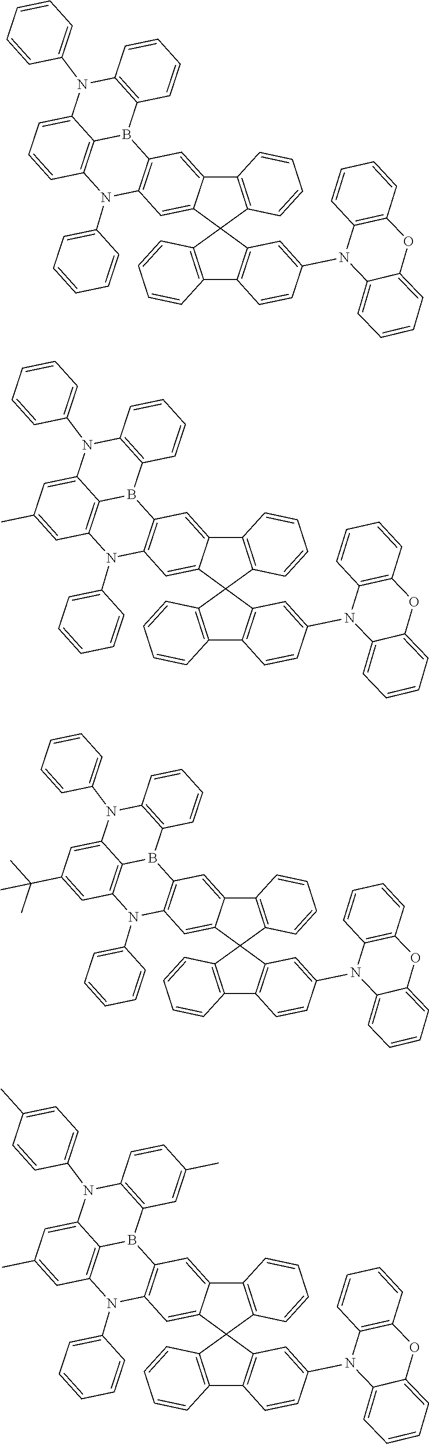 [SMILES: c1ccc(N2c3ccccc3B3c4cc5c(cc4N(c4ccccc4)c4cccc2c43)C2(c3ccccc3-c3ccc(N4c6ccccc6Oc6ccccc64)cc32)c2ccccc2-5)cc1 ; Cc1cc2c3c(c1)N(c1ccccc1)c1cc4c(cc1B3c1ccccc1N2c1ccccc1)-c1ccccc1C41c2ccccc2-c2ccc(N3c4ccccc4Oc4ccccc43)cc21 ; CC(C)(C)c1cc2c3c(c1)N(c1ccccc1)c1cc4c(cc1B3c1ccccc1N2c1ccccc1)-c1ccccc1C41c2ccccc2-c2ccc(N3c4ccccc4Oc4ccccc43)cc21 ; Cc1ccc(N2c3ccc(C)cc3B3c4cc5c(cc4N(c4ccccc4)c4cc(C)cc2c43)C2(c3ccccc3-c3ccc(N4c6ccccc6Oc6ccccc64)cc32)c2ccccc2-5)cc1]

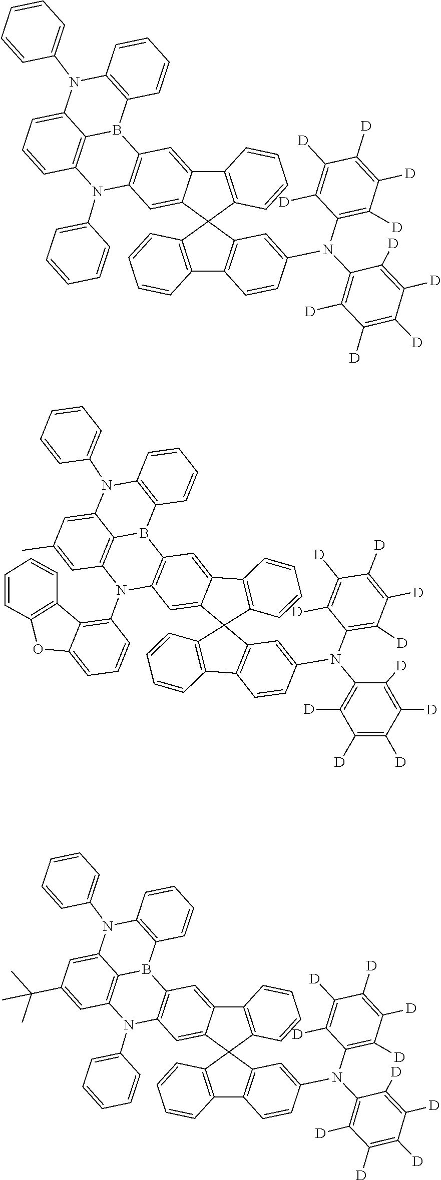

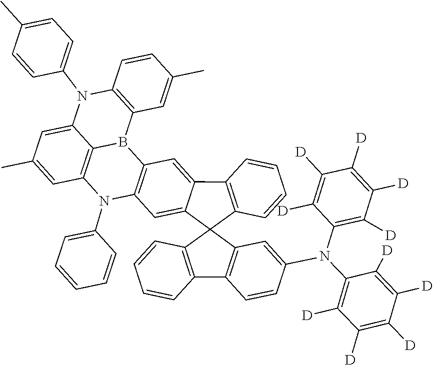 [SMILES: [2H]c1c([2H])c([2H])c(N(c2ccc3c(c2)C2(c4ccccc4-3)c3ccccc3-c3cc4c(cc32)N(c2ccccc2)c2cc(C)cc3c2B4c2cc(C)ccc2N3c2ccc(C)cc2)c2c([2H])c([2H])c([2H])c([2H])c2[2H])c([2H])c1[2H]]

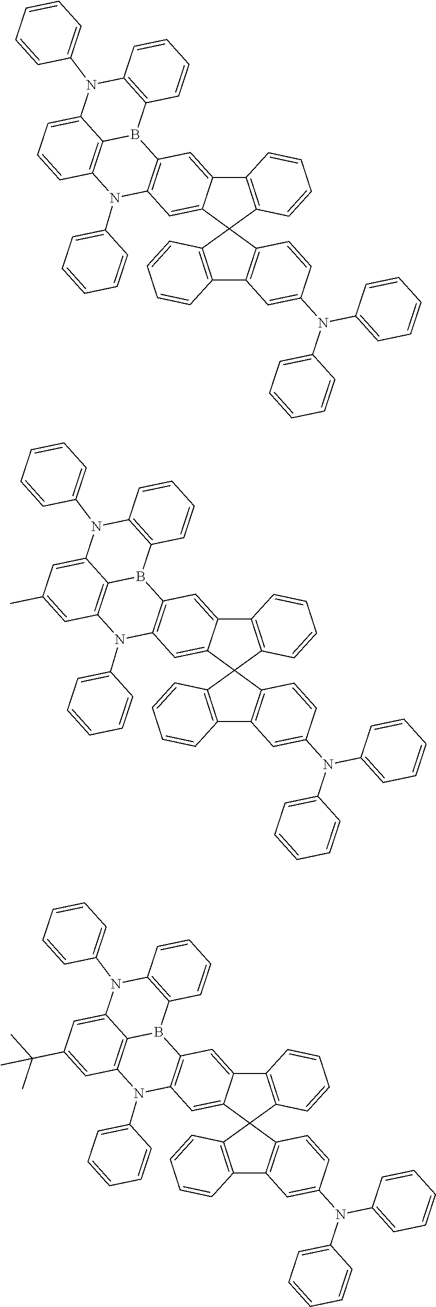 [SMILES: c1ccc(N(c2ccccc2)c2ccc3c(c2)-c2ccccc2C32c3ccccc3-c3cc4c(cc32)N(c2ccccc2)c2cccc3c2B4c2ccccc2N3c2ccccc2)cc1 ; Cc1cc2c3c(c1)N(c1ccccc1)c1cc4c(cc1B3c1ccccc1N2c1ccccc1)-c1ccccc1C41c2ccccc2-c2cc(N(c3ccccc3)c3ccccc3)ccc21 ; CC(C)(C)c1cc2c3c(c1)N(c1ccccc1)c1cc4c(cc1B3c1ccccc1N2c1ccccc1)-c1ccccc1C41c2ccccc2-c2cc(N(c3ccccc3)c3ccccc3)ccc21]

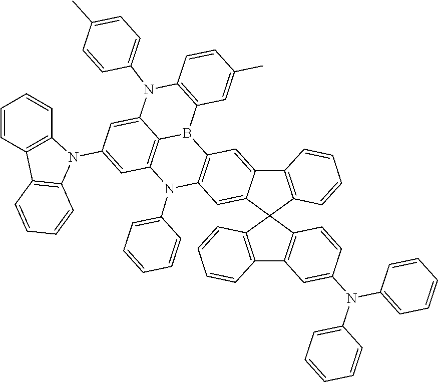 [SMILES: Cc1ccc(N2c3ccc(C)cc3B3c4cc5c(cc4N(c4ccccc4)c4cc(-n6c7ccccc7c7ccccc76)cc2c43)C2(c3ccccc3-c3cc(N(c4ccccc4)c4ccccc4)ccc32)c2ccccc2-5)cc1]

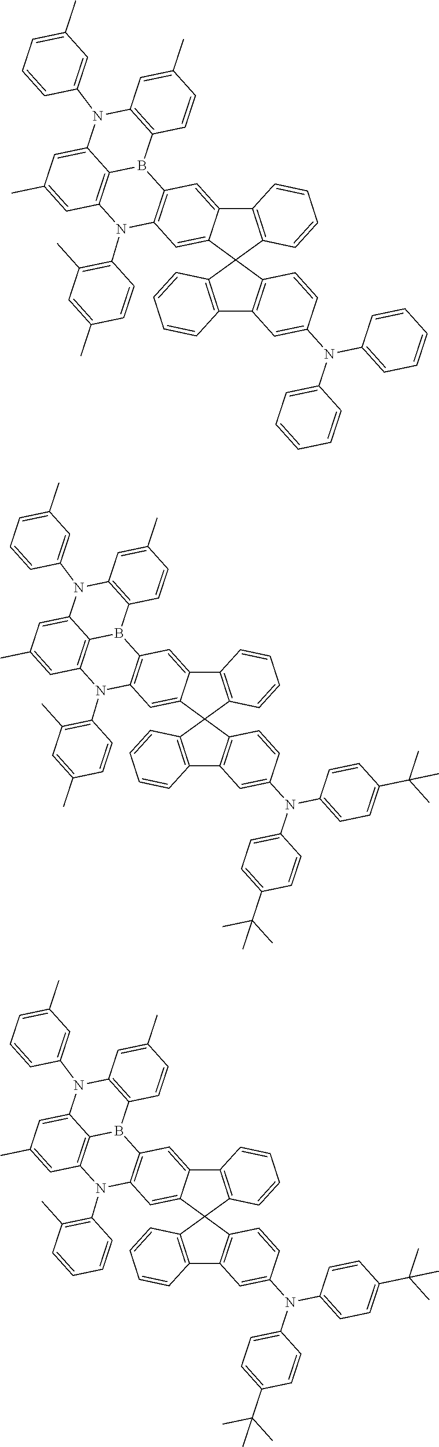

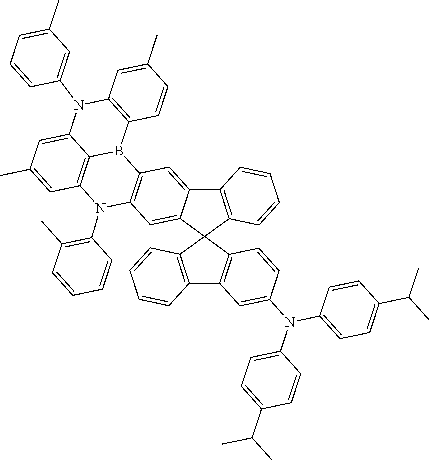 [SMILES: Cc1cccc(N2c3cc(C)ccc3B3c4cc5c(cc4N(c4ccccc4C)c4cc(C)cc2c43)C2(c3ccccc3-c3cc(N(c4ccc(C(C)C)cc4)c4ccc(C(C)C)cc4)ccc32)c2ccccc2-5)c1]

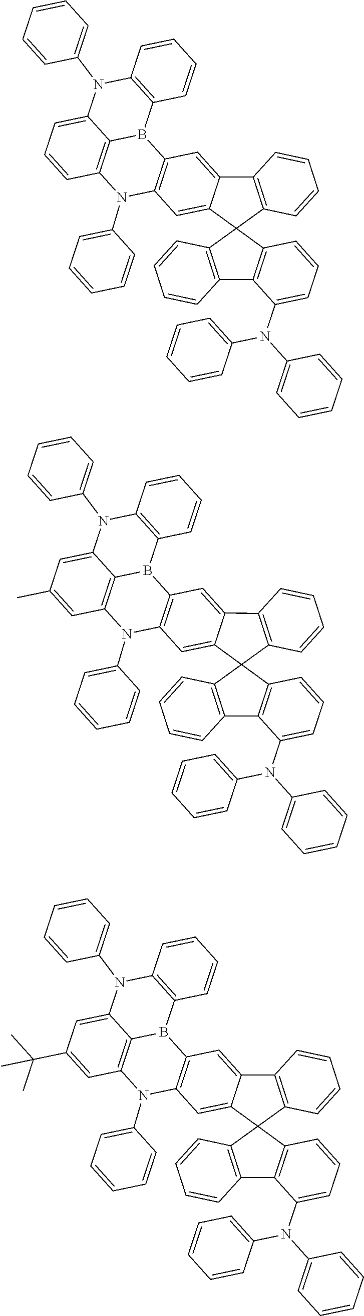 [SMILES: c1ccc(N(c2ccccc2)c2cccc3c2-c2ccccc2C32c3ccccc3-c3cc4c(cc32)N(c2ccccc2)c2cccc3c2B4c2ccccc2N3c2ccccc2)cc1 ; Cc1cc2c3c(c1)N(c1ccccc1)c1cc4c(cc1B3c1ccccc1N2c1ccccc1)-c1ccccc1C41c2ccccc2-c2c(N(c3ccccc3)c3ccccc3)cccc21 ; CC(C)(C)c1cc2c3c(c1)N(c1ccccc1)c1cc4c(cc1B3c1ccccc1N2c1ccccc1)-c1ccccc1C41c2ccccc2-c2c(N(c3ccccc3)c3ccccc3)cccc21]

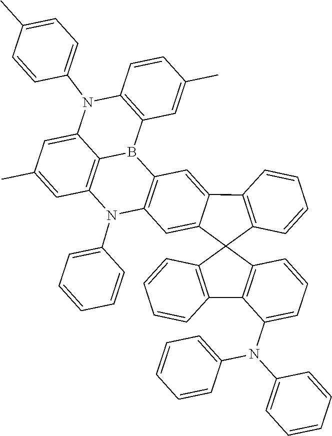 [SMILES: Cc1ccc(N2c3ccc(C)cc3B3c4cc5c(cc4N(c4ccccc4)c4cc(C)cc2c43)C2(c3ccccc3-5)c3ccccc3-c3c(N(c4ccccc4)c4ccccc4)cccc32)cc1]

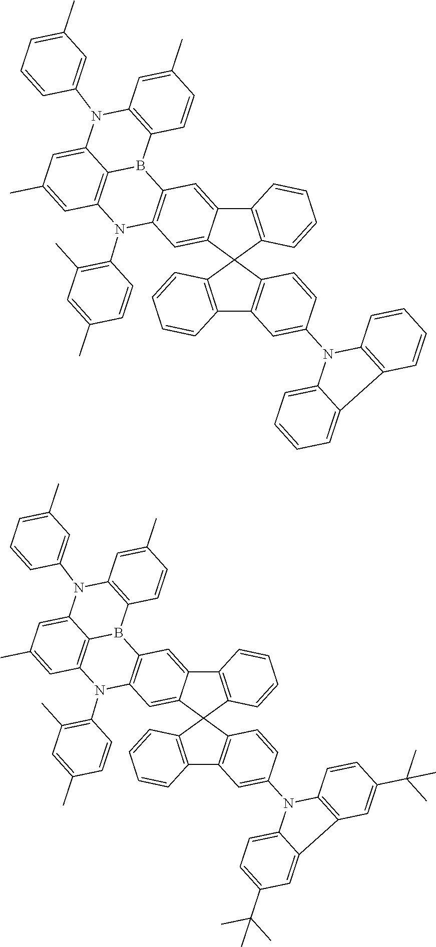 [SMILES: Cc1cccc(N2c3cc(C)ccc3B3c4cc5c(cc4N(c4ccc(C)cc4C)c4cc(C)cc2c43)C2(c3ccccc3-c3cc(-n4c6ccccc6c6ccccc64)ccc32)c2ccccc2-5)c1 ; Cc1cccc(N2c3cc(C)ccc3B3c4cc5c(cc4N(c4ccc(C)cc4C)c4cc(C)cc2c43)C2(c3ccccc3-c3cc(-n4c6ccc(C(C)(C)C)cc6c6cc(C(C)(C)C)ccc64)ccc32)c2ccccc2-5)c1]

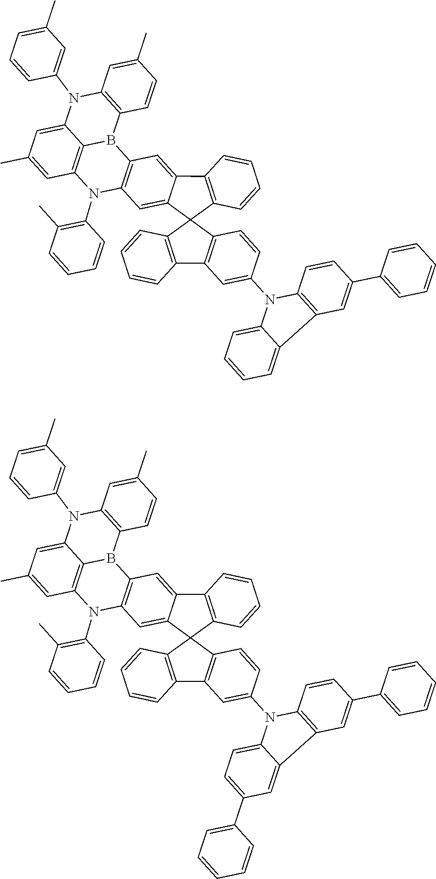 [SMILES: Cc1cccc(N2c3cc(C)ccc3B3c4cc5c(cc4N(c4ccccc4C)c4cc(C)cc2c43)C2(c3ccccc3-c3cc(-n4c6ccccc6c6cc(-c7ccccc7)ccc64)ccc32)c2ccccc2-5)c1 ; Cc1cccc(N2c3cc(C)ccc3B3c4cc5c(cc4N(c4ccccc4C)c4cc(C)cc2c43)C2(c3ccccc3-c3cc(-n4c6ccc(-c7ccccc7)cc6c6cc(-c7ccccc7)ccc64)ccc32)c2ccccc2-5)c1]

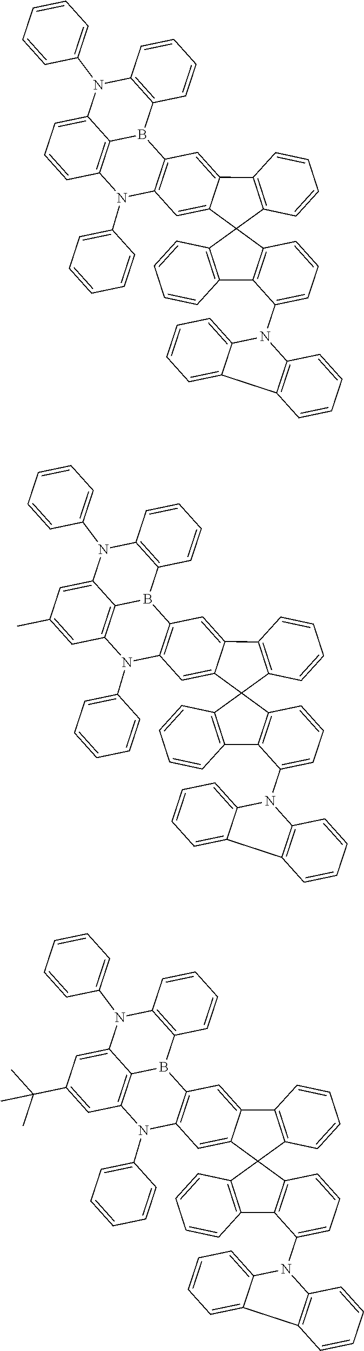 [SMILES: c1ccc(N2c3ccccc3B3c4cc5c(cc4N(c4ccccc4)c4cccc2c43)C2(c3ccccc3-5)c3ccccc3-c3c(-n4c5ccccc5c5ccccc54)cccc32)cc1 ; Cc1cc2c3c(c1)N(c1ccccc1)c1cc4c(cc1B3c1ccccc1N2c1ccccc1)-c1ccccc1C41c2ccccc2-c2c(-n3c4ccccc4c4ccccc43)cccc21 ; CC(C)(C)c1cc2c3c(c1)N(c1ccccc1)c1cc4c(cc1B3c1ccccc1N2c1ccccc1)-c1ccccc1C41c2ccccc2-c2c(-n3c4ccccc4c4ccccc43)cccc21]

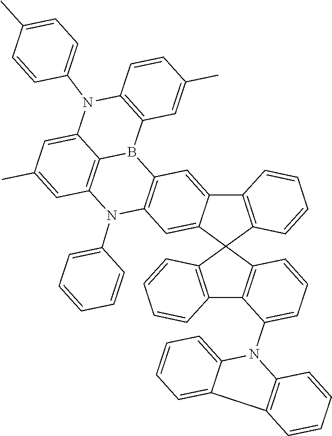 [SMILES: Cc1ccc(N2c3ccc(C)cc3B3c4cc5c(cc4N(c4ccccc4)c4cc(C)cc2c43)C2(c3ccccc3-5)c3ccccc3-c3c(-n4c5ccccc5c5ccccc54)cccc32)cc1]

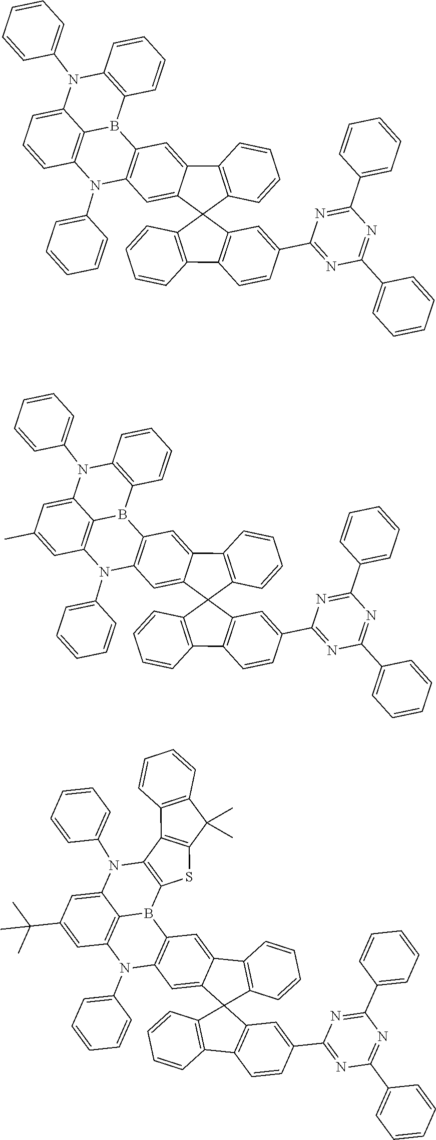 [SMILES: c1ccc(-c2nc(-c3ccccc3)nc(-c3ccc4c(c3)C3(c5ccccc5-4)c4ccccc4-c4cc5c(cc43)N(c3ccccc3)c3cccc4c3B5c3ccccc3N4c3ccccc3)n2)cc1 ; Cc1cc2c3c(c1)N(c1ccccc1)c1cc4c(cc1B3c1ccccc1N2c1ccccc1)-c1ccccc1C41c2ccccc2-c2ccc(-c3nc(-c4ccccc4)nc(-c4ccccc4)n3)cc21 ; CC(C)(C)c1cc2c3c(c1)N(c1ccccc1)c1c(sc4c1-c1ccccc1C4(C)C)B3c1cc3c(cc1N2c1ccccc1)C1(c2ccccc2-c2ccc(-c4nc(-c5ccccc5)nc(-c5ccccc5)n4)cc21)c1ccccc1-3]

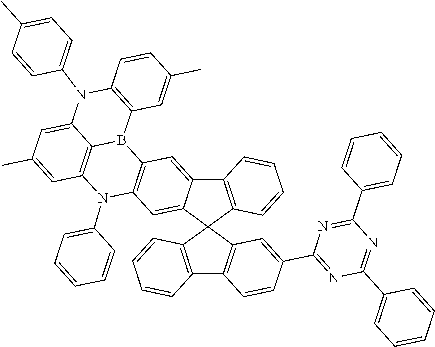 [SMILES: Cc1ccc(N2c3ccc(C)cc3B3c4cc5c(cc4N(c4ccccc4)c4cc(C)cc2c43)C2(c3ccccc3-c3ccc(-c4nc(-c6ccccc6)nc(-c6ccccc6)n4)cc32)c2ccccc2-5)cc1]

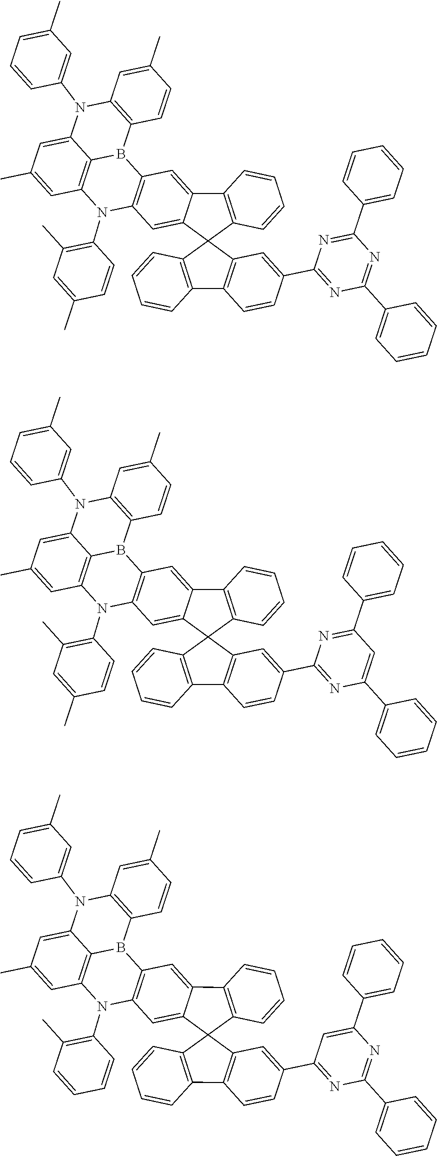 [SMILES: Cc1cccc(N2c3cc(C)ccc3B3c4cc5c(cc4N(c4ccc(C)cc4C)c4cc(C)cc2c43)C2(c3ccccc3-c3ccc(-c4nc(-c6ccccc6)nc(-c6ccccc6)n4)cc32)c2ccccc2-5)c1 ; Cc1cccc(N2c3cc(C)ccc3B3c4cc5c(cc4N(c4ccc(C)cc4C)c4cc(C)cc2c43)C2(c3ccccc3-c3ccc(-c4nc(-c6ccccc6)cc(-c6ccccc6)n4)cc32)c2ccccc2-5)c1 ; Cc1cccc(N2c3cc(C)ccc3B3c4cc5c(cc4N(c4ccccc4C)c4cc(C)cc2c43)C2(c3ccccc3-c3ccc(-c4cc(-c6ccccc6)nc(-c6ccccc6)n4)cc32)c2ccccc2-5)c1]

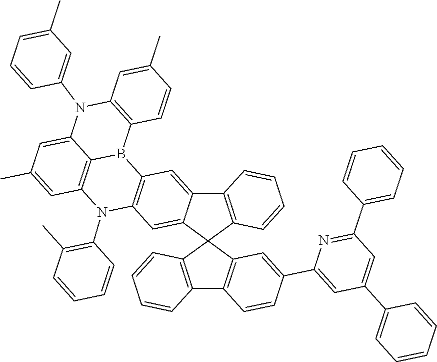 [SMILES: Cc1cccc(N2c3cc(C)ccc3B3c4cc5c(cc4N(c4ccccc4C)c4cc(C)cc2c43)C2(c3ccccc3-c3ccc(-c4cc(-c6ccccc6)cc(-c6ccccc6)n4)cc32)c2ccccc2-5)c1]

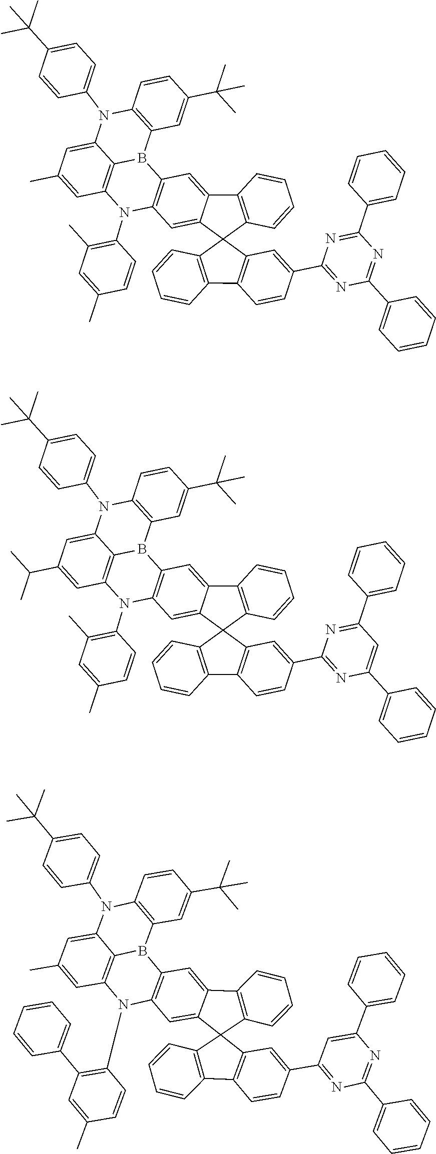 [SMILES: Cc1ccc(N2c3cc4c(cc3B3c5cc(C(C)(C)C)ccc5N(c5ccc(C(C)(C)C)cc5)c5cc(C)cc2c53)-c2ccccc2C42c3ccccc3-c3ccc(-c4nc(-c5ccccc5)nc(-c5ccccc5)n4)cc32)c(C)c1 ; Cc1ccc(N2c3cc4c(cc3B3c5cc(C(C)(C)C)ccc5N(c5ccc(C(C)(C)C)cc5)c5cc(C(C)C)cc2c53)-c2ccccc2C42c3ccccc3-c3ccc(-c4nc(-c5ccccc5)cc(-c5ccccc5)n4)cc32)c(C)c1 ; Cc1ccc(N2c3cc4c(cc3B3c5cc(C(C)(C)C)ccc5N(c5ccc(C(C)(C)C)cc5)c5cc(C)cc2c53)-c2ccccc2C42c3ccccc3-c3ccc(-c4cc(-c5ccccc5)nc(-c5ccccc5)n4)cc32)c(-c2ccccc2)c1]

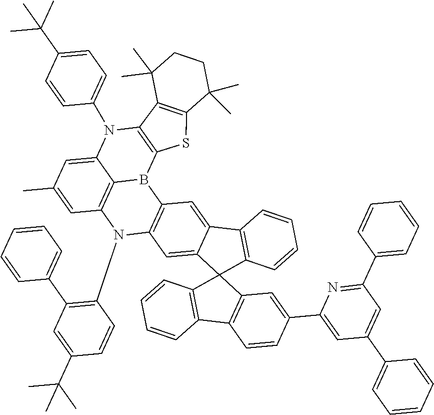 [SMILES: Cc1cc2c3c(c1)N(c1ccc(C(C)(C)C)cc1)c1c(sc4c1C(C)(C)CCC4(C)C)B3c1cc3c(cc1N2c1ccc(C(C)(C)C)cc1-c1ccccc1)C1(c2ccccc2-c2ccc(-c4cc(-c5ccccc5)cc(-c5ccccc5)n4)cc21)c1ccccc1-3]

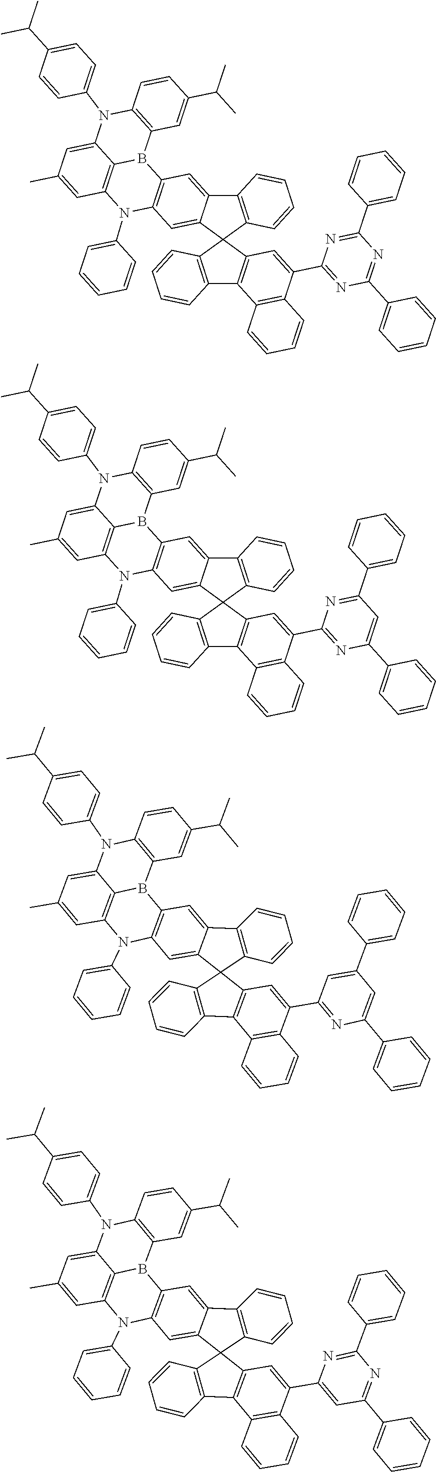

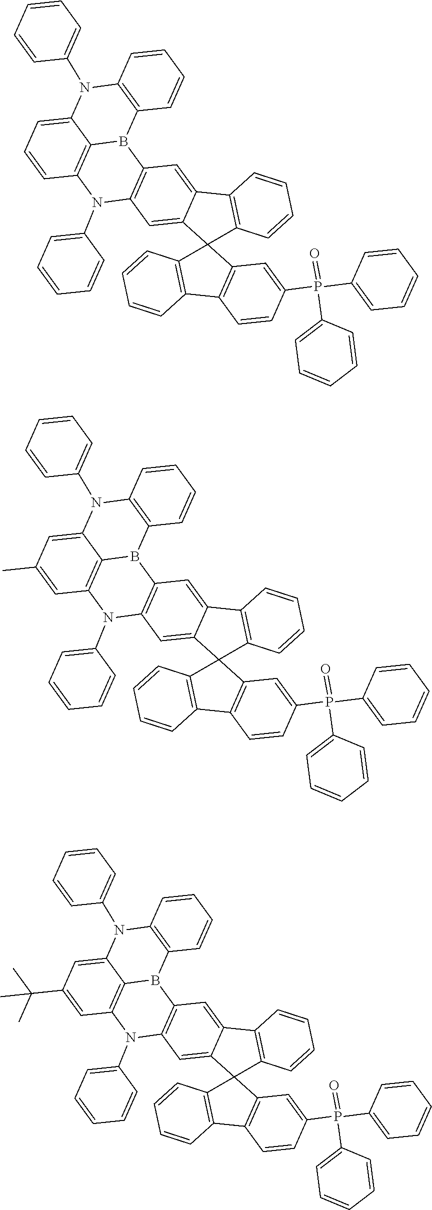 [SMILES: O=P(c1ccccc1)(c1ccccc1)c1ccc2c(c1)C1(c3ccccc3-2)c2ccccc2-c2cc3c(cc21)N(c1ccccc1)c1cccc2c1B3c1ccccc1N2c1ccccc1 ; Cc1cc2c3c(c1)N(c1ccccc1)c1cc4c(cc1B3c1ccccc1N2c1ccccc1)-c1ccccc1C41c2ccccc2-c2ccc(P(=O)(c3ccccc3)c3ccccc3)cc21 ; CC(C)(C)c1cc2c3c(c1)N(c1ccccc1)c1cc4c(cc1B3c1ccccc1N2c1ccccc1)-c1ccccc1C41c2ccccc2-c2ccc(P(=O)(c3ccccc3)c3ccccc3)cc21]

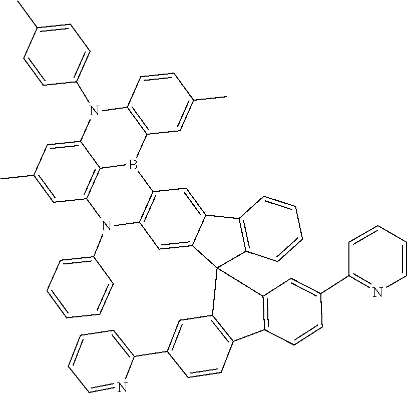 [SMILES: Cc1ccc(N2c3ccc(C)cc3B3c4cc5c(cc4N(c4ccccc4)c4cc(C)cc2c43)C2(c3ccccc3-5)c3cc(-c4ccccn4)ccc3-c3ccc(-c4ccccn4)cc32)cc1]

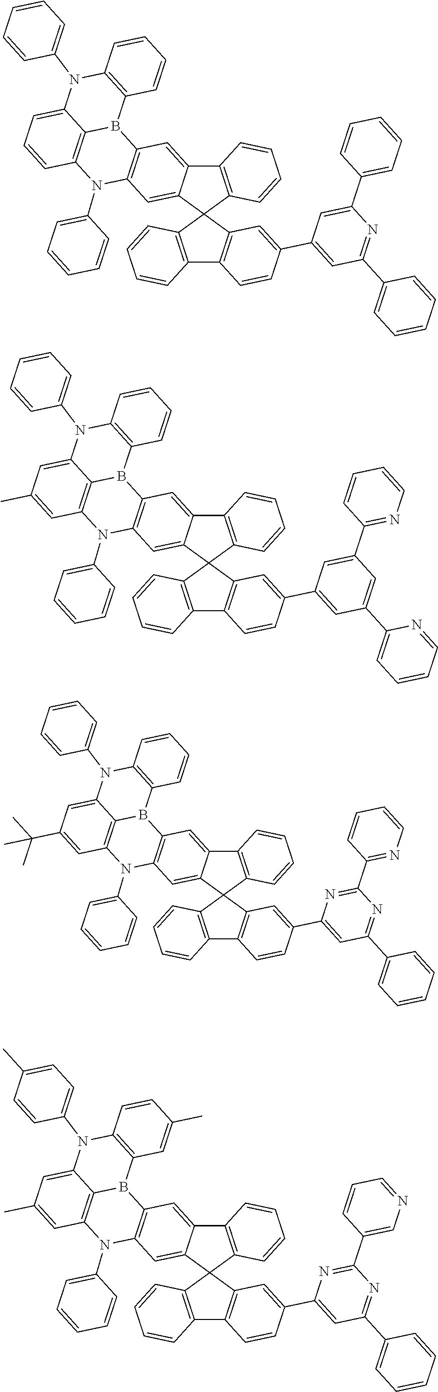 [SMILES: c1ccc(-c2cc(-c3ccc4c(c3)C3(c5ccccc5-4)c4ccccc4-c4cc5c(cc43)N(c3ccccc3)c3cccc4c3B5c3ccccc3N4c3ccccc3)cc(-c3ccccc3)n2)cc1 ; Cc1cc2c3c(c1)N(c1ccccc1)c1cc4c(cc1B3c1ccccc1N2c1ccccc1)-c1ccccc1C41c2ccccc2-c2ccc(-c3cc(-c4ccccn4)cc(-c4ccccn4)c3)cc21 ; CC(C)(C)c1cc2c3c(c1)N(c1ccccc1)c1cc4c(cc1B3c1ccccc1N2c1ccccc1)-c1ccccc1C41c2ccccc2-c2ccc(-c3cc(-c4ccccc4)nc(-c4ccccn4)n3)cc21 ; Cc1ccc(N2c3ccc(C)cc3B3c4cc5c(cc4N(c4ccccc4)c4cc(C)cc2c43)C2(c3ccccc3-c3ccc(-c4cc(-c6ccccc6)nc(-c6cccnc6)n4)cc32)c2ccccc2-5)cc1]

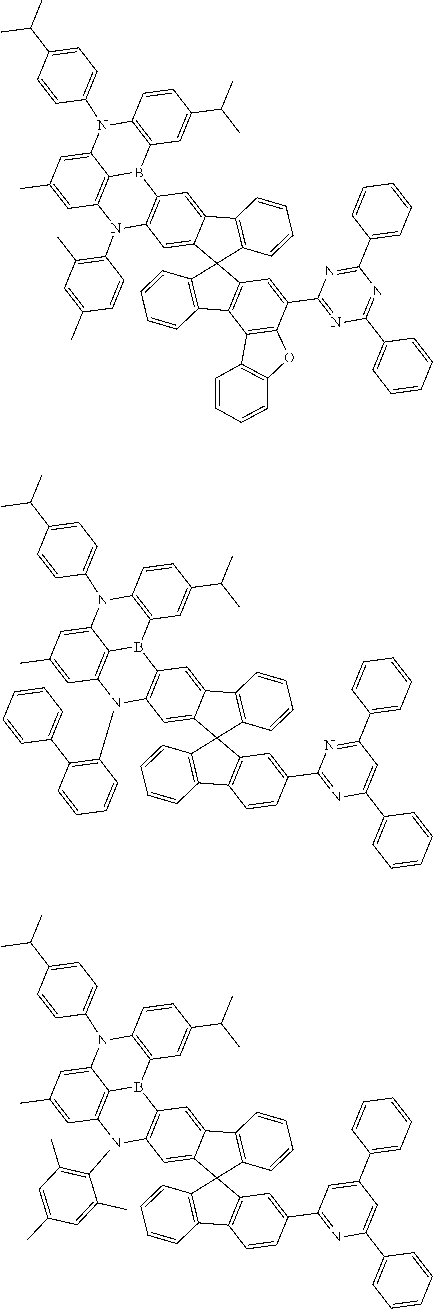 [SMILES: Cc1ccc(N2c3cc4c(cc3B3c5cc(C(C)C)ccc5N(c5ccc(C(C)C)cc5)c5cc(C)cc2c53)-c2ccccc2C42c3ccccc3-c3c2cc(-c2nc(-c4ccccc4)nc(-c4ccccc4)n2)c2oc4ccccc4c32)c(C)c1 ; Cc1cc2c3c(c1)N(c1ccccc1-c1ccccc1)c1cc4c(cc1B3c1cc(C(C)C)ccc1N2c1ccc(C(C)C)cc1)-c1ccccc1C41c2ccccc2-c2ccc(-c3nc(-c4ccccc4)cc(-c4ccccc4)n3)cc21 ; Cc1cc(C)c(N2c3cc4c(cc3B3c5cc(C(C)C)ccc5N(c5ccc(C(C)C)cc5)c5cc(C)cc2c53)-c2ccccc2C42c3ccccc3-c3ccc(-c4cc(-c5ccccc5)cc(-c5ccccc5)n4)cc32)c(C)c1]

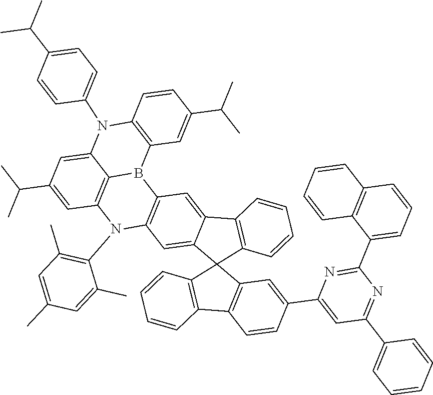 [SMILES: Cc1cc(C)c(N2c3cc4c(cc3B3c5cc(C(C)C)ccc5N(c5ccc(C(C)C)cc5)c5cc(C(C)C)cc2c53)-c2ccccc2C42c3ccccc3-c3ccc(-c4cc(-c5ccccc5)nc(-c5cccc6ccccc56)n4)cc32)c(C)c1]

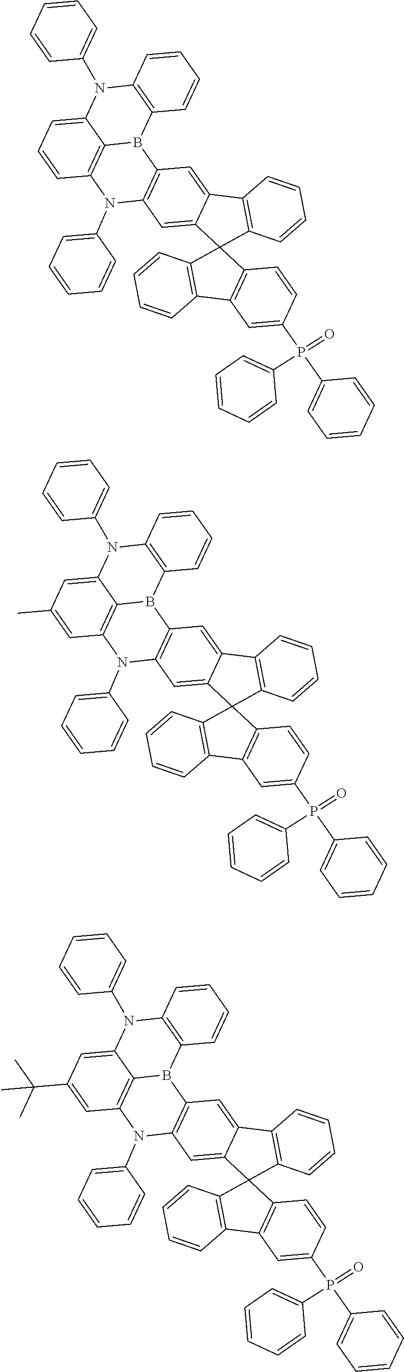 [SMILES: O=P(c1ccccc1)(c1ccccc1)c1ccc2c(c1)-c1ccccc1C21c2ccccc2-c2cc3c(cc21)N(c1ccccc1)c1cccc2c1B3c1ccccc1N2c1ccccc1 ; Cc1cc2c3c(c1)N(c1ccccc1)c1cc4c(cc1B3c1ccccc1N2c1ccccc1)-c1ccccc1C41c2ccccc2-c2cc(P(=O)(c3ccccc3)c3ccccc3)ccc21 ; CC(C)(C)c1cc2c3c(c1)N(c1ccccc1)c1cc4c(cc1B3c1ccccc1N2c1ccccc1)-c1ccccc1C41c2ccccc2-c2cc(P(=O)(c3ccccc3)c3ccccc3)ccc21]

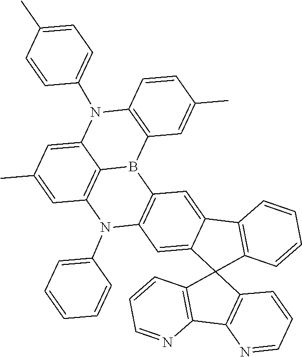 [SMILES: Cc1ccc(N2c3ccc(C)cc3B3c4cc5c(cc4N(c4ccccc4)c4cc(C)cc2c43)C2(c3ccccc3-5)c3cccnc3-c3ncccc32)cc1]

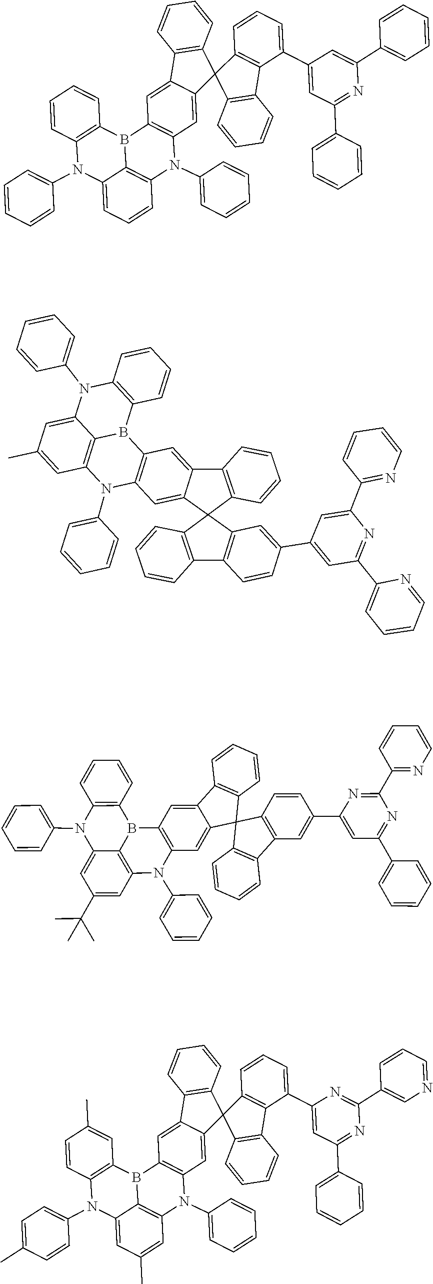 [SMILES: c1ccc(-c2cc(-c3cccc4c3-c3ccccc3C43c4ccccc4-c4cc5c(cc43)N(c3ccccc3)c3cccc4c3B5c3ccccc3N4c3ccccc3)cc(-c3ccccc3)n2)cc1 ; Cc1cc2c3c(c1)N(c1ccccc1)c1cc4c(cc1B3c1ccccc1N2c1ccccc1)-c1ccccc1C41c2ccccc2-c2ccc(-c3cc(-c4ccccn4)nc(-c4ccccn4)c3)cc21 ; CC(C)(C)c1cc2c3c(c1)N(c1ccccc1)c1cc4c(cc1B3c1ccccc1N2c1ccccc1)-c1ccccc1C41c2ccccc2-c2cc(-c3cc(-c4ccccc4)nc(-c4ccccn4)n3)ccc21 ; Cc1ccc(N2c3ccc(C)cc3B3c4cc5c(cc4N(c4ccccc4)c4cc(C)cc2c43)C2(c3ccccc3-5)c3ccccc3-c3c(-c4cc(-c5ccccc5)nc(-c5cccnc5)n4)cccc32)cc1]

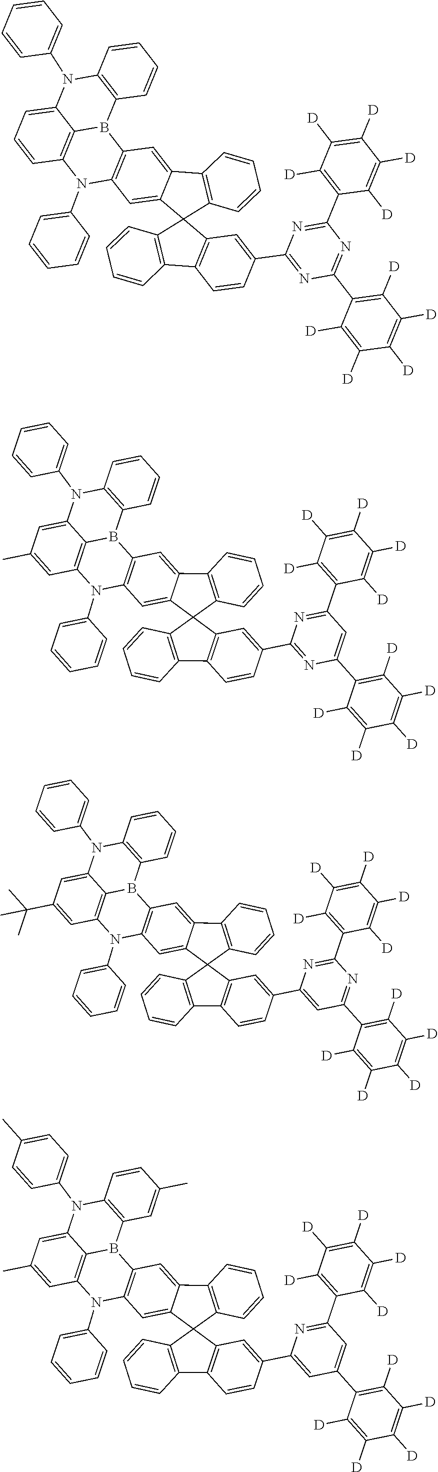

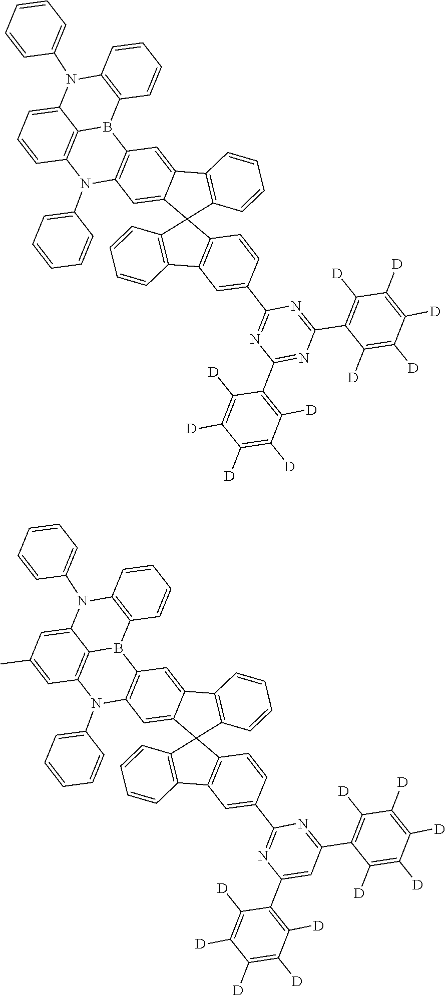 [SMILES: [2H]c1c([2H])c([2H])c(-c2nc(-c3ccc4c(c3)-c3ccccc3C43c4ccccc4-c4cc5c(cc43)N(c3ccccc3)c3cccc4c3B5c3ccccc3N4c3ccccc3)nc(-c3c([2H])c([2H])c([2H])c([2H])c3[2H])n2)c([2H])c1[2H] ; [2H]c1c([2H])c([2H])c(-c2cc(-c3c([2H])c([2H])c([2H])c([2H])c3[2H])nc(-c3ccc4c(c3)-c3ccccc3C43c4ccccc4-c4cc5c(cc43)N(c3ccccc3)c3cc(C)cc4c3B5c3ccccc3N4c3ccccc3)n2)c([2H])c1[2H]]

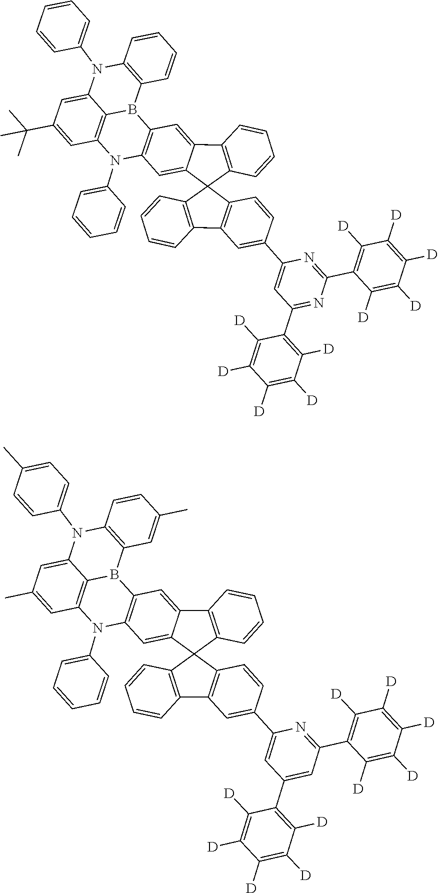 [SMILES: [2H]c1c([2H])c([2H])c(-c2cc(-c3ccc4c(c3)-c3ccccc3C43c4ccccc4-c4cc5c(cc43)N(c3ccccc3)c3cc(C(C)(C)C)cc4c3B5c3ccccc3N4c3ccccc3)nc(-c3c([2H])c([2H])c([2H])c([2H])c3[2H])n2)c([2H])c1[2H] ; [2H]c1c([2H])c([2H])c(-c2cc(-c3ccc4c(c3)-c3ccccc3C43c4ccccc4-c4cc5c(cc43)N(c3ccccc3)c3cc(C)cc4c3B5c3cc(C)ccc3N4c3ccc(C)cc3)nc(-c3c([2H])c([2H])c([2H])c([2H])c3[2H])c2)c([2H])c1[2H]]

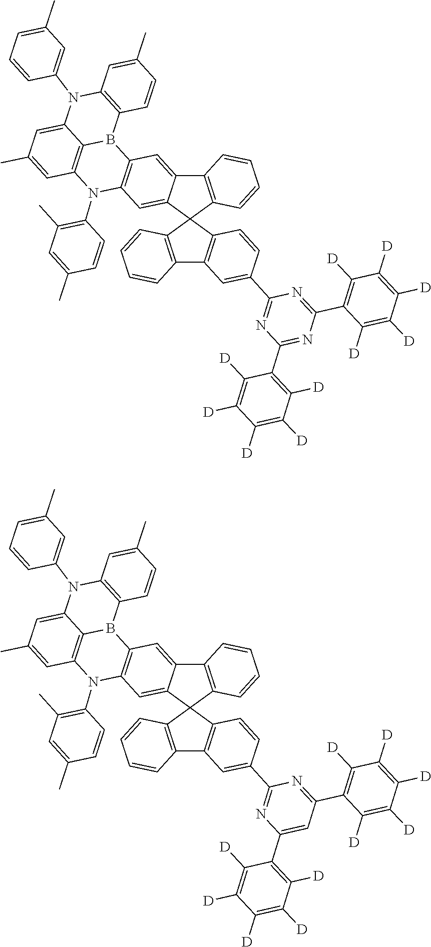 [SMILES: [2H]c1c([2H])c([2H])c(-c2nc(-c3ccc4c(c3)-c3ccccc3C43c4ccccc4-c4cc5c(cc43)N(c3ccc(C)cc3C)c3cc(C)cc4c3B5c3ccc(C)cc3N4c3cccc(C)c3)nc(-c3c([2H])c([2H])c([2H])c([2H])c3[2H])n2)c([2H])c1[2H] ; [2H]c1c([2H])c([2H])c(-c2cc(-c3c([2H])c([2H])c([2H])c([2H])c3[2H])nc(-c3ccc4c(c3)-c3ccccc3C43c4ccccc4-c4cc5c(cc43)N(c3ccc(C)cc3C)c3cc(C)cc4c3B5c3ccc(C)cc3N4c3cccc(C)c3)n2)c([2H])c1[2H]]

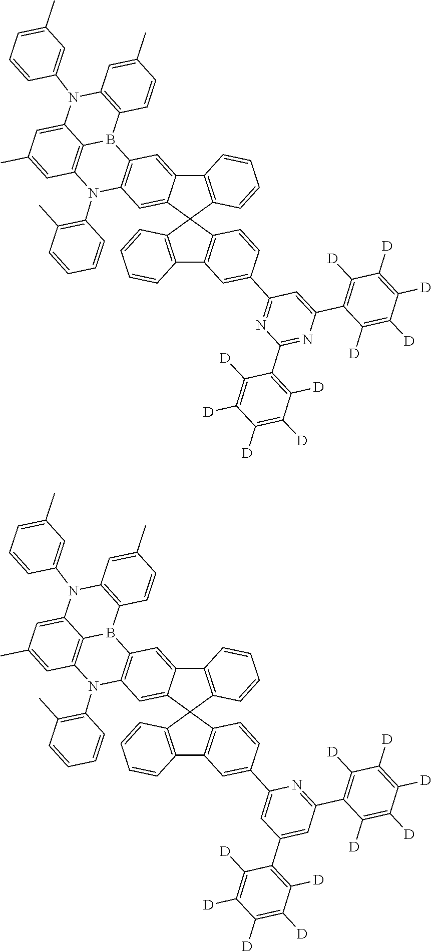 [SMILES: [2H]c1c([2H])c([2H])c(-c2cc(-c3ccc4c(c3)-c3ccccc3C43c4ccccc4-c4cc5c(cc43)N(c3ccccc3C)c3cc(C)cc4c3B5c3ccc(C)cc3N4c3cccc(C)c3)nc(-c3c([2H])c([2H])c([2H])c([2H])c3[2H])n2)c([2H])c1[2H] ; [2H]c1c([2H])c([2H])c(-c2cc(-c3ccc4c(c3)-c3ccccc3C43c4ccccc4-c4cc5c(cc43)N(c3ccccc3C)c3cc(C)cc4c3B5c3ccc(C)cc3N4c3cccc(C)c3)nc(-c3c([2H])c([2H])c([2H])c([2H])c3[2H])c2)c([2H])c1[2H]]

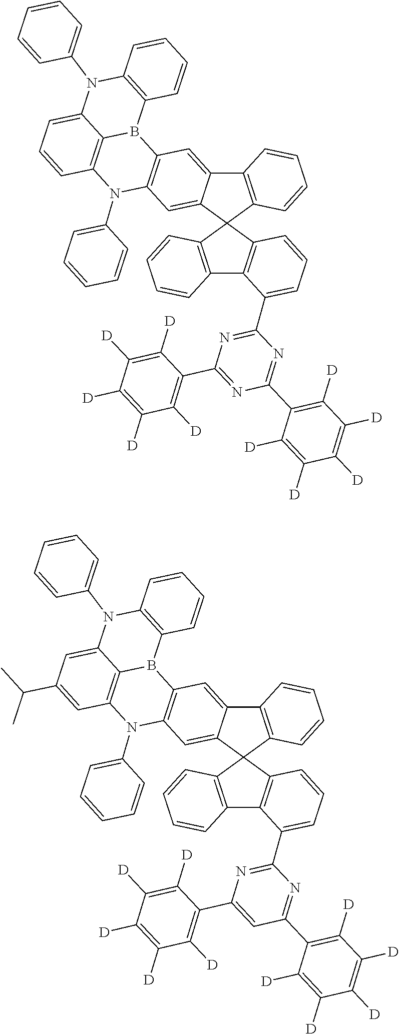 [SMILES: [2H]c1c([2H])c([2H])c(-c2nc(-c3cccc4c3-c3ccccc3C43c4ccccc4-c4cc5c(cc43)N(c3ccccc3)c3cccc4c3B5c3ccccc3N4c3ccccc3)nc(-c3c([2H])c([2H])c([2H])c([2H])c3[2H])n2)c([2H])c1[2H] ; [2H]c1c([2H])c([2H])c(-c2cc(-c3c([2H])c([2H])c([2H])c([2H])c3[2H])nc(-c3cccc4c3-c3ccccc3C43c4ccccc4-c4cc5c(cc43)N(c3ccccc3)c3cc(C(C)C)cc4c3B5c3ccccc3N4c3ccccc3)n2)c([2H])c1[2H]]

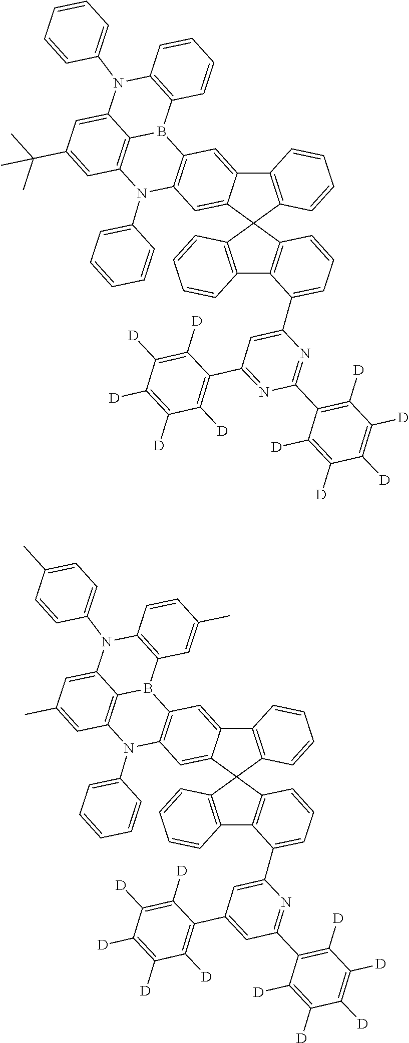 [SMILES: [2H]c1c([2H])c([2H])c(-c2cc(-c3cccc4c3-c3ccccc3C43c4ccccc4-c4cc5c(cc43)N(c3ccccc3)c3cc(C(C)(C)C)cc4c3B5c3ccccc3N4c3ccccc3)nc(-c3c([2H])c([2H])c([2H])c([2H])c3[2H])n2)c([2H])c1[2H] ; [2H]c1c([2H])c([2H])c(-c2cc(-c3cccc4c3-c3ccccc3C43c4ccccc4-c4cc5c(cc43)N(c3ccccc3)c3cc(C)cc4c3B5c3cc(C)ccc3N4c3ccc(C)cc3)nc(-c3c([2H])c([2H])c([2H])c([2H])c3[2H])c2)c([2H])c1[2H]]

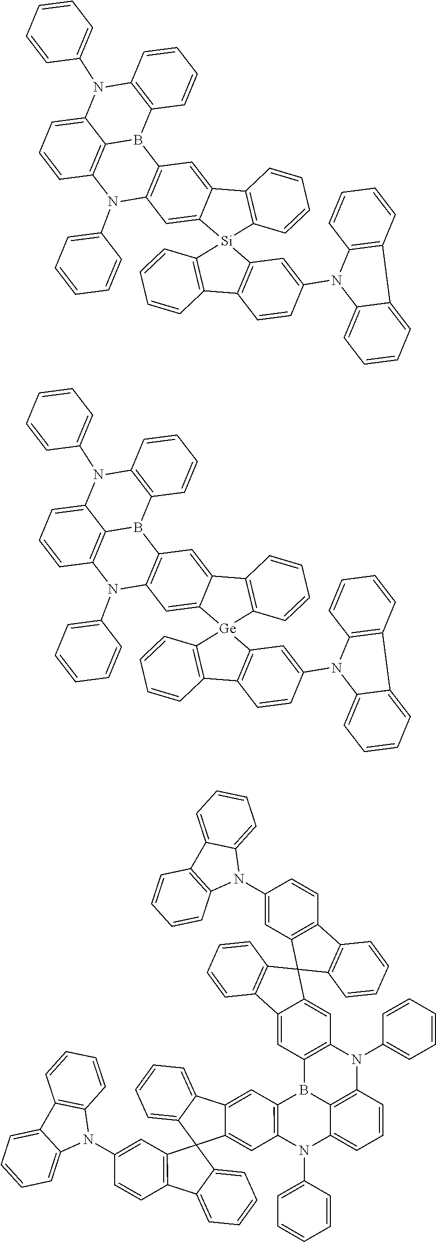

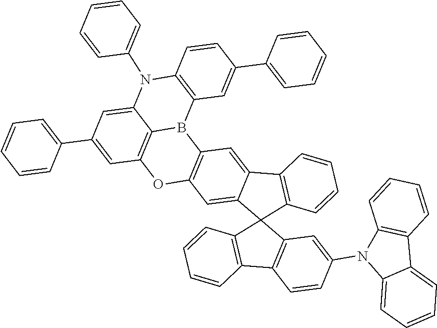 [SMILES: c1ccc(-c2ccc3c(c2)B2c4cc5c(cc4Oc4cc(-c6ccccc6)cc(c42)N3c2ccccc2)C2(c3ccccc3-c3ccc(-n4c6ccccc6c6ccccc64)cc32)c2ccccc2-5)cc1]

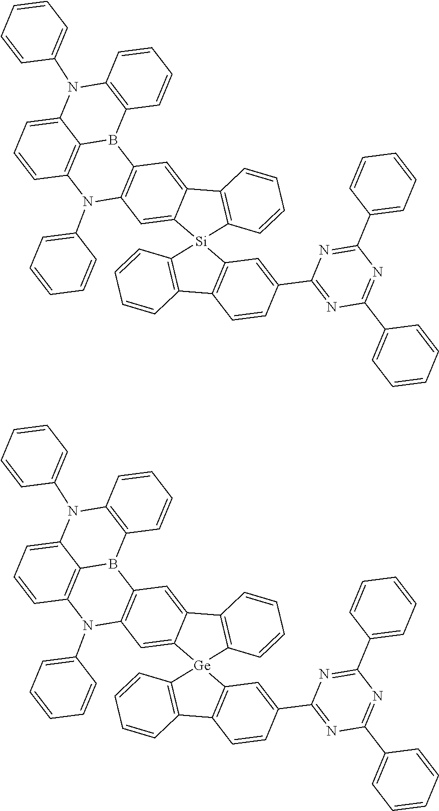

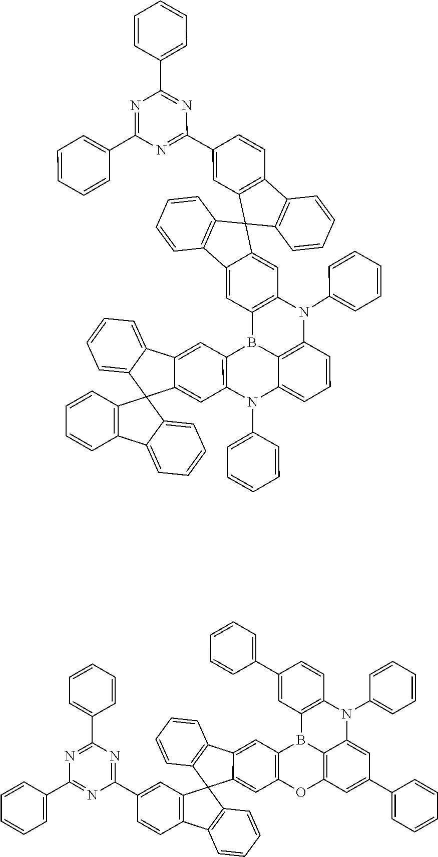 [SMILES: c1ccc(-c2nc(-c3ccccc3)nc(-c3ccc4c(c3)C3(c5ccccc5-4)c4ccccc4-c4cc5c(cc43)N(c3ccccc3)c3cccc4c3B5c3cc5c(cc3N4c3ccccc3)C3(c4ccccc4-c4ccccc43)c3ccccc3-5)n2)cc1 ; c1ccc(-c2ccc3c(c2)B2c4cc5c(cc4Oc4cc(-c6ccccc6)cc(c42)N3c2ccccc2)C2(c3ccccc3-c3ccc(-c4nc(-c6ccccc6)nc(-c6ccccc6)n4)cc32)c2ccccc2-5)cc1]

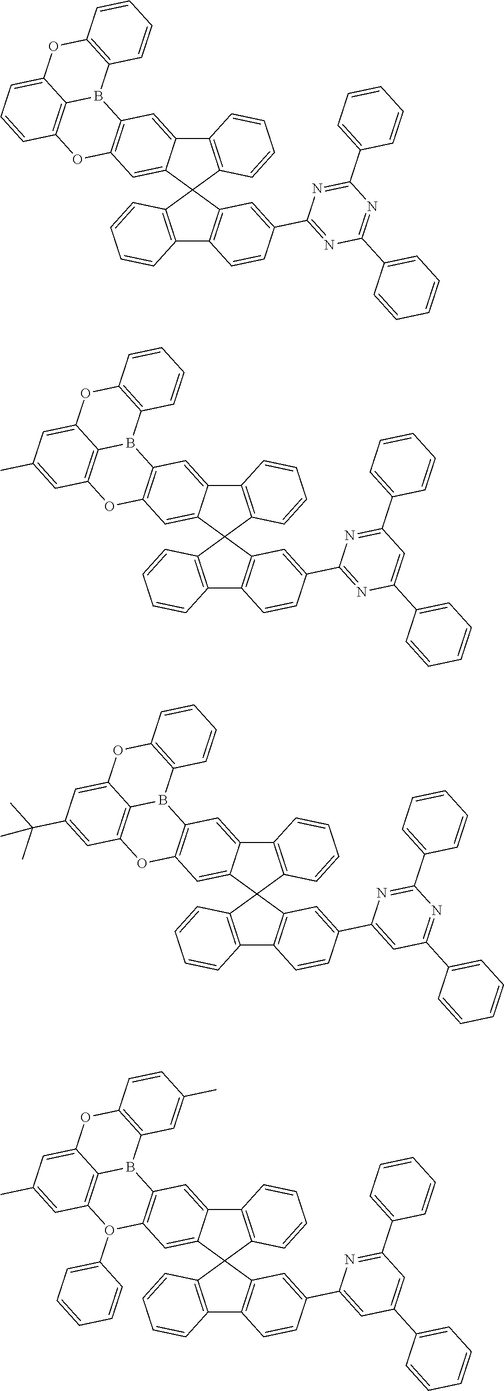

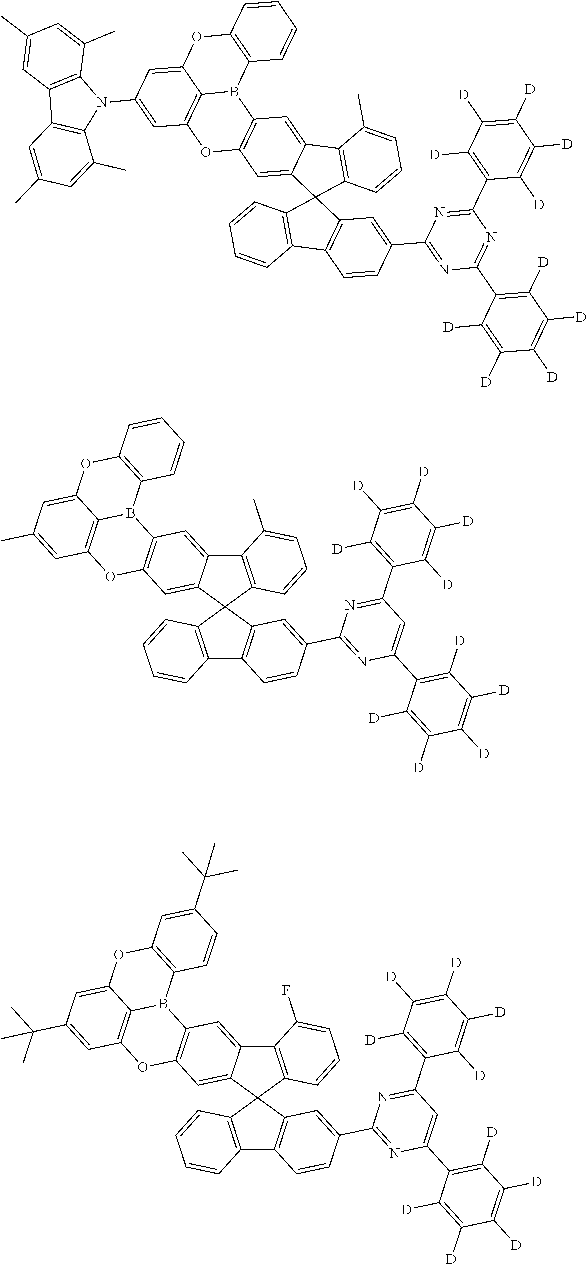

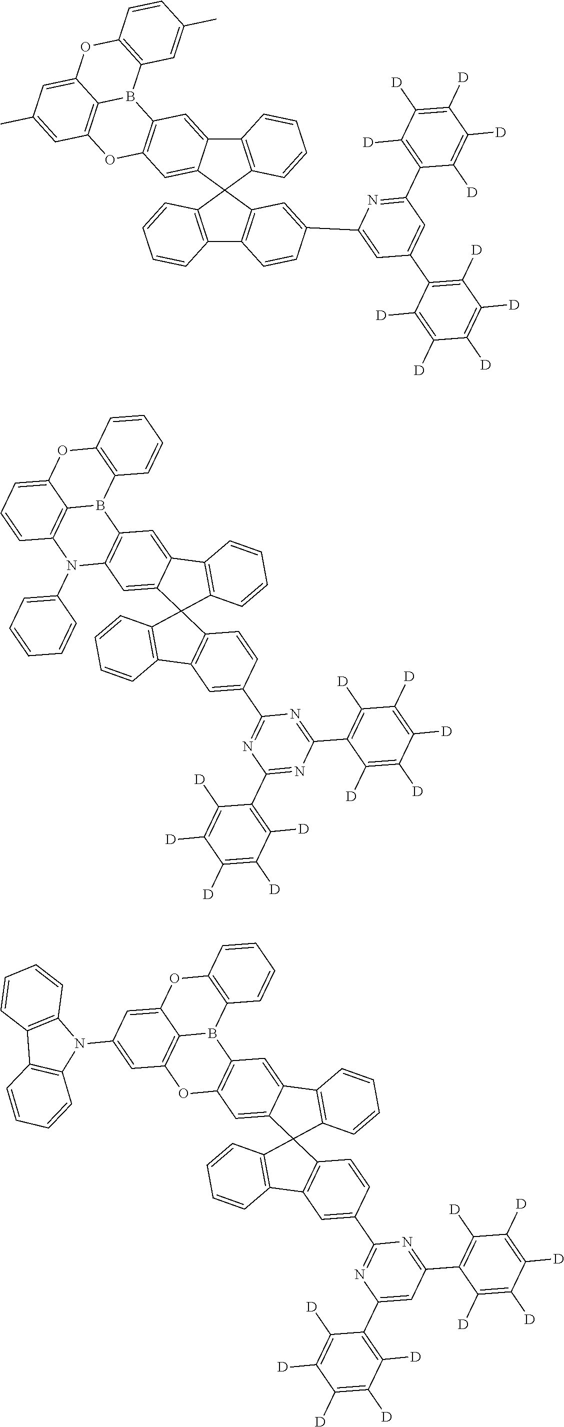

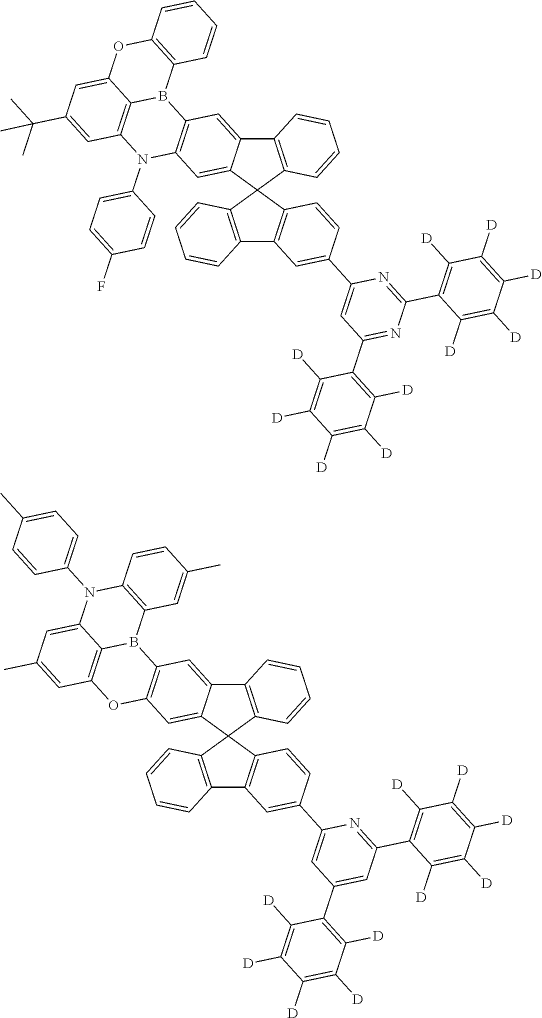 [SMILES: [2H]c1c([2H])c([2H])c(-c2cc(-c3ccc4c(c3)-c3ccccc3C43c4ccccc4-c4cc5c(cc43)N(c3ccc(F)cc3)c3cc(C(C)(C)C)cc4c3B5c3ccccc3O4)nc(-c3c([2H])c([2H])c([2H])c([2H])c3[2H])n2)c([2H])c1[2H] ; [2H]c1c([2H])c([2H])c(-c2cc(-c3ccc4c(c3)-c3ccccc3C43c4ccccc4-c4cc5c(cc43)Oc3cc(C)cc4c3B5c3cc(C)ccc3N4c3ccc(C)cc3)nc(-c3c([2H])c([2H])c([2H])c([2H])c3[2H])c2)c([2H])c1[2H]]

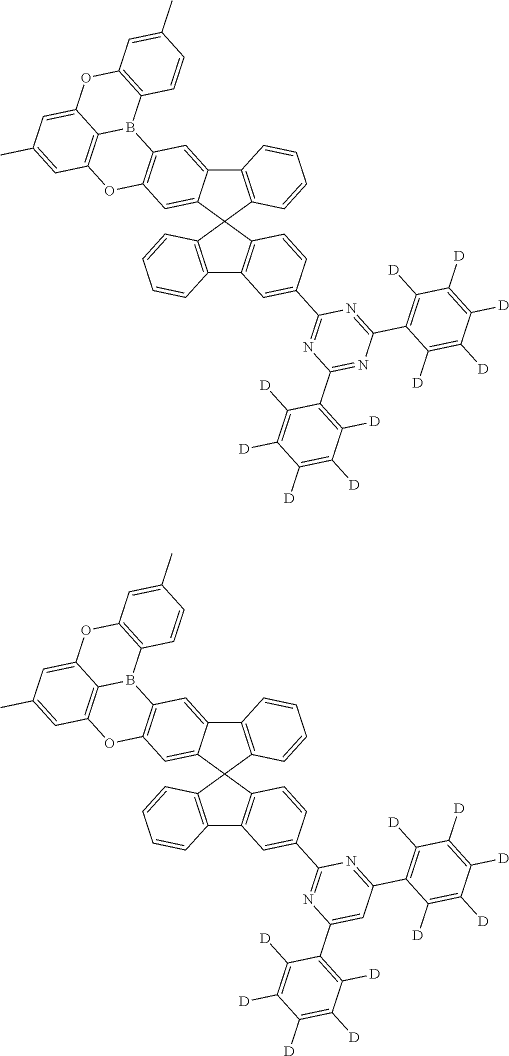 [SMILES: [2H]c1c([2H])c([2H])c(-c2nc(-c3ccc4c(c3)-c3ccccc3C43c4ccccc4-c4cc5c(cc43)Oc3cc(C)cc4c3B5c3ccc(C)cc3O4)nc(-c3c([2H])c([2H])c([2H])c([2H])c3[2H])n2)c([2H])c1[2H] ; [2H]c1c([2H])c([2H])c(-c2cc(-c3c([2H])c([2H])c([2H])c([2H])c3[2H])nc(-c3ccc4c(c3)-c3ccccc3C43c4ccccc4-c4cc5c(cc43)Oc3cc(C)cc4c3B5c3ccc(C)cc3O4)n2)c([2H])c1[2H]]

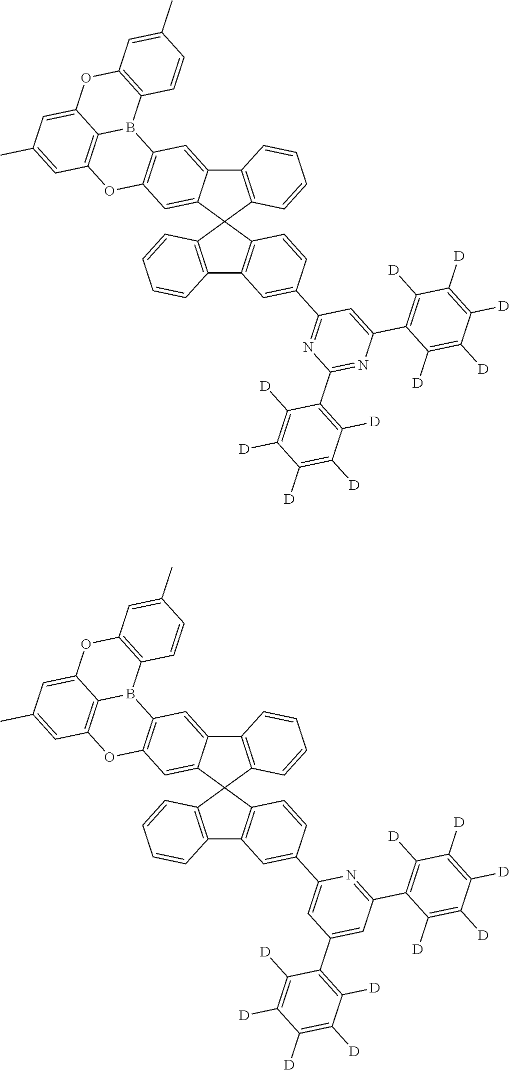 [SMILES: [2H]c1c([2H])c([2H])c(-c2cc(-c3ccc4c(c3)-c3ccccc3C43c4ccccc4-c4cc5c(cc43)Oc3cc(C)cc4c3B5c3ccc(C)cc3O4)nc(-c3c([2H])c([2H])c([2H])c([2H])c3[2H])n2)c([2H])c1[2H] ; [2H]c1c([2H])c([2H])c(-c2cc(-c3ccc4c(c3)-c3ccccc3C43c4ccccc4-c4cc5c(cc43)Oc3cc(C)cc4c3B5c3ccc(C)cc3O4)nc(-c3c([2H])c([2H])c([2H])c([2H])c3[2H])c2)c([2H])c1[2H]]

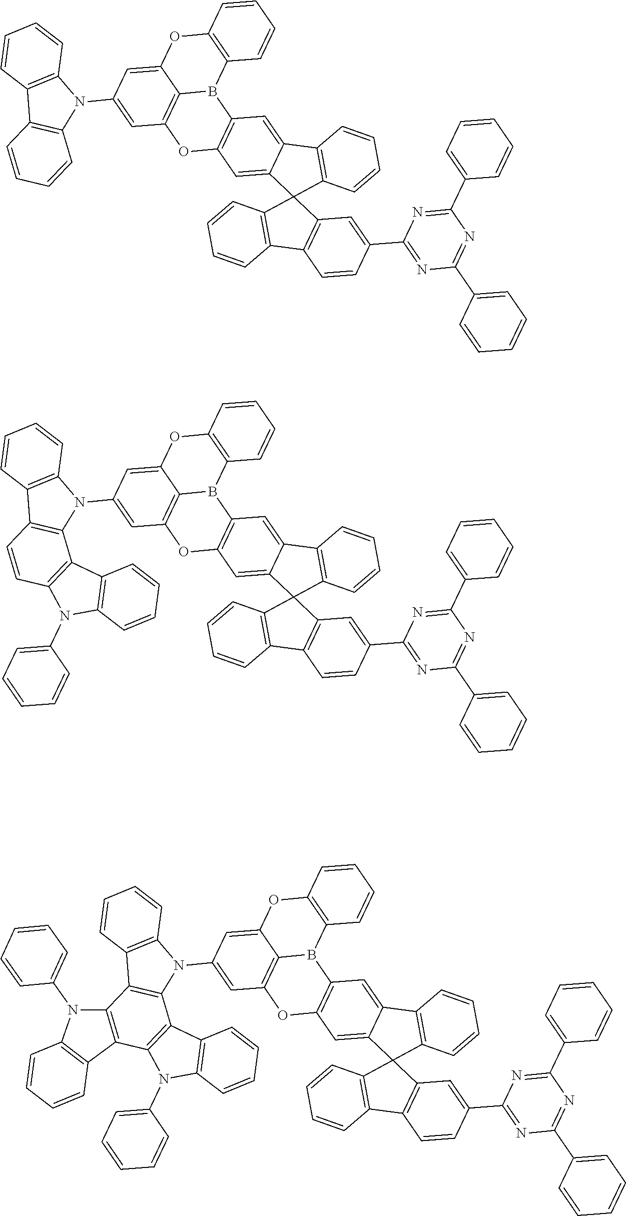 [SMILES: c1ccc(-c2nc(-c3ccccc3)nc(-c3ccc4c(c3)C3(c5ccccc5-4)c4ccccc4-c4cc5c(cc43)Oc3cc(-n4c6ccccc6c6ccccc64)cc4c3B5c3ccccc3O4)n2)cc1 ; c1ccc(-c2nc(-c3ccccc3)nc(-c3ccc4c(c3)C3(c5ccccc5-4)c4ccccc4-c4cc5c(cc43)Oc3cc(-n4c6ccccc6c6ccc7c(c8ccccc8n7-c7ccccc7)c64)cc4c3B5c3ccccc3O4)n2)cc1 ; c1ccc(-c2nc(-c3ccccc3)nc(-c3ccc4c(c3)C3(c5ccccc5-4)c4ccccc4-c4cc5c(cc43)Oc3cc(-n4c6ccccc6c6c7c(c8ccccc8n7-c7ccccc7)c7c(c8ccccc8n7-c7ccccc7)c64)cc4c3B5c3ccccc3O4)n2)cc1]

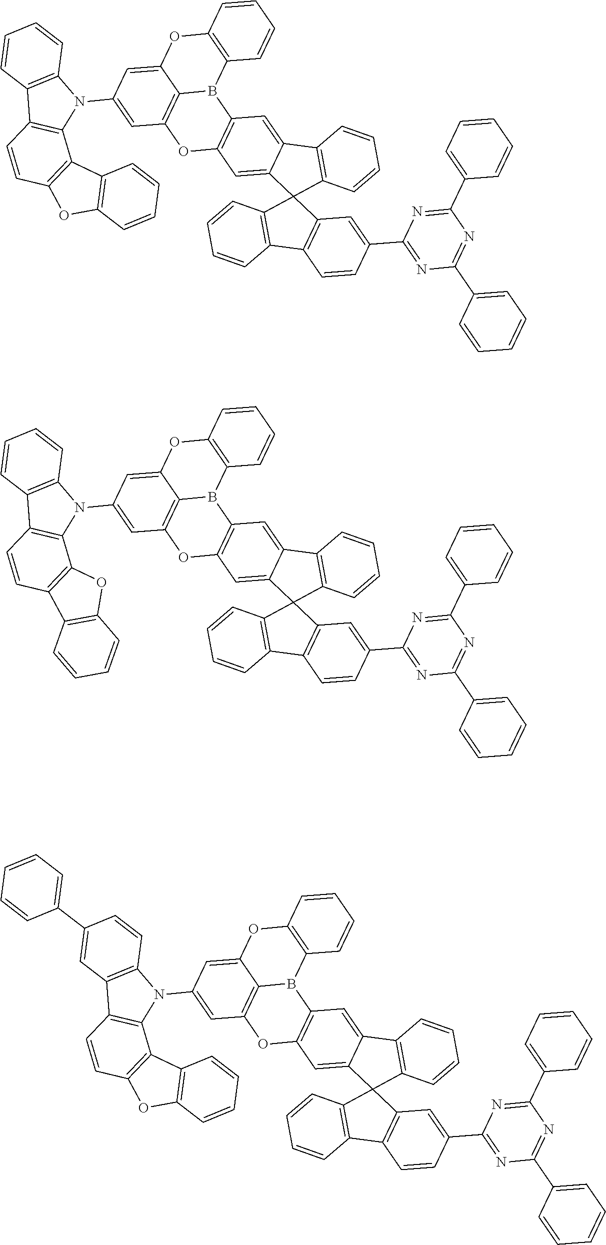 [SMILES: c1ccc(-c2nc(-c3ccccc3)nc(-c3ccc4c(c3)C3(c5ccccc5-4)c4ccccc4-c4cc5c(cc43)Oc3cc(-n4c6ccccc6c6ccc7oc8ccccc8c7c64)cc4c3B5c3ccccc3O4)n2)cc1 ; c1ccc(-c2nc(-c3ccccc3)nc(-c3ccc4c(c3)C3(c5ccccc5-4)c4ccccc4-c4cc5c(cc43)Oc3cc(-n4c6ccccc6c6ccc7c8ccccc8oc7c64)cc4c3B5c3ccccc3O4)n2)cc1 ; c1ccc(-c2ccc3c(c2)c2ccc4oc5ccccc5c4c2n3-c2cc3c4c(c2)Oc2cc5c(cc2B4c2ccccc2O3)-c2ccccc2C52c3ccccc3-c3ccc(-c4nc(-c5ccccc5)nc(-c5ccccc5)n4)cc32)cc1]

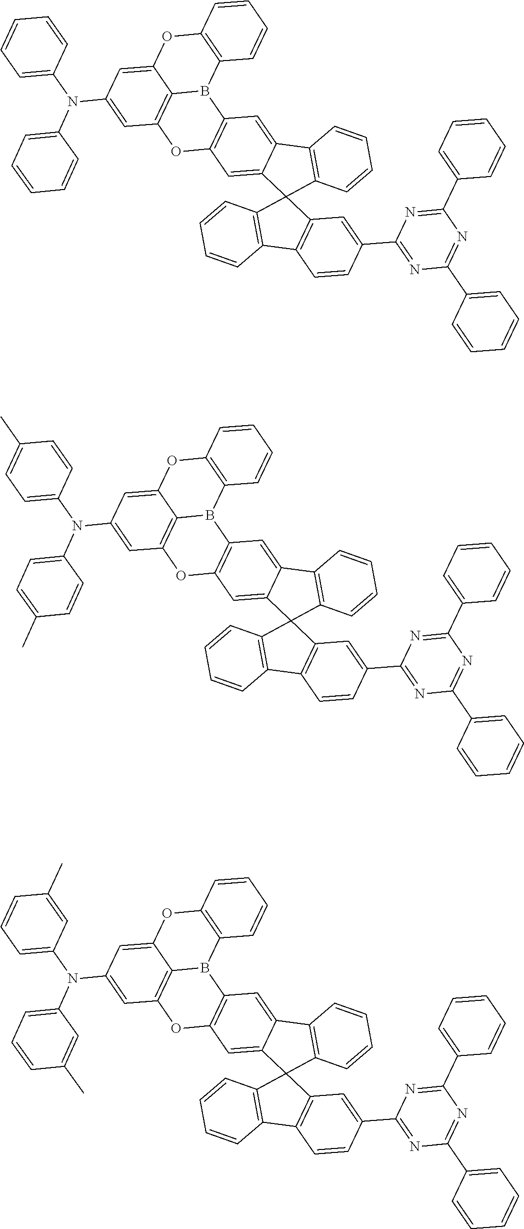 [SMILES: c1ccc(-c2nc(-c3ccccc3)nc(-c3ccc4c(c3)C3(c5ccccc5-4)c4ccccc4-c4cc5c(cc43)Oc3cc(N(c4ccccc4)c4ccccc4)cc4c3B5c3ccccc3O4)n2)cc1 ; Cc1ccc(N(c2ccc(C)cc2)c2cc3c4c(c2)Oc2cc5c(cc2B4c2ccccc2O3)-c2ccccc2C52c3ccccc3-c3ccc(-c4nc(-c5ccccc5)nc(-c5ccccc5)n4)cc32)cc1 ; Cc1cccc(N(c2cccc(C)c2)c2cc3c4c(c2)Oc2cc5c(cc2B4c2ccccc2O3)-c2ccccc2C52c3ccccc3-c3ccc(-c4nc(-c5ccccc5)nc(-c5ccccc5)n4)cc32)c1]

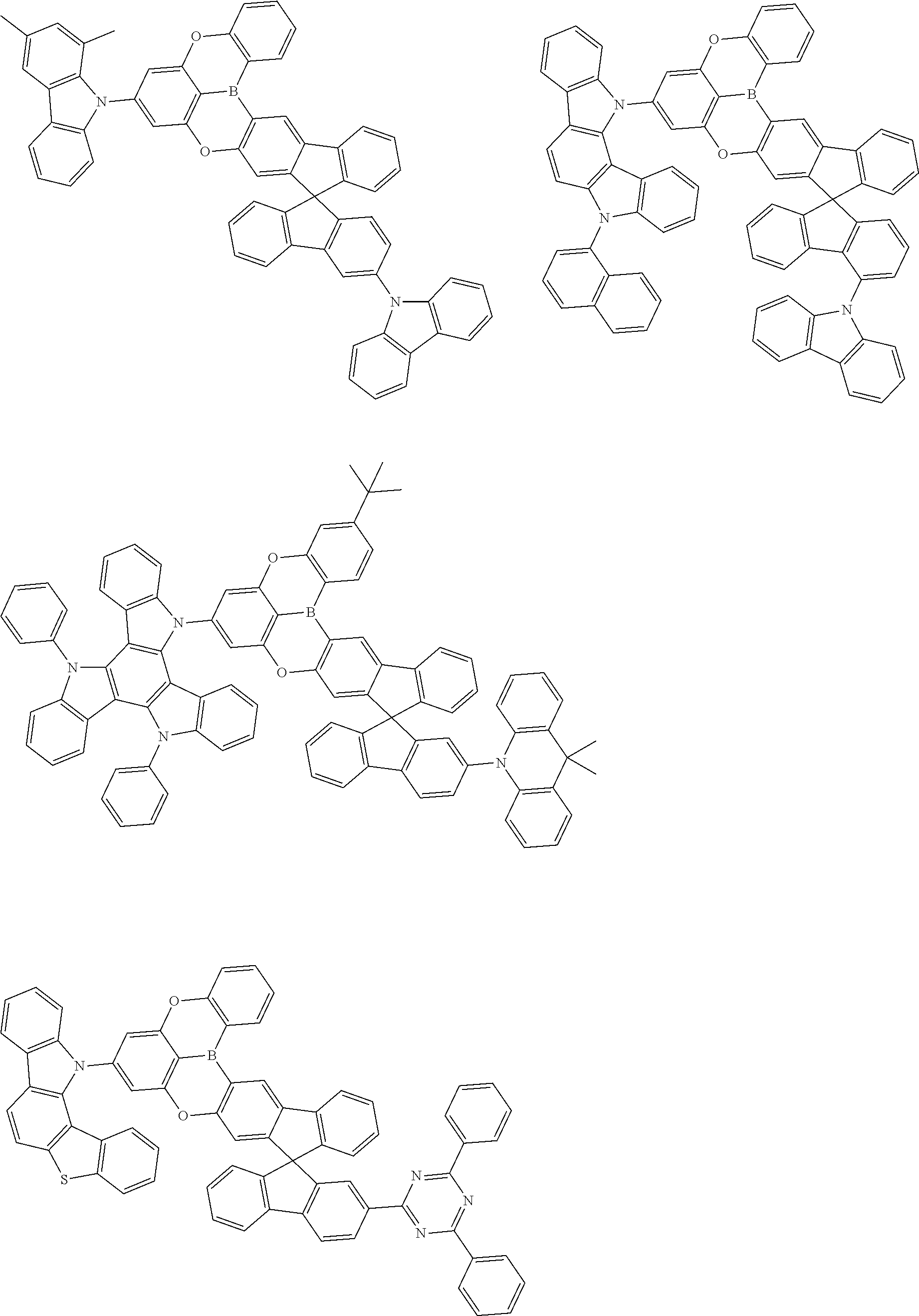

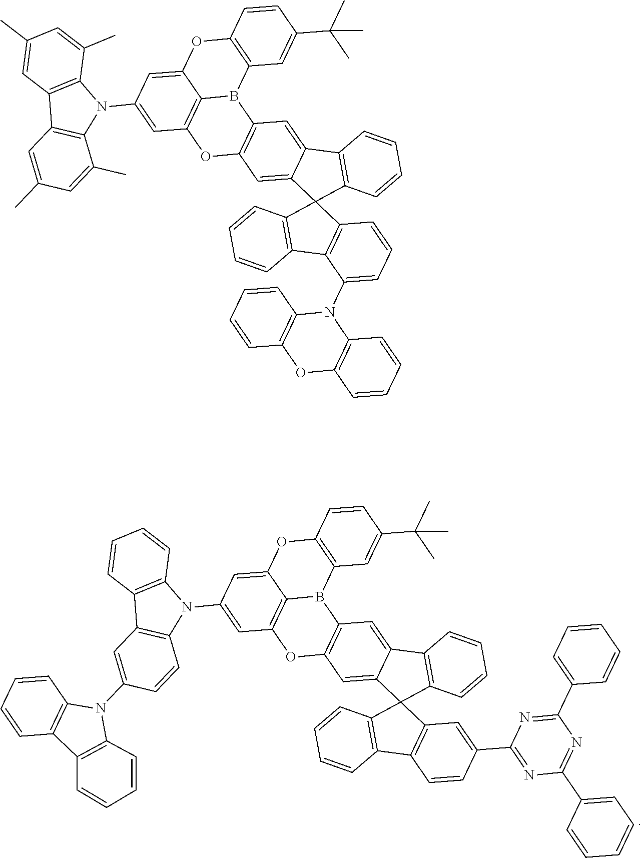 [SMILES: Cc1cc(C)c2c(c1)c1cc(C)cc(C)c1n2-c1cc2c3c(c1)Oc1cc4c(cc1B3c1cc(C(C)(C)C)ccc1O2)-c1ccccc1C41c2ccccc2-c2c(N3c4ccccc4Oc4ccccc43)cccc21 ; CC(C)(C)c1ccc2c(c1)B1c3cc4c(cc3Oc3cc(-n5c6ccccc6c6cc(-n7c8ccccc8c8ccccc87)ccc65)cc(c31)O2)C1(c2ccccc2-c2ccc(-c3nc(-c5ccccc5)nc(-c5ccccc5)n3)cc21)c1ccccc1-4]

8. An organic light-emitting diode comprising:
a first electrode;
a second electrode;
a light-emitting layer disposed between the first electrode and the second electrode; and
further comprising or not comprising an organic layer adjacent to any one or both surfaces of the light-emitting layer,
wherein the light-emitting layer includes the multifunctional compound of claim 1, and
the light-emitting layer or the adjacent organic layer includes an excited complex-forming compound.

9. The organic light-emitting diode of claim 8, wherein the multifunctional compound represented by Chemical Formula 1 is divided into an atom represented by X, a light-emitting moiety and an excited complex-forming moiety, the light-emitting moiety and the excited complex-forming moiety are linked through the atom represented by X, and the atom represented by X is X presented in Chemical Formula 1;
the light-emitting moiety includes ring A, a conjugated ring formed to include Y¹ to Y⁵, and Q in Chemical Formula 1;
the excited complex-forming moiety includes a conjugated ring formed to include Y⁶ to Y¹⁰, a conjugated ring formed to include Y¹¹ to Y¹⁵, and Z in Chemical Formula 1; and
the excited complex-forming moiety includes an atom having at least one unshared electron pair.

10. The organic light-emitting diode of claim 9, wherein at least one of Y⁶ to Y¹⁵ and Z is an atom having an unshared electron pair included in a wave function of HOMO or LUMO of the excited complex-forming moiety; or
at least one of Y⁶ to Y¹⁵ has R represented by the following Chemical Formula 5 or the following Chemical Formula 6: 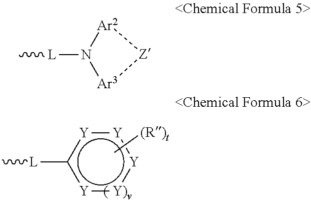
in Chemical Formula 5 and Chemical Formula 6,
L′ is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof;
Z′ is not present, represents a single bond, or is one atom selected from the group consisting of Group IIIA, Group IVA, Group VA and Group VIA elements, and when Z′ is an atom, it optionally has a substituent selected from hydrogen, alkyl having 1 to 30 carbon atoms, cycloalkyl having 3 to 30 carbon atoms, heterocycloalkyl having 2 to 30 carbon atoms, aryl having 6 to 30 carbon atoms unsubstituted or substituted with a third additional substituent, heteroaryl having 2 to 30 carbon atoms unsubstituted or substituted with a third additional substituent, and combinations thereof according to a stoichiometric ratio;
Ar² and Ar³ are each independently alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, or heteroaryl having 2 to 30 carbon atoms unsubstituted or substituted with a third additional substituent, and Ar² and Ar³ are optionally each independently linked to L′ or the second additional substituent to form a fused ring;
t is an integer of 0 to 5;
v is 0 or 1;
R″s are each independently selected from hydrogen, deuterium, alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkyl amine having 3 to 30 carbon atoms, heterocycloalkyl amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 6 to 30 carbon atoms, aryl phosphine oxide having 6 to 30 carbon atoms, and combinations thereof, and herein, at least two R′s are optionally linked to each other to form a ring;
the third additional substituent is selected from alkyl having 1 to 30 carbon atoms, cycloalkyl having 3 to 30 carbon atoms, heterocycloalkyl having 2 to 30 carbon atoms, ally having 3 to 30 carbon atoms, aryl having 6 to 30 carbon atoms, heteroaryl having 2 to 30 carbon atoms, alkyl amine having 1 to 30 carbon atoms, cycloalkyl amine having 3 to 30 carbon atoms, heterocycloalkyl amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof;
Ys are each independently nitrogen, oxygen, sulfur or carbon; [symbol]
represents a linking site;
however, in Chemical Formula 6, L′ or R″ includes at least one atom having an unshared electron pair included in a wave function of HOMO or LUMO of the excited complex-forming moiety, or at least one of Ys is nitrogen, oxygen or sulfur.

11. The organic light-emitting diode of claim 9, wherein the excited complex-forming moiety forms an excited complex with the excited complex-forming compound; and the light-emitting moiety emits light by receiving excited energy of the excited complex.

12. The organic light-emitting diode of claim 8, wherein the multifunctional compound includes at least one deuterium.

13. The organic light-emitting diode of claim 8, wherein the light-emitting layer includes at least two types of the multifunctional compound.

14. The organic light-emitting diode of claim 8, wherein the light-emitting layer further includes at least one selected from the group consisting of a host, an additional dopant and combinations thereof.

15. The organic light-emitting diode of claim 8, wherein the light-emitting layer further includes a phosphorescent material including Ir or Pt.

16. The organic light-emitting diode of claim 8, wherein the light-emitting layer further includes a delayed fluorescent material in which an energy difference between a singlet and a triplet is 0.3 eV or less.

17. The organic light-emitting diode of claim 8, which is a tandem-type organic light-emitting diode including a plurality of organic light-emitting units, wherein at least one of the plurality of organic light-emitting units includes the light-emitting layer.
